(19) United States
(12) Patent Application Publication
(10) Pub. No.: US 2009/0186300 A1
(43) Pub. Date: Jul. 23, 2009

(54) RESIST COMPOSITION FOR LIQUID IMMERSION LITHOGRAPHY, METHOD OF FORMING RESIST PATTERN, AND FLUORINE-CONTAINING COPOLYMER

(75) Inventors: Sanae Furuya, Kawasaki-shi (JP); Takahiro Dazai, Kawasaki-shi (JP); Takayoshi Mori, Kawasaki-shi (JP); Daiju Shiono, Kawasaki-shi (JP); Tomoyuki Hirano, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 12/348,780

(22) Filed: Jan. 5, 2009

(30) Foreign Application Priority Data
Jan. 23, 2008 (JP) 2008-013024

(51) Int. Cl. G03C 1/053; G03F 7/26; C08F 220/22

(52) U.S. Cl. 430/285.1; 430/406; 526/245

(57) ABSTRACT

A resist composition for immersion exposure including a base component (A) that exhibits changed solubility in an alkali developing solution under the action of acid, an acid generator component (B) that generates acid upon exposure, and a fluorine-containing copolymer (C) containing a structural unit (c1) represented by general formula (c1-1) shown below. In the formula, R¹ represents a hydrogen atom, a lower alkyl group or a halogenated lower alkyl group, Q¹ represents a single bond or a divalent linking group, A represents an aromatic cyclic group that may have a substituent, Q² represents a group in which one hydrogen atom has been removed from a monovalent hydrophilic group, R² represents a base dissociable group, and a represents 1 or 2, provided that at least one among A and the a R² groups contains a fluorine atom.

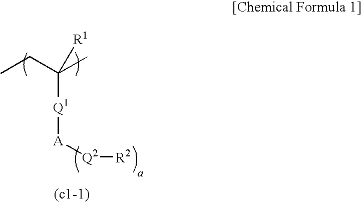

### BACKGROUND OF THE INVENTION

1. Field of the Invention

The present invention relates to a resist composition for liquid immersion exposure (liquid immersion lithography), a method of forming a resist pattern that uses the resist composition for liquid immersion exposure, and a fluorine-containing copolymer.

Priority is claimed on Japanese Patent Application No. 2008-13024, filed Jan. 23, 2008, the content of which is incorporated herein by reference.

2. Description of Related Art

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

For miniaturization of semiconductor elements, shortening the wavelength of the exposure light source, and increasing the numerical aperture (NA) of the projector lens have progressed considerably, and currently, exposure apparatuses in which an ArF excimer laser having a wavelength of 193 nm is used as an exposure light source and in which NA=0.84 have been developed. As shortening of the wavelength of the exposure light source progresses, various lithography properties of the resist material must also be improved, including a high level of sensitivity to these types of exposure light sources and a high resolution capable of reproducing patterns of minute dimensions. As a resist material which satisfies these conditions, a chemically amplified resist is used, which includes a base resin that exhibits changed solubility in an alkali developing solution under the action of acid and an acid generator that generates acid upon exposure.

Currently, resins that contain structural units derived from (meth)acrylate esters within the main chain (namely, acrylic resins) are typically used as the base resins for chemically amplified resists that use ArF excimer laser lithography or the like, as they exhibit excellent transparency in the vicinity of 193 nm.

Here, the term “(meth)acrylic acid” is a generic term that includes either or both of acrylic acid having a hydrogen atom bonded to the α-position and methacrylic acid having a methyl group bonded to the α-position. The term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

As a technique for further improving the resolution, a lithography method called liquid immersion lithography (hereafter, frequently referred to as “immersion exposure”) is known in which exposure (immersion exposure) is conducted in a state where the region between the objective lens of the exposure apparatus and the sample is filled with a liquid (an immersion medium) that has a larger refractive index than the refractive index of air (see, for example, Non-Patent Document 1).

According to this type of immersion exposure, it is considered that higher resolutions equivalent to those obtained using a shorter wavelength light source or a higher NA lens can be obtained using the same exposure light source wavelength, with no lowering of the depth of focus. Furthermore, immersion exposure can be conducted using a conventional exposure apparatus. As a result, it is expected that immersion exposure will enable the formation of resist patterns of higher resolution and superior depth of focus at lower costs. Accordingly, in the production of semiconductor devices, which requires enormous capital investment, immersion exposure is attracting considerable attention as a method that offers significant potential to the semiconductor industry, both in terms of cost and in terms of lithography properties such as resolution.

Immersion lithography is effective in forming patterns having all manner of shapes. Further, immersion exposure is expected to be capable of being used in combination with currently studied super-resolution techniques, such as phase shift methods and modified illumination methods. Currently, as the immersion exposure technique, techniques using an ArF excimer laser as an exposure source are being actively studied, and water is mainly used as the immersion medium.

In recent years, fluorine-containing compounds have been attracting attention for their properties such as water repellency and transparency, and active research and development of fluorine-containing compounds have been conducted in various fields. For example, in the field of resist materials, currently, an acid-labile group such as a methoxymethyl group, tert-butyl group or tert-butyloxycarbonyl group is introduced into a fluorine-containing polymer compound to enable use of the fluorine-containing polymer compound as a base resin for a chemically amplified positive resist. However, when such a fluorine-containing polymer compound is used as a base resin for a positive resist composition, disadvantages arise in that a large quantity of out-gas is generated following exposure, and the resistance to dry etching gases (namely, the etching resistance) is unsatisfactory.

Recently, as a fluorine-containing polymer compound that exhibits excellent etching resistance, a fluorine-containing polymer compound having an acid-labile group containing a cyclic hydrocarbon group has been reported (see, for example, Non-Patent Document 2).

[Non-Patent Document 1]

Proceedings of SPIE (U.S.), vol. 5754, pp. 119-128 (2005)

[Non-Patent Document 2]

Proceedings of SPIE (U.S.), vol. 4690, pp. 76-83 (2002)

### SUMMARY OF THE INVENTION

In immersion exposure, a resist material is required that exhibits not only general lithography properties (such as sensitivity, resolution, and etching resistance), but also properties suited to liquid immersion lithography. For example, in immersion exposure, when the resist film comes into contact with the immersion medium, elution of substances contained in the resist film into the immersion medium (substance elution) occurs. This substance elution causes phenomena such as a degeneration of the resist film, and a change in the refractive index of the immersion medium, thereby adversely affecting the lithography properties. The amount of this substance elution is affected by the properties of the resist film surface (such as the hydrophilicity or hydrophobicity). For example, by enhancing the hydrophobicity of the resist film surface, this substance elution can be reduced. Further, when the immersion medium is water, and immersion exposure is performed using a scanning-type immersion exposure apparatus as disclosed in Non-Patent Document 1, a water tracking ability wherein the immersion medium is capable of tracking the movement of the lens is required. When the water tracking ability is poor, the exposure speed decreases, and as a result, there is a possibility that the productivity may be adversely affected. It is presumed that the water tracking ability can be improved by enhancing the hydrophobicity of the resist film (rendering the resist film hydrophobic).

Accordingly, it is presumed that the above characteristic problems of immersion lithography, which require a reduction in substance elution and an improvement in the water tracking ability, can be addressed by enhancing the hydrophobicity of the resist film surface. However, if the resist film is simply rendered hydrophobic, then adverse effects are seen on the lithography properties and the like. For example, as the hydrophobicity of the resist film is increased, defects tend to occur more readily on the resist film following alkali developing. Particularly in the case of a positive resist composition, defects tend to occur more readily in the unexposed portions of the resist. Here, the term “defects” describes general abnormalities within a resist film that are detected when observed from directly above the developed resist film using a surface defect detection apparatus (product name: “KLA”) manufactured by KLA-TENCOR Corporation. Examples of these “abnormalities” include post-developing scum, foam, dust, bridges (structures that bridge different portions of the resist pattern), color irregularities, foreign deposits, and residues.

It is considered that a material which is hydrophobic during immersion exposure but then becomes hydrophilic during developing can address the problems described above. However, materials exhibiting such properties are essentially unknown at present.

The present invention takes the above circumstances into consideration, with an object of providing a novel fluorine-containing copolymer that is useful as an additive for a resist composition for immersion exposure, a resist composition for immersion composure that includes the fluorine-containing copolymer, and a method of forming a resist pattern that uses the resist composition for immersion exposure.

In order to achieve the above object, the present invention employs the following aspects.

Specifically, a first aspect of the present invention is a resist composition for immersion exposure including a base component (A) that exhibits changed solubility in an alkali developing solution under the action of acid, an acid generator component (B) that generates acid upon exposure, and a fluorine-containing copolymer (C) containing a structural unit (c1) represented by general formula (c1-1) shown below.

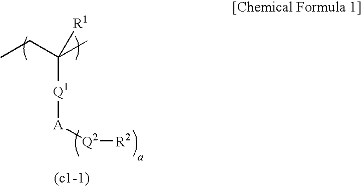

[wherein, R¹ represents a hydrogen atom, a lower alkyl group or a halogenated lower alkyl group, Q¹ represents a single bond or a divalent linking group, A represents an aromatic cyclic group that may have a substituent, Q² represents a group in which one hydrogen atom has been removed from a monovalent hydrophilic group, R² represents a base dissociable group, and a represents 1 or 2, provided that at least one among A and the a R² groups contains a fluorine atom.]

A second aspect of the present invention is a method of forming a resist pattern, including: forming a resist film on a substrate using a positive resist composition for immersion exposure according to the first aspect described above, conducting immersion exposure of the resist film, and alkali-developing the resist film to form a resist pattern.

A third aspect of the present invention is a fluorine-containing copolymer containing a structural unit (c1) represented by general formula (c1-1) shown below.

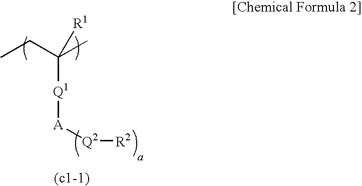

[wherein, R¹ represents a hydrogen atom, a lower alkyl group or a halogenated lower alkyl group, Q¹ represents a single bond or a divalent linking group, A represents an aromatic cyclic group that may have a substituent, Q² represents a group in which one hydrogen atom has been removed from a monovalent hydrophilic group, R² represents a base dissociable group, and a represents 1 or 2, provided that at least one among A and the a R² groups contains a fluorine atom.]

In the present specification and claims, a “structural unit” refers to a monomer unit that contributes to the formation of a resin component (namely, a polymer or copolymer).

The term “exposure” is used as a general concept that includes irradiation with any form of radiation.

An “alkyl group”, unless otherwise specified, includes linear, branched and cyclic, monovalent saturated hydrocarbon groups.

A “lower alkyl group” is an alkyl group of 1 to 5 carbon atoms.

According to the present invention, there are provided a novel fluorine-containing copolymer that is useful as an additive for a resist composition for immersion exposure, a resist composition for immersion exposure that includes the fluorine-containing copolymer, and a method of forming a resist pattern that uses the resist composition for immersion exposure.

### BRIEF DESCRIPTION OF THE DRAWINGS

FIG. 1 is a diagram describing an advancing angle (θ₁), a receding angle (θ₂) and a sliding angle (θ₃).

### DETAILED DESCRIPTION OF THE INVENTION

### <<Fluorine-Containing Compound>>

First is a description of a fluorine-containing copolymer of the third aspect of the present invention (hereafter frequently referred to as the “fluorine-containing copolymer (C)”). This fluorine-containing copolymer (C) is a copolymer that acts as a component of the resist composition for immersion exposure according to the first aspect of the present invention, and can be used favorably as an additive within resist compositions for immersion exposure.

Structural Unit (c1)

The fluorine-containing copolymer (C) contains a structural unit (c1) represented by general formula (c1-1) shown above.

In formula (c1-1), a represents 1 or 2, and is preferably 1.

In formula (c1-1), R¹ represents a hydrogen atom, a lower alkyl group or a halogenated lower alkyl group.

Specific examples of the lower alkyl group for R¹ include linear or branched lower alkyl groups such as a methyl group, ethyl group, propyl group, isopropyl group, n-butyl group, isobutyl group, tert-butyl group, pentyl group, isopentyl group and neopentyl group.

Specific examples of the halogenated lower alkyl group for R¹ include groups in which some or all of the hydrogen atoms of the aforementioned lower alkyl groups have been substituted with halogen atoms. Examples of the halogen atom include a fluorine atom, chlorine atom, bromine atom and iodine atom, and of these, a fluorine atom is particularly preferred.

R¹ is preferably a hydrogen atom, a lower alkyl group or a fluorinated lower alkyl group, and is more preferably a hydrogen atom or a methyl group.

In formula (c1-1), Q¹ is a single bond or a divalent linking group.

Examples of the divalent linking group for Q¹ include hydrocarbon groups, and groups that include a hetero atom.

Examples of the hydrocarbon groups include alkylene groups. The alkylene group may be either linear or branched. The alkylene group preferably has 1 to 12 carbon atoms, more preferably 1 to 5 carbon atoms, and still more preferably 1 to 3 carbon atoms. Specific examples of the alkylene group include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂—, —CH(CH₂CH₃)CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

A hetero atom refers to an atom other than a carbon atom or hydrogen atom, and examples thereof include an oxygen atom, nitrogen atom, sulfur atom or halogen atom. Examples of groups that include a hetero atom include —O—, —C(═O)—, —C(═O)—O—, —NH—, —NR⁰⁴— (wherein, R⁰⁴ is an alkyl group), —NH—C(═O)—, ═N—, and groups composed of a combination of one or more of these groups and a divalent hydrocarbon group. The alkyl group represented by R⁰⁴ is preferably a group of 1 to 10 carbon atoms, and more preferably 1 to 5 carbon atoms.

As Q¹, a single bond or —C(═O)—O— group is preferred, and a single bond is particularly desirable.

In formula (c1-1), A represents an aromatic cyclic group that may have a substituent. In other words, a group in which two hydrogen atoms have been removed from an aromatic hydrocarbon ring that may have a substituent. The cyclic structure of the aromatic cyclic structure of A preferably contains 6 to 15 carbon atoms, and examples thereof include a benzene ring, naphthalene ring, phenanthrene ring and anthracene ring. Of these, a benzene ring and a naphthalene ring are particularly preferred.

In A, examples of the substituent that may be bonded to the aromatic cyclic group include a halogen atom, alkyl group, alkoxy group, halogenated lower alkyl group, and an oxygen atom (═O). Examples of the halogen atom include a fluorine atom, chlorine atom, iodine atom or bromine atom. The alkyl group, alkoxy group or halogenated lower alkyl group preferably contains 1 to 10 carbon atoms, and more preferably 1 to 5 carbon atoms. As the substituent that may be bonded to the aromatic cyclic group, a fluorine atom is particularly desirable.

The aromatic cyclic group represented by A may or may not have a substituent, but a group having no substituent is preferred. In those cases where the aromatic cyclic group of A has a substituent, the number of substituents may be either 1, or 2 or more, but is preferably either 1 or 2, and is most preferably 1.

In formula (c1-1), in the group Q², there are no particular limitations on the monovalent hydrophilic group, provided it contains at least one hydrogen atom, and specific examples thereof include a hydroxyl group (—OH), a carboxyl group (—C(═O)OH) and an amino group (—NH₂).

Q² is a group in which one hydrogen atom has been removed from the above type of monovalent hydrophilic group, so that for example in the case where the monovalent hydrophilic group is an —OH group, Q² is an —O— group. If the monovalent hydrophilic group is —C(═O)OH, then Q² is —C(═O)O—. Further, if the monovalent hydrophilic group is —NH₂, then Q² is —NH—.

As Q², —O— or —C(═O)O— is preferred, and —O— is particularly desirable.

In formula (c1-1), R² represents a base dissociable group

In the present specification and claims, the term “base dissociable group” describes an organic group that can dissociate under the action of a base. In other words, a “base dissociable group” dissociates under the action of an alkali developing solution (for example, at 23° C. in a 2.38% by weight aqueous solution of TMAH). The fluorine-containing copolymer (C) includes a base dissociable group, and therefore under the action of an alkali developing solution, the base dissociable group dissociates, thereby generating a monovalent hydrophilic group (-A-Q²H in this case) and increasing the affinity of the copolymer relative to the alkali developing solution.

There are no particular limitations on the base dissociable group provided it satisfies the above definition. However, the structure of the fluorine-containing copolymer (C) must include at least one fluorine atom among A and the a R² groups. Accordingly, in those cases where the A group within the fluorine-containing copolymer (C) includes no fluorine atoms, at least one R² group is a base dissociable group having a fluorine atom. In those cases where the A group within the fluorine-containing copolymer (C) includes a fluorine atom, the R² group may or may not contain a fluorine atom.

As specific examples of the base dissociable group, one or more groups selected from among groups represented by general formulas (II-1) to (II-3) shown below are preferred, and in terms of exhibiting superior effects for the present invention, and ensuring ease of synthesis, groups represented by general formula (II-1) are particularly preferred.

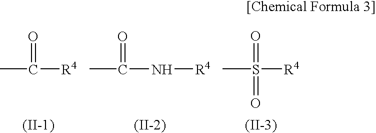

[wherein, each R⁴ independently represents a hydrocarbon group that may contain a fluorine atom.]

In formulas (II-1) to (II-3), R⁴ represents a hydrocarbon group that may contain a fluorine atom.

The hydrocarbon group represented by R⁴ may be an unsubstituted hydrocarbon group composed solely of carbon atoms and hydrogen atoms, or a fluorine-substituted hydrocarbon group in which some or all of the hydrogen atoms of the unsubstituted hydrocarbon group have been substituted with fluorine atoms.

The hydrocarbon group may be either an aliphatic hydrocarbon group or an aromatic hydrocarbon group.

In the present specification and claims, the term “aliphatic” is a relative concept used in relation to the term “aromatic”, and defines a group or compound or the like that has no aromaticity.

An aliphatic hydrocarbon group is a hydrocarbon group that has no aromaticity. The aliphatic hydrocarbon group may be either saturated or unsaturated, but is preferably saturated. In other words, the aliphatic hydrocarbon group is preferably an unsubstituted alkyl group or a fluorine-substituted alkyl group.

The unsubstituted alkyl group may be a linear, branched or cyclic group, or may be a combination of a linear or branched alkyl group and a cyclic alkyl group.

The unsubstituted linear alkyl group preferably contains 1 to 10 carbon atoms, and more preferably 1 to 8 carbon atoms. Specific examples include a methyl group, ethyl group, n-propyl group, n-butyl group, n-pentyl group, n-hexyl group, n-heptyl group, n-octyl group, n-nonyl group and n-decanyl group.

The unsubstituted branched alkyl group preferably contains 3 to 10 carbon atoms, and more preferably 3 to 8 carbon atoms. As the branched alkyl group, tertiary alkyl groups are preferred, and groups represented by general formula (III-1) shown below are particularly desirable.

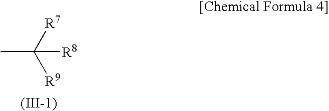

[wherein, R⁷ to R⁹ each independently represents a linear alkyl group of 1 to 5 carbon atoms.]

Each alkyl group represented by R⁷ to R⁹ is preferably an ethyl group or a methyl group, and is most preferably a methyl group.

The unsubstituted cyclic alkyl group preferably contains 4 to 15 carbon atoms, and more preferably 5 to 12 carbon atoms, and examples thereof include groups in which one hydrogen atom has been removed from a monocycloalkane, or a polycycloalkane such as a bicycloalkane, tricycloalkane or tetracycloalkane. Specific examples include monocycloalkyl groups such as a cyclopentyl group and cyclohexyl group, and polycycloalkyl groups such as an adamantyl group, norbornyl group, isobornyl group, tricyclodecanyl group and tetracyclododecanyl group.

Examples of the combination of an unsubstituted linear or branched alkyl group and a cyclic alkyl group include groups in which a cyclic alkyl group is bonded to a linear or branched alkyl group as a substituent, and groups in which a linear or branched alkyl group is bonded to a cyclic alkyl group as a substituent.

Examples of the fluorine-substituted alkyl group include groups in which some or all of the hydrogen atoms within an unsubstituted alkyl group described above have been substituted with fluorine atoms.

The fluorine-substituted alkyl group may be either a group in which some of the hydrogen atoms of the unsubstituted alkyl group have been substituted with fluorine atoms, or a group in which all of the hydrogen atoms of the unsubstituted alkyl group have been substituted with fluorine atoms (namely, a perfluoroalkyl group).

As the fluorinated alkyl group for R⁴, a linear or branched fluorine-substituted alkyl group is preferred, and a group represented by a formula —R⁴¹—R⁴² [wherein, R⁴¹ represents an unsubstituted alkylene group of 1 to 9 carbon atoms, and R⁴² represents a fluorine-substituted alkyl group of 1 to 9 carbon atoms, provided that the combined number of carbon atoms within R⁴¹ and R⁴² is not more than 10] is particularly preferred.

In the above formula, R⁴¹ is preferably a linear or branched alkylene group of 1 to 5 carbon atoms, and is more preferably a methylene group, ethylene group or propylene group.

R⁴² is preferably a linear or branched fluorine-substituted alkyl group of 1 to 5 carbon atoms, and a perfluoroalkyl group is particularly desirable. Of such groups, a trifluoromethyl group or pentafluoroethyl group is particularly preferred.

When R⁴ is an aromatic cyclic group, R⁴ represents an aromatic cyclic group that may have a substituent. In other words, a group in which one hydrogen atom has been removed from an aromatic hydrocarbon ring that may have a substituent. The cyclic structure of the aromatic cyclic group of R⁴ preferably contains 6 to 15 carbon atoms, and examples thereof include a benzene ring, naphthalene ring, phenanthrene ring and anthracene ring. Of these, a benzene ring and a naphthalene ring are particularly preferred.

In R⁴, examples of the substituent that may be bonded to the aromatic cyclic group include a halogen atom, alkyl group, alkoxy group, halogenated lower alkyl group, and an oxygen atom (═O). Examples of the halogen atom include a fluorine atom, chlorine atom, iodine atom or bromine atom. The alkyl group, alkoxy group or halogenated lower alkyl group preferably contains 1 to 10 carbon atoms, and more preferably 1 to 5 carbon atoms.

As the structural unit (c1), structural units represented by general formula (c1-1-1) shown below and structural units represented by general formula (c1-1-2) shown below are preferred.

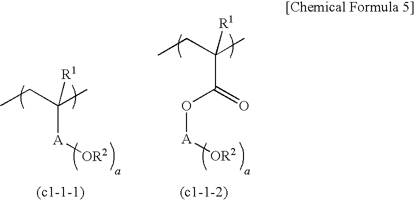

[wherein, R¹, R², A and a are as defined above for formula (c1-1).]

Of the structural units represented by general formula (c1-1-1), structural units represented by general formula (c1-1-11) and structural units represented by general formula (c1-1-12) shown below are preferred.

Of the structural units represented by general formula (c1-1-2), structural units represented by general formula (c1-1-21) and structural units represented by general formula (c1-1-22) shown below are preferred.

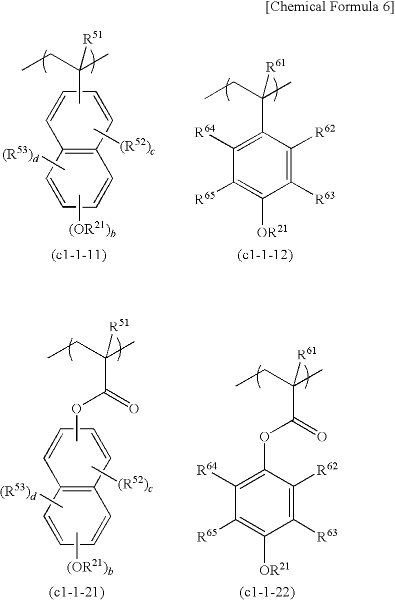

[wherein, R⁵¹ and R⁶¹ each represents a hydrogen atom, a lower alkyl group or a halogenated lower alkyl group, R²¹ represents a base dissociable group having at least one fluorine atom, R⁵² and R⁵³ each independently represents a substituent, R⁶² to R⁶⁵ each independently represents a hydrogen atom or a fluorine atom, b represents either 1 or 2, c represents an integer of 0 to 3, and d represents an integer of 0 to 3, provided that b+d is an integer of 1 to 4.]

Examples of the groups R⁵¹ and R⁶¹ include the same groups as those exemplified above for R¹. R⁵¹ and R⁶¹ each preferably represents a hydrogen atom, a lower alkyl group or a fluorinated lower alkyl group, and is most preferably a hydrogen atom or a methyl group.

R²¹ represents a base dissociable group having at least one fluorine atom. Examples of R²¹ include those groups among the groups exemplified above for the base dissociable group of R² that also include a fluorine atom.

Examples of the substituents of R⁵² and R⁵³ include the same groups as those exemplified above for the substituent that may be bonded to the aromatic cyclic group within the group A, and of these, a fluorine atom is preferred.

In formulas (c1-1-11) and (c1-1-21), if factors such as the ease of production are taken into consideration, then c and d are preferably both zero. Further, R⁵² and R⁵³ are preferably both fluorine atoms, c is preferably 3, and d is preferably 4-b.

R⁶² to R⁶⁵ each independently represents a hydrogen atom or a fluorine atom. In formulas (c1-1-12) and (c1-1-22), if factors such as the ease of production are taken into consideration, then structural units in which R⁶² to R⁶⁵ are all hydrogen atoms, or structural units in which R⁶² to R⁶⁵ are all fluorine atoms are preferred.

In the fluorine-containing copolymer (C), the structural unit (c1) is preferably represented by one or more of general formulas (c1-1-11), (c1-1-112), (c1-1-121), (c1-1-122), (c1-1-211), (c1-1-212), (c1-1-221) and (c1-1-222) shown below, and more preferably one or more of general formulas (c1-1-111), (c1-1-112), (c1-1- 121) and (c1-1-122).

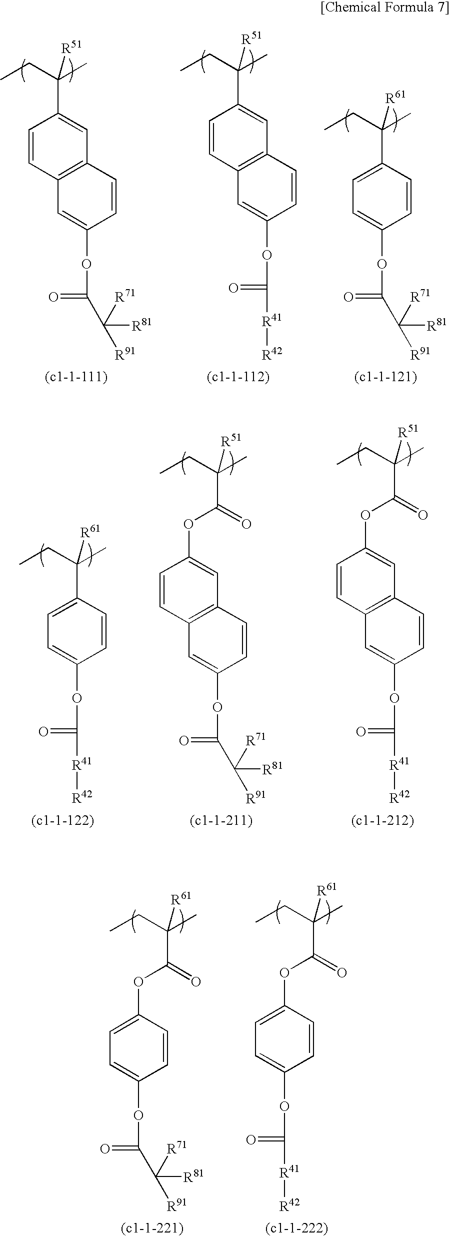

[wherein, R⁵¹, R⁶¹, R⁴¹ and R⁴² are as defined above. R⁷¹, R⁸¹ and R⁹¹ each independently represents a linear alkyl group of 1 to 5 carbon atoms, provided that at least one of R⁷¹, R⁸¹ and R⁹¹ contains a fluorine atom.]

As the alkyl group for R⁷¹, R⁸¹ and R⁹¹, an ethyl group or methyl group is preferred, and a methyl group is particularly desirable. Of the alkyl groups represented by R⁷¹, R⁸¹ and R⁹¹, any one group must be a fluorine-substituted alkyl group, although all the groups may also be fluorine-substituted groups.

In the fluorine-containing copolymer (C), one type of structural unit may be used as the structural unit (c1), or two or more types may be used in combination.

The proportion of the structural unit (c1) within the fluorine-containing copolymer (C), relative to the combined total of all the structural units that constitute the fluorine-containing copolymer (C), is preferably at least 10 mol % but less than 100 mol %, is more preferably at least 50 mol % but less than 100 mol %, still more preferably at least 60 mol % but less than 100 mol %, and is most preferably from 60 to 90 mol %.

Structural Unit (c2)

The fluorine-containing copolymer (C) is a copolymer that includes other structural units besides the structural unit (c1). As this other structural unit besides the structural unit (c1) within the fluorine-containing copolymer (C), a structural unit (c2) containing an acid dissociable group is preferred.

In the present specification and claims, the term “acid dissociable group” describes an organic group that can dissociate under the action of acid. There are no particular limitations on the acid dissociable group contained within the structural unit (c2), provided it is an organic group that can dissociate under the action of acid, and examples include any of the groups that have been proposed as acid dissociable, dissolution inhibiting groups for the base resins of chemically amplified resists. Specific examples include the same groups as those exemplified below for the acid dissociable, dissolution inhibiting group within a structural unit (a1). There are no particular limitations on the structure of the main chain of the structural unit (c2), and examples include structural units derived from styrene and structural units derived from (meth)acrylic acid.

In the fluorine-containing copolymer (C), the structural unit (c2) is preferably a structural unit represented by general formula (c2-1) shown below.

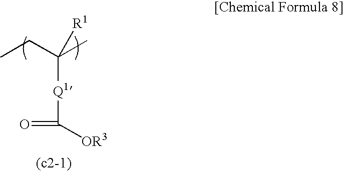

[wherein, R¹ represents a hydrogen atom, a lower alkyl group or a halogenated lower alkyl group, Q¹′ represents a single bond or a divalent linking group, and R³ represents an acid dissociable group.]

In formula (c2-1), R¹ represents a hydrogen atom, a lower alkyl group or a halogenated lower alkyl group. Examples of the lower alkyl group and halogenated lower alkyl group for R¹ include the same groups as those exemplified above for R¹ in formula (c1-1).

In formula (c2-1), Q¹′ represents a single bond or a divalent linking group. Examples of the divalent linking group for Q¹′ include the same groups as those exemplified for Q¹ in formula (c1-1) or divalent aromatic hydrocarbon groups. Examples of the divalent aromatic hydrocarbon group include aromatic hydrocarbon groups of 6 to 20 carbon atoms, including groups in which two hydrogen atom have been removed from benzene, naphthalene or anthracene. In the structural unit (c2), Q¹′ preferably represents either a single bond or —C(═O)—O—R^{c}— [wherein, R^{c} represents a linear or branched alkylene group of 1 to 10 carbon atoms that may include an oxygen atom], and a single bond is particularly desirable.

In formula (c2-1), R³ represents an acid dissociable group. There are no particular limitations on the acid dissociable group for R³ provided it is an organic group that can dissociate under the action of acid, and examples thereof include a cyclic or chain-like tertiary alkyl ester-type acid dissociable group, or an acetal-type acid dissociable group such as an alkoxyalkyl group. Of these, in the fluorine-containing copolymer (C), R³ is preferably a tertiary alkyl ester-type acid dissociable group, and is more preferably a group represented by general formula (IV-1) shown below.

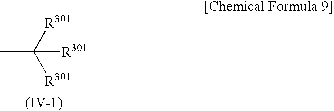

[wherein, the plurality of R³⁰¹ groups may be the same or different, provided that at least one of the R³⁰¹ groups represents a linear or branched alkyl group of 1 to 4 carbon atoms; and the remaining two R³⁰¹ groups each independently represents a linear or branched alkyl group of 1 to 4 carbon atoms or a monovalent aliphatic cyclic group of 4 to 20 carbon atoms, or alternatively, the remaining two R³⁰¹ groups are bonded together to form a divalent aliphatic cyclic group of 4 to 20 carbon atoms together with the carbon atom to which both groups are bonded.]

Examples of the aliphatic cyclic group include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane or cyclohexane, or a polycycloalkane such as adamantane, norbornane, isobornane, tricyclodecane or tetracyclododecane. More specific examples include a cyclopentyl group, cyclohexyl group, norbornyl group and adamantyl group.

Examples of the linear or branched alkyl group of 1 to 4 carbon atoms include a methyl group, ethyl group, propyl group, isopropyl group, n-butyl group, isobutyl group and tert-butyl group.

Of the acid dissociable groups represented by general formula (IV-1), examples of groups in which the plurality of R³⁰¹ groups each independently represents a linear or branched alkyl group of 1 to 4 carbon atoms include a tert-butyl group, tert-pentyl group and tert-hexyl group.

Of the acid dissociable groups represented by general formula (IV-1), examples of groups in which at least one of the plurality of R³⁰¹ groups represents a linear or branched alkyl group of 1 to 4 carbon atoms, and the remaining two R³⁰¹ groups each independently represents a linear or branched alkyl group of 1 to 4 carbon atoms or a monovalent aliphatic cyclic group of 4 to 20 carbon atoms include a 1-(1-adamantyl)-1-methylethyl group, 1-(1-adamantyl)-1-methylpropyl group, 1-(1-adamantyl)-1-methylbutyl group, 1-(1-adamantyl)-1-methylpentyl group, 1-(1-cyclopentyl)-1-methylethyl group, 1-(1-cyclopentyl)-1-methylpropyl group, 1-(1-cyclopentyl)-1-methylbutyl group, 1-(1-cyclopentyl)-1-methylpentyl group, 1-(1-cyclohexyl)-1-methylethyl group, 1-(1-cyclohexyl)-1-methylpropyl group, 1-(1-cyclohexyl)-1-methylbutyl group, and 1-(1-cyclohexyl)-1-methylpentyl group.

Of the acid dissociable groups represented by general formula (IV-1), examples of groups in which one of the plurality of R³⁰¹ groups represents a linear or branched alkyl group of 1 to 4 carbon atoms, and the remaining two R³⁰¹ groups are bonded together to form a divalent aliphatic cyclic group of 4 to 20 carbon atoms together with the carbon atom to which both groups are bonded include 2-alkyl-2-adamantyl groups such as a 2-methyl-2-adamantyl group and 2-ethyl-2-adamantyl group, and 1-alkyl-1-cycloalkyl groups such as a 1-methyl-1-cyclopentyl group, 1-ethyl-1-cyclopentyl group, 1-methyl-1-cyclohexyl group, and 1-ethyl-1-cyclohexyl group.

Of the above possibilities, the acid dissociable group represented by general formula (IV-1) is preferably a group in which one of the R³⁰¹ groups represents a linear or branched alkyl group of 1 to 4 carbon atoms, and the remaining two R³⁰¹ groups are bonded together to form a divalent aliphatic cyclic group of 4 to 20 carbon atoms together with the carbon atom to which both groups are bonded, and a 2-methyl-2-adamantyl group is particularly desirable.

Further, provided the group represented by general formula (IV-1) is able to function as an acid dissociable group, each of the R³⁰¹ groups may have a substituent. Examples of the substituent include a halogen atom such as a fluorine atom.

In formula (c2-1), examples of preferred structural units in which Q¹′ represents a single bond include structural units represented by general formulas (c2-1-1) to (c2-1-12) shown below.

Further, in formula (c2-1), examples of preferred structural units in which Q¹′ represents —C(═O)—O—R^{c}— include structural units represented by general formulas (c2-1-13) to (c2-1-24) shown below.

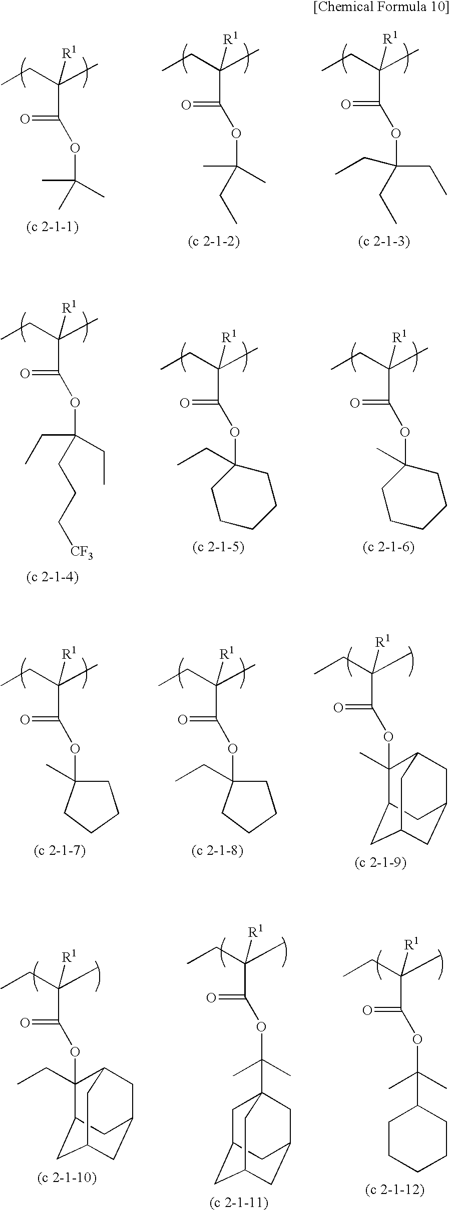

[wherein, R¹ is as defined above for formula (c2-1).]

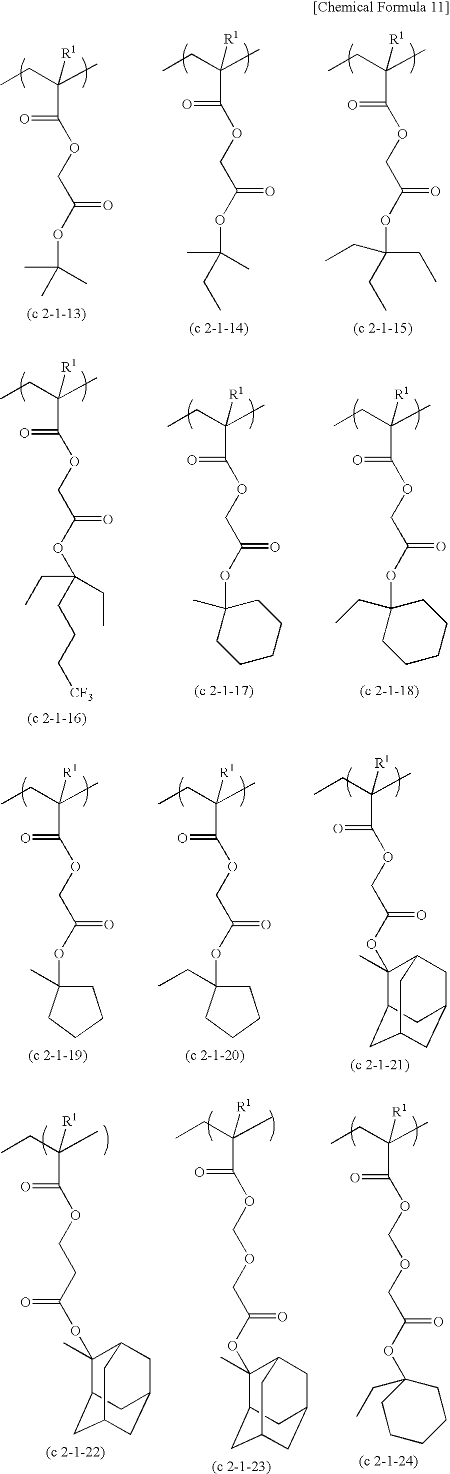

[wherein, R¹ is as defined above for formula (c2-1).]

In the fluorine-containing copolymer (C), the structural unit (c2) is preferably a unit represented by one or more of general formulas (c2-1-1) to (c2-1-12), and more preferably one or more of general formulas (c2-1-1) to (c2-1-5).

In the fluorine-containing copolymer (C), one type of structural unit may be used as the structural unit (c2), or two or more types may be used in combination.

The proportion of the structural unit (c2) within the fluorine-containing copolymer (C) is preferably smaller than the proportion of the structural unit (c1). For example, relative to the combined total of all the structural units that constitute the fluorine-containing copolymer (C), the proportion of the structural unit (c2) is preferably at least 1 mol % but less than 50 mol %, is more preferably from 5 to 45 mol %, and is still more preferably from 10 to 40 mol %.

Structural Unit (c3)

The fluorine-containing copolymer (C) may also include a structural unit (c3) besides the structural units (c1) and (c2), provided that inclusion of the structural unit (c3) does not impair the effects of the present invention. There are no particular limitations on this other structural unit, although structural units represented by general formula (c0-1) shown below are preferred. Other examples include structural units (a1) to (a4), which are potential structural units for a resin component (A1) in a resist composition for immersion exposure described below, structural units derived from hydroxystyrene, and structural units derived from styrene.

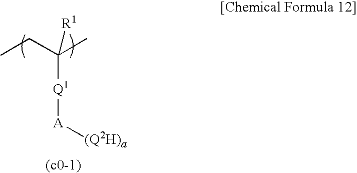

[wherein, R¹, Q¹, A, Q² and a are as defined above for formula (c1-1).]

The weight average molecular weight (Mw) (the polystyrene equivalent value determined by gel permeation chromatography) of the fluorine-containing copolymer (C) is not particularly limited, but is preferably from 2,000 to 50,000, more preferably from 3,000 to 30,000, and most preferably from 5,000 to 20,000. Provided the weight average molecular weight is less than the upper limit of the above-mentioned range, the copolymer (C) exhibits satisfactory solubility in the resist solvent when used as a resist, whereas ensuring that the weight average molecular weight is larger than the lower limit of the above range yields a more favorable dry etching resistance and cross-sectional shape for the resist pattern.

Further, the degree of dispersion (Mw/Mn) is preferably from 1.0 to 5.0, more preferably from 1.0 to 3.0, and most preferably from 1.2 to 2.5. Here, Mn represents the number average molecular weight.

### <Method of Producing Fluorine-Containing Copolymer (C)>

The fluorine-containing copolymer (C) can be obtained by conducting a conventional radical polymerization or the like of the monomers that give rise to each of the desired structural units, using a radical polymerization initiator such as azobisisobutyronitrile (AIBN) or dimethyl-2,2′-azobis(2-methylpropionate) (V-601, a product name, manufactured by Wako Pure Chemical Industries, Ltd.).

Examples of the monomer that gives rise to the structural unit (c1) include monomers represented by general formula (c1-0) shown below (hereafter referred to as the “fluorine-containing compound (C0)”).

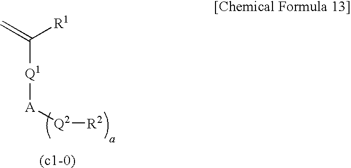

[wherein, R¹, Q¹, A, Q², R² and a are as defined above for formula (c1-1).]

The fluorine-containing compound (C0) can be produced, for example, by introducing a base dissociable group —R² [wherein, R² is as defined above] at the hydrophilic group -Q²H within a monomer represented by general formula (c1-0-0) shown below (hereafter referred to as “monomer (V-1)”). This introduction of a group represented by —R² can be conducted using conventional methods. For example, the fluorine-containing compound (C0) can be produced by reacting the monomer (V-1) with a compound (V-2) represented by general formula (V-2) shown below.

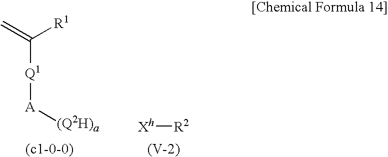

[wherein, R¹, Q¹, A, Q², R² and a are as defined above for formula (c1-1), and X^{h} represents a halogen atom or a hydroxyl group.]

Examples of the halogen atom for X^{h} include a bromine atom, chlorine atom, iodine atom or fluorine atom. In terms of ensuring superior reactivity, X^{h} is preferably a bromine atom or a chlorine atom, and is most preferably a chlorine atom.

There are no particular limitations on the method used for reacting the monomer (V-1) and the compound (V-2), and for example, a method may be used in which the monomer (V-1) and the compound (V-2) are brought into contact within a reaction solvent, in the presence of a base. In those cases where X^{h} is a halogen atom, this method can be executed by adding the compound (V-2), in the presence of a base, to a solution prepared by dissolving the monomer (V-1) in a reaction solvent. Further, in the case where X^{h} represents a hydroxyl group, the monomer (V-1) and the compound (V-2) can be reacted (via a condensation reaction) by adding the monomer (V-1), in the presence of a base and a condensation agent, to a solution prepared by dissolving the compound (V-2) in a reaction solvent. Furthermore, when X^{h} represents a hydroxyl group, the monomer (V-1) and the compound (V-2) may also be reacted (via a condensation reaction) by adding the monomer (V-1), in the presence of an acid, to a solution prepared by dissolving the compound (V-2) in a reaction solvent.

As the monomer (V-1) and the compound (V-2), either commercially available products or synthesized compounds may be used.

As the reaction solvent, any solvent that is capable of dissolving the monomer (V-1) and the compound (V-2) that act as the raw materials may be used, and specific examples of the solvent include tetrahydrofuran (THF), acetone, dimethylformamide (DMF), dimethylacetamide, dimethylsulfoxide (DMSO) and acetonitrile.

Examples of the base include organic bases such as triethylamine, 4-dimethylaminopyridine (DMAP) and pyridine, as well as inorganic bases such as sodium hydride, K₂CO₃ and Cs₂CO₃.

As the acid, those acids typically used within dehydration-condensation reactions can be used, and specific examples include inorganic acids such as hydrochloric acid, sulfuric acid and phosphoric acid, and organic acids such as methanesulfonic acid, trifluoromethanesulfonic acid, benzenesulfonic acid and p-toluenesulfonic acid. These acids may be used alone, or in combinations containing two or more different acids.

Examples of the condensation agent include carbodiimide reagents such as ethyldiisopropylaminocarbodiimide (EDCI) hydrochloride, dicyclohexylcarbodiimide (DCC), diisopropylcarbodiimide and carbodiimidazole, as well as tetraethyl pyrophosphate and benzotriazole-N-hydroxytrisdimethylaminophosphonium hexafluorophosphate (Bop reagent).

The amount added of the compound (V-2) relative to the monomer (V-1) is preferably within a range from 1 to 3 equivalents, and more preferably from 1 to 2 equivalents.

The reaction temperature is preferably within a range from −20 to 40° C., and more preferably from 0 to 30° C.

The reaction time varies depending on factors such as the reactivity of the monomer (V-1) and compound (V-2) and the reaction temperature, but is preferably within a range from 30 to 240 minutes, and more preferably from 60 to 180 minutes.

Furthermore, the monomer that gives rise to the structural unit (c2) can be obtained by introducing an acid dissociable group into a compound having a polymerizable group. There are no particular limitations on the method used for introducing the acid dissociable group, and conventional methods may be used. For example, a method may be used in which a hydrogen atom of a compound having a polymerizable group is substituted with an acid dissociable group. As the polymerizable group, the types of polymerizable group typically used in monomers can be used, and specific examples include groups having a ethylenic unsaturated double bond.

Moreover, the fluorine-containing copolymer (C) may also be produced by introducing a —R² group such as a group represented by one of the above general formulas (II-1) to (II-3) [wherein, R² is as defined above] at the hydrophilic group of a copolymer having hydrophilic groups represented by -Q²H [wherein, Q² is as defined above] (for example, a hydroxystyrene-based resin such as a polyhydroxystyrene or an acrylic resin).

The fluorine-containing copolymer (C) of the present invention described above is a novel compound that has been unknown until now.

The fluorine-containing copolymer (C) can be used favorably as an additive for a resist composition, and a resist composition containing the added fluorine-containing copolymer (C) is useful as a resist composition for immersion exposure.

There are no particular limitations on the resist composition containing the added fluorine-containing copolymer (C), provided the composition can be used for immersion exposure, although a chemically amplified resist composition including a base component that exhibits changed solubility in an alkali developing solution under the action of acid, and an acid generator component that generates acid upon irradiation is ideal.

The fluorine-containing copolymer (C) is ideal for use within the resist composition for immersion exposure according to the present invention described below.

### <<Resist Composition for Immersion Exposure>>

Next is a description of the resist composition for immersion exposure according to the first aspect of the present invention.

The resist composition for immersion exposure according to the present invention includes a base component (A) (hereafter, referred to as “component (A)”) that exhibits changed solubility in an alkali developing solution under the action of acid, an acid generator component (B) (hereafter, referred to as “component (B)”) that generates acid upon exposure, and a fluorine-containing copolymer (C) (hereafter, referred to as “component (C)”) containing a structural unit (c1) represented by general formula (c1-1) shown above.

### <Component (A)>

As the component (A), either a single organic compound typically used as a base component for a chemically amplified resist may be used, or a mixture of two or more such organic compounds may be used.

The term “base component” refers to an organic compound capable of forming a film, and preferably refers to an organic compound having a molecular weight of 500 or more. When the organic compound has a molecular weight of 500 or more, the film-forming ability is improved, and a nano level resist pattern can be readily formed.

Organic compounds having a molecular weight of 500 or more that may be used as the base component can be broadly classified into low molecular weight organic compounds having a molecular weight of at least 500 but less than 2,000 (namely, “low molecular weight materials”) and high molecular weight organic compounds having a molecular weight of 2,000 or more (namely, “polymer materials”). Generally, a non-polymer is used as the low molecular weight material. A resin (polymer or copolymer) is used as the polymer material, and the “molecular weight” of the polymer material refers to the polystyrene equivalent weight average molecular weight determined by GPC (gel permeation chromatography). Hereafter, the simplified term “resin” refers to a resin having a molecular weight of 2,000 or more.

The component (A) may be either a resin that exhibits changed alkali solubility under the action of acid, or a low molecular weight material that exhibits changed alkali solubility under the action of acid.

In those cases where the resist composition for immersion exposure according to the present invention is a negative resist composition, a base component that is soluble in an alkali developing solution is used as the component (A), and a cross-linker is blended into the negative resist composition.

In the negative resist composition, when acid is generated from the component (B) upon exposure, the action of this acid causes cross-linking between the base component and the cross-linker, and the cross-linked portion becomes substantially insoluble in alkali. As a result, during resist pattern formation, when a resist film obtained by applying the negative resist composition to a substrate is selectively exposed, the exposed portions of the resist become substantially insoluble in an alkali developing solution, whereas the unexposed portions remain soluble in the alkali developing solution, meaning a resist pattern can be formed by alkali developing.

As the component (A) of the negative resist composition, a resin that is soluble in an alkali developing solution (hereafter frequently referred to as an “alkali-soluble resin”) is usually used.

As the alkali-soluble resin, it is preferable to use a resin having structural units derived from at least one of an α-(hydroxyalkyl)acrylic acid and a lower alkyl ester of an α-(hydroxyalkyl)acrylic acid, as such resins enable the formation of a satisfactory resist pattern with minimal swelling. Here, the term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the cross-linker, typically, an amino-based cross-linker such as a glycoluril having a methylol group or alkoxymethyl group is preferable, as it enables the formation of a resist pattern with minimal swelling. The amount of the cross-linker added is preferably within a range from 1 to 50 parts by weight relative to 100 parts by weight of the alkali-soluble resin.

When the resist composition for immersion exposure according to the present invention is a positive resist composition, as the component (A), a base component that exhibits increased solubility in an alkali developing solution under the action of acid is used. More specifically, the component (A) is substantially insoluble in an alkali developing solution prior to exposure, but when acid is generated from the component (B) upon exposure, the action of this acid causes an increase in the solubility of the base component in an alkali developing solution. Accordingly, during resist pattern formation, when a resist film formed by applying the positive resist composition to a substrate is selectively exposed, the exposed portions change from being substantially insoluble in an alkali developing solution to being alkali-soluble, whereas the unexposed portions remain substantially alkali-insoluble, meaning a resist pattern can be formed by alkali developing.

In the resist composition of the present invention, the component (A) is preferably a base component that exhibits increased solubility in an alkali developing solution under the action of acid. Namely, the resist composition of the present invention is preferably a positive resist composition.

The component (A) may be a resin component (A1) that exhibits increased solubility in an alkali developing solution under the action of acid (hereafter, frequently referred to as “component (A1)”), a low molecular weight material (A2) that exhibits increased solubility in an alkali developing solution under the action of acid (hereafter, frequently referred to as “component (A2)”), or a mixture thereof.

### [Component (A1)]

As the component (A1), either a single resin component (base resin) typically used as a base component for a chemically amplified resist may be used, or a mixture of two or more such resin components may be used.

In the present invention, as the component (A1), a resin containing a structural unit derived from an acrylate ester is preferred.

In the present specification and the claims, the expression “structural unit derived from an acrylate ester” refers to a structural unit that is formed by cleavage of the ethylenic double bond of an acrylate ester.

The term “acrylate ester” is a generic term that includes the acrylate ester having a hydrogen atom bonded to the carbon atom on the α-position, and acrylate esters having a substituent (an atom other than a hydrogen atom or a group) bonded to the carbon atom on the α-position. Examples of the substituent include a lower alkyl group or a halogenated lower alkyl group.

In a structural unit derived from an acrylate ester, the “α-position” (the carbon atom on the α-position), unless specified otherwise, refers to the carbon atom having the carbonyl group bonded thereto.

In the acrylate ester, specific examples of the lower alkyl group for the substituent at the α-position include linear or branched lower alkyl groups such as a methyl group, ethyl group, propyl group, isopropyl group, n-butyl group, isobutyl group, tert-butyl group, pentyl group, isopentyl group and neopentyl group.

Further, specific examples of the halogenated lower alkyl group include groups in which some or all of the hydrogen atoms of the above “lower alkyl group for the substituent at the α-position” are substituted with halogen atoms. Examples of the halogen atom include a fluorine atom, chlorine atom, bromine atom and iodine atom, and a fluorine atom is particularly desirable.

In the present invention, it is preferable that a hydrogen atom, a lower alkyl group or a halogenated lower alkyl group, and more preferably a hydrogen atom, a lower alkyl group or a fluorinated lower alkyl group, is bonded to the α-position of the acrylate ester. In terms of industrial availability, a hydrogen atom or a methyl group is the most desirable.

The component (A1) preferably includes a structural unit (a1) derived from an acrylate ester containing an acid dissociable, dissolution inhibiting group.

Further, in addition to this structural unit (a1), the component (A1) preferably also includes a structural unit (a2) derived from an acrylate ester that contains a lactone-containing cyclic group.

Moreover, in addition to the structural unit (a1), or in addition to the combination of the structural units (a1) and (a2), the component (A1) preferably also includes a structural unit (a3) derived from an acrylate ester that contains a polar group-containing aliphatic hydrocarbon group.

Structural Unit (a1)

As the acid dissociable, dissolution inhibiting group within the structural unit (a1), any of the groups that have been proposed as acid dissociable, dissolution inhibiting groups for the base resins of chemically amplified resists can be used, provided the group has an alkali dissolution inhibiting effect that renders the entire component (A1) insoluble in an alkali developing solution prior to dissociation, and then following dissociation under the action of acid, increases the solubility of the entire component (A1) in the alkali developing solution. Generally, groups that form either a cyclic or chain-like tertiary alkyl ester with the carboxyl group of (meth)acrylic acid or the like, and acetal-type acid dissociable, dissolution inhibiting groups such as alkoxyalkyl groups are widely known.

Here, a “tertiary alkyl ester” describes a structure in which an ester is formed by substituting the hydrogen atom of a carboxyl group with a chain-like or cyclic alkyl group, and a tertiary carbon atom within the chain-like or cyclic alkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable, dissolution inhibiting groups”.

Examples of these tertiary alkyl ester-type acid dissociable, dissolution inhibiting groups include aliphatic branched, acid dissociable, dissolution inhibiting groups and aliphatic cyclic group-containing acid dissociable, dissolution inhibiting groups.

The term “aliphatic branched” refers to a branched structure having no aromaticity. The structure of the “aliphatic branched, acid dissociable, dissolution inhibiting group” is not limited to structures composed solely of carbon atoms and hydrogen atoms (namely, not limited to hydrocarbon groups), but is preferably a hydrocarbon group. Further, the “hydrocarbon group” may be either saturated or unsaturated, but is preferably saturated.

Examples of aliphatic branched, acid dissociable, dissolution inhibiting groups include tertiary alkyl groups of 4 to 8 carbon atoms, and specific examples include a tert-butyl group, tert-pentyl group and tert-heptyl group.

The term “aliphatic cyclic group” refers to a monocyclic group or polycyclic group that has no aromaticity.

The “aliphatic cyclic group” within the structural unit (a1) may or may not have a substituent. Examples of the substituent include lower alkyl groups of 1 to 5 carbon atoms, lower alkoxy groups of 1 to 5 carbon atoms, a fluorine atom, fluorinated lower alkyl groups of 1 to 5 carbon atoms, and an oxygen atom (═O).

The basic ring structure of the “aliphatic cyclic group” exclusive of substituents is not limited to structures composed solely of carbon and hydrogen (namely, not limited to hydrocarbon groups), but is preferably a hydrocarbon group. Further, the “hydrocarbon group” may be either saturated or unsaturated, but is preferably saturated. Furthermore, the “aliphatic cyclic group” is preferably a polycyclic group.

The aliphatic cyclic group preferably contains 4 to 20 carbon atoms, and examples thereof include groups in which one or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated lower alkyl group. Specific examples include groups in which one or more hydrogen atoms have been removed from either a monocycloalkane such as cyclopentane or cyclohexane, or a polycycloalkane such as adamantane, norbornane, isobornane, tricyclodecane or tetracyclododecane.

Examples of the aliphatic cyclic group-containing acid dissociable, dissolution inhibiting group include groups having a tertiary carbon atom on the ring structure of the cyclic alkyl group. Specific examples include a 2-methyl-2-adamantyl group and a 2-ethyl-2-adamantyl group. Alternatively, groups having an aliphatic cyclic group such as an adamantyl group, cyclohexyl group, cyclopentyl group, norbornyl group, tricyclodecanyl group or tetracyclododecanyl group, and a branched alklene group with a tertiary carbon atom bonded to the aliphatic cyclic group, such as the groups bonded to the oxygen atom of the carbonyloxy group (—C(O)—O—) in the structural units represented by general formulas (a1″-1) to (a1″-6) shown below, may also be exemplified.

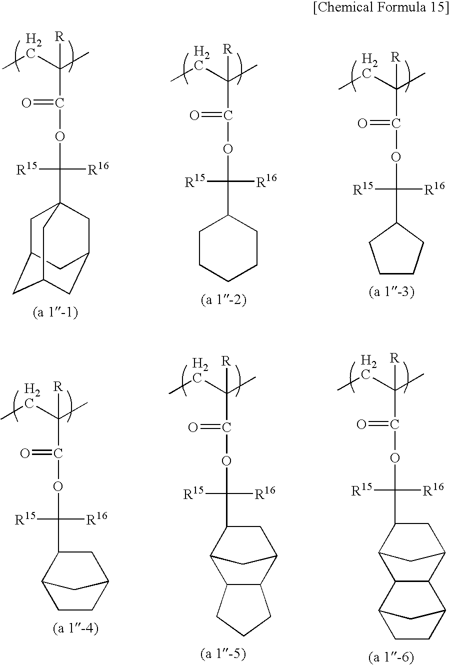

[wherein, R represents a hydrogen atom, a lower alkyl group or a halogenated lower alkyl group; and R¹⁵ and R¹⁶ each represents an alkyl group (which may be linear or branched, and preferably has 1 to 5 carbon atoms).]

In general formulas (a1″-1) to (a1″-6) above, the lower alkyl group or halogenated lower alkyl group for R is the same as the lower alkyl group or halogenated lower alkyl group that may be bonded to the α-position of the aforementioned acrylate ester.

An “acetal-type acid dissociable, dissolution inhibiting group” is generally substituted in place of a hydrogen atom at the terminal of an alkali-soluble group such as a carboxyl group or hydroxyl group, and is therefore bonded to an oxygen atom. When acid is generated upon exposure, the generated acid cleaves the bond between the acetal-type acid dissociable, dissolution inhibiting group and the oxygen atom to which the acetal-type, acid dissociable, dissolution inhibiting group is bonded.

Examples of acetal-type acid dissociable, dissolution inhibiting groups include groups represented by general formula (p1) shown below.

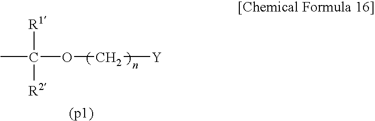

[wherein, R¹′ and R²′ each independently represents a hydrogen atom or a lower alkyl group, n represents an integer of 0 to 3, and Y represents a lower alkyl group or an aliphatic cyclic group.]

In general formula (p1) above, n is preferably an integer of 0 to 2, more preferably 0 or 1, and is most preferably 0.

Examples of the lower alkyl group for R¹′ and R²′ include the same lower alkyl groups as those exemplified above for the group R, and of these, a methyl group or ethyl group is preferred, and a methyl group is particularly desirable.

In the present invention, at least one of R¹′ and R²′ is preferably a hydrogen atom. That is, it is preferable that the acid dissociable, dissolution inhibiting group (p1) is a group represented by general formula (p1-1) shown below.

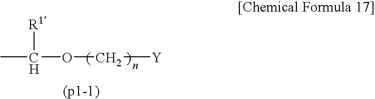

[wherein R¹′, n and Y are as defined above.]

Examples of the lower alkyl group for Y include the same lower alkyl groups as those exemplified above for the group R.

As the aliphatic cyclic group for Y, any of the monocyclic or polycyclic aliphatic cyclic groups that have been proposed for conventional ArF resists and the like can be appropriately selected for use. For example, the same groups as those described above in relation to the “aliphatic cyclic group” may be exemplified.

Further, examples of the acetal-type, acid dissociable, dissolution inhibiting group also include groups represented by general formula (p2) shown below.

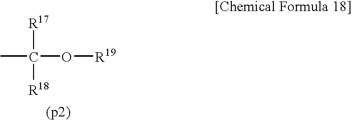

[wherein, R¹⁷ and R¹⁸ each independently represents a linear or branched alkyl group or a hydrogen atom, and R¹⁹ represents a linear, branched or cyclic alkyl group. Alternatively, R¹⁷ and R¹⁹ may each independently represent a linear or branched alkylene group, wherein the terminal of R¹⁷ is bonded to the terminal of R¹⁹ to form a ring.]

The alkyl group for R¹⁷ and R¹⁸ preferably contains 1 to 15 carbon atoms, may be either linear or branched, is preferably either an ethyl group or a methyl group, and is most preferably a methyl group.

Groups in which one of R¹⁷ and R¹⁸ is a hydrogen atom and the other is a methyl group are particularly desirable.

R¹⁹ represents a linear, branched or cyclic alkyl group which preferably contains 1 to 15 carbon atoms, and may be any of linear, branched or cyclic.

When R¹⁹ represents a linear or branched alkyl group, it is preferably an alkyl group of 1 to 5 carbon atoms, is more preferably an ethyl group or methyl group, and is most preferably an ethyl group.

When R¹⁹ represents a cyclic alkyl group, it preferably contains 4 to 15 carbon atoms, more preferably 4 to 12 carbon atoms, and most preferably 5 to 10 carbon atoms. Examples of the cyclic alkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from either a monocycloalkane such as cyclopentane or cyclohexane, or a polycycloalkane such as adamantane, norbornane, isobornane, tricyclodecane or tetracyclododecane. Of these, a group in which one or more hydrogen atoms have been removed from adamantane is preferred.

In general formula (p2) above, R¹⁷ and R¹⁹ may each independently represent a linear or branched alkylene group (preferably an alkylene group of 1 to 5 carbon atoms), wherein the terminal of R¹⁹ is bonded to the terminal of R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of this type of cyclic group include a tetrahydropyranyl group and a tetrahydrofuranyl group.

As the structural unit (a1), it is preferable to use at least one unit selected from the group consisting of structural units represented by general formula (a1-0-1) shown below and structural units represented by general formula (a1-0-2) shown below.

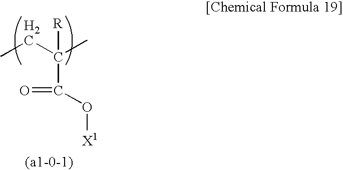

[wherein, R represents a hydrogen atom, a lower alkyl group or a halogenated lower alkyl group; and X¹ represents an acid dissociable, dissolution inhibiting group.]

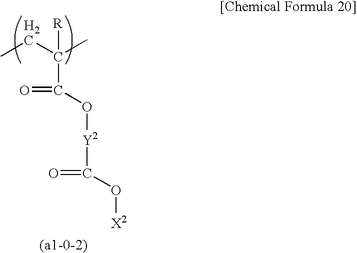

[wherein, R represents a hydrogen atom, a lower alkyl group or a halogenated lower alkyl group; X² represents an acid dissociable, dissolution inhibiting group; and Y² represents an alkylene group or an aliphatic cyclic group.]

In general formula (a1-0-1), the lower alkyl group or halogenated lower alkyl group for R is the same as the lower alkyl group or halogenated lower alkyl group that may be bonded to the α-position of the aforementioned acrylate ester.

There are no particular limitations on X¹, provided it is an acid dissociable, dissolution inhibiting group. Examples thereof include the aforementioned tertiary alkyl ester-type acid dissociable, dissolution inhibiting groups and acetal-type acid dissociable, dissolution inhibiting groups, and of these, a tertiary alkyl ester-type acid dissociable, dissolution inhibiting group is preferred.

In general formula (a1-0-2), R is as defined above.

X² is as defined for X¹ in formula (a1-0-1).

Y² is preferably an alkylene group of 1 to 10 carbon atoms or a divalent aliphatic cyclic group. As the aliphatic cyclic group, the same groups as those exemplified above in relation to the description of the “aliphatic cyclic group” may be used, with the exception that two hydrogen atoms have been removed therefrom.

In those cases where Y² is an alkylene group of 1 to 10 carbon atoms, the number of carbon atoms within the group is more preferably from 1 to 6, still more preferably from 1 to 4, and is most preferably from 1 to 3.

In those cases where Y² is a divalent aliphatic cyclic group, groups in which two or more hydrogen atoms have been removed from cyclopentane, cyclohexane, norbornane, isobornane, adamantane, tricyclodecane or tetracyclododecane are preferred.

Specific examples of the structural unit (a1) include structural units represented by general formulas (a1-1) to (a1-4) shown below.

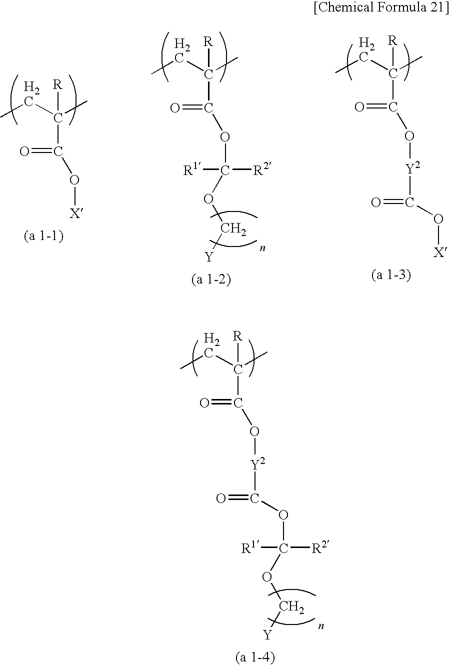

[wherein, X′ represents a tertiary alkyl ester-type acid dissociable, dissolution inhibiting group, Y represents a lower alkyl group of 1 to 5 carbon atoms or an aliphatic cyclic group, n represents an integer of 0 to 3, Y² represents an alkylene group or an aliphatic cyclic group, R is as defined above, and R¹′ and R²′ each independently represents a hydrogen atom or a lower alkyl group of 1 to 5 carbon atoms.]

In the above formulas, examples of X′ include the same tertiary alkyl ester-type acid dissociable, dissolution inhibiting groups as those exemplified above in relation to X¹.

Examples of R¹′, R²′, n and Y include the same groups as those exemplified above for R¹′, R²′, n and Y in general formula (p1) within the description of the aforementioned “acetal-type acid dissociable, dissolution inhibiting groups”.

Examples of Y² include the same groups as those exemplified for Y² in general formula (a1-0-2) shown above.

Specific examples of structural units represented by general formulas (a1-1) to (a1-4) are shown below.

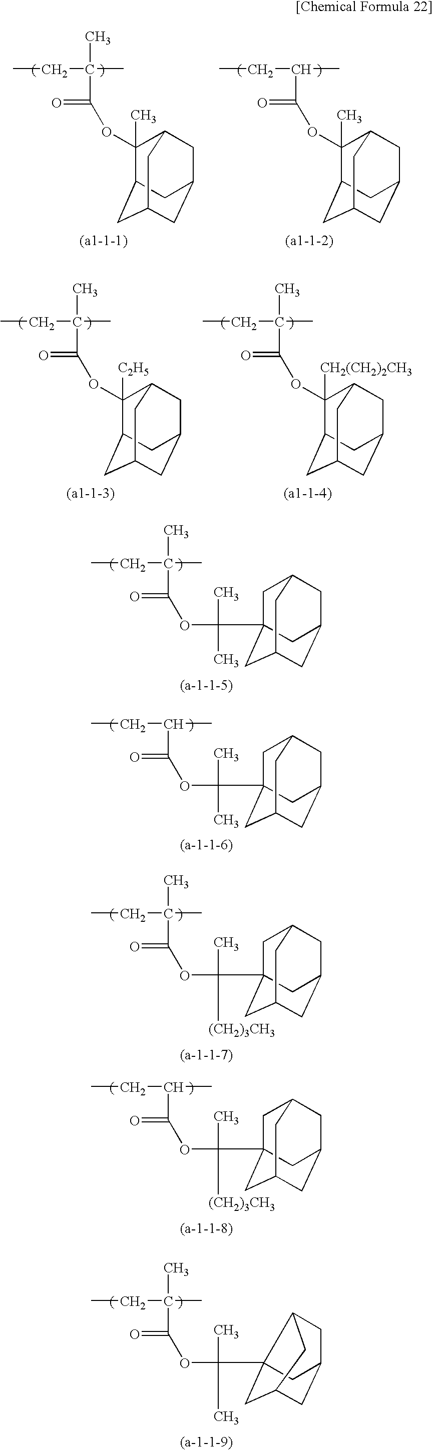

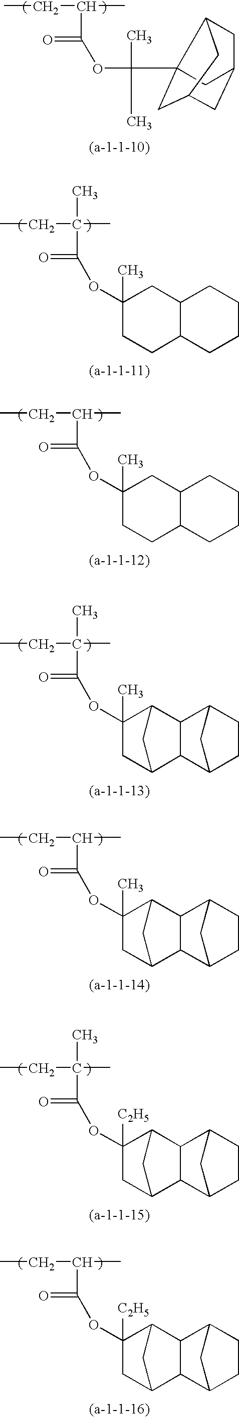

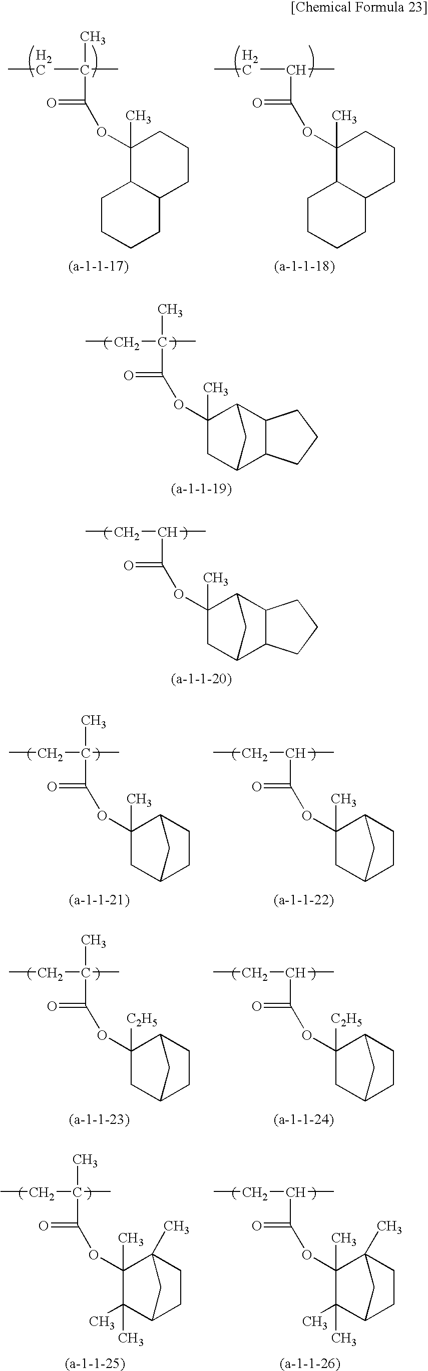

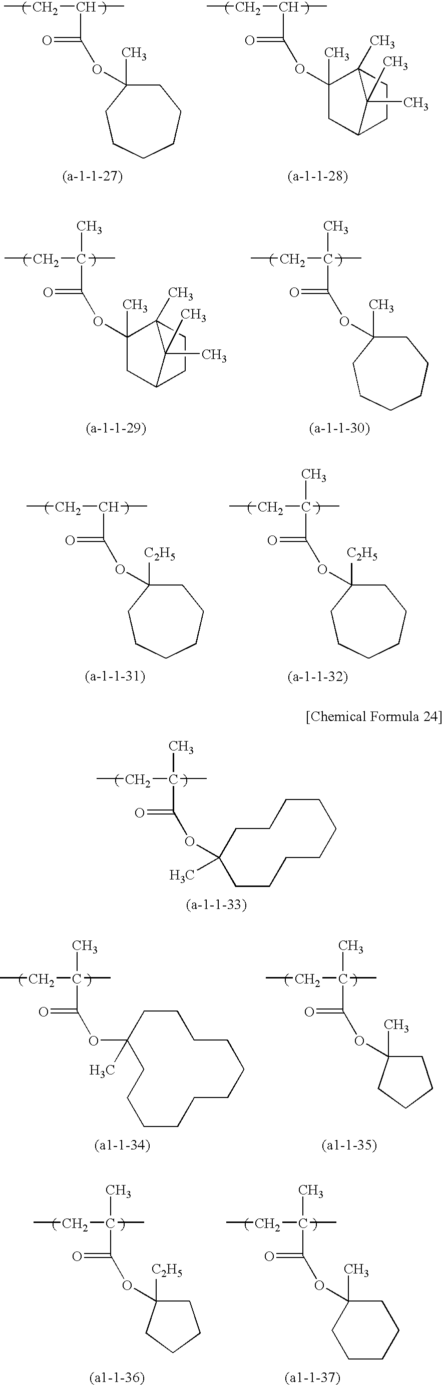

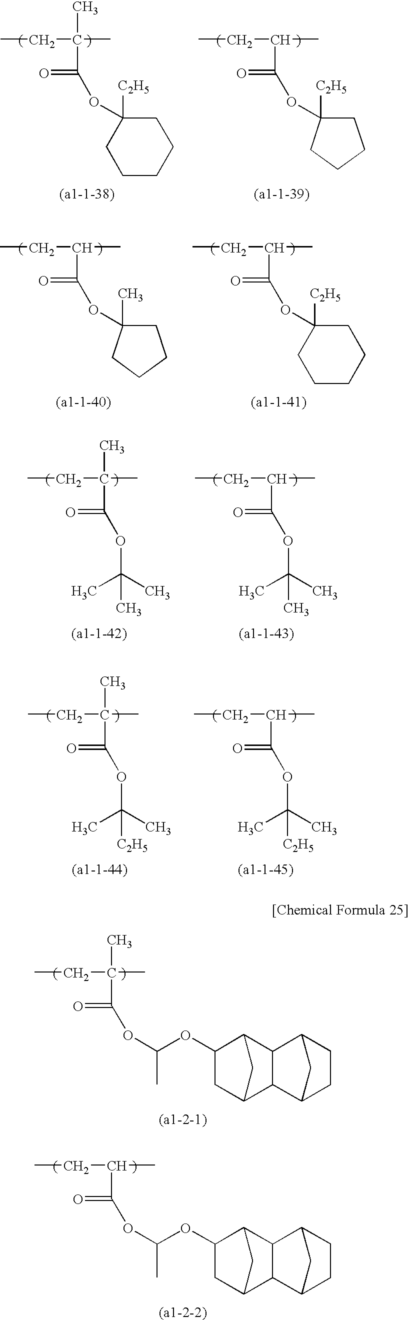

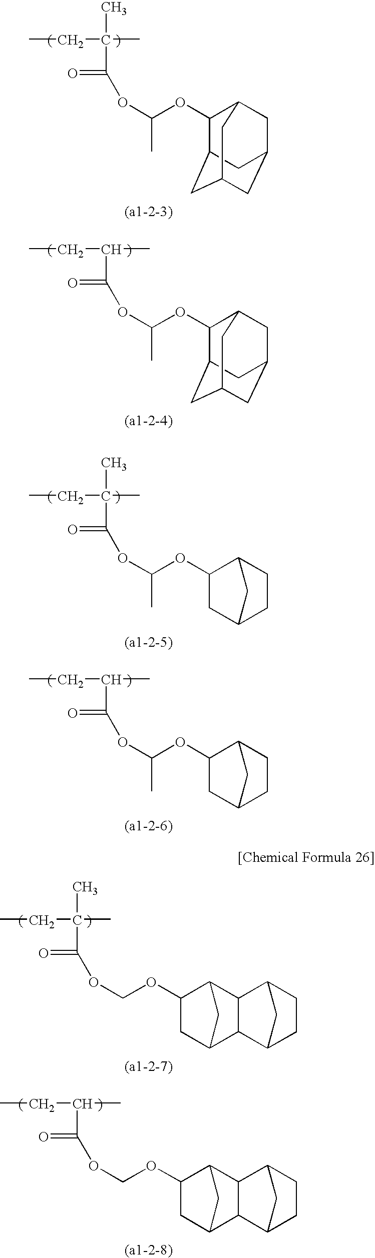

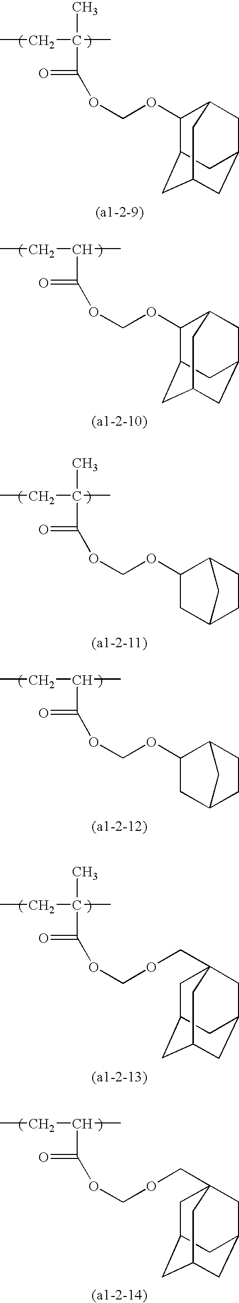

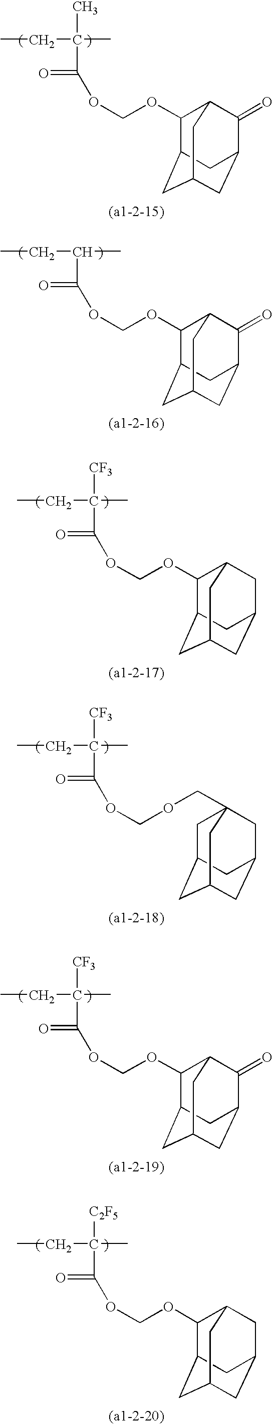

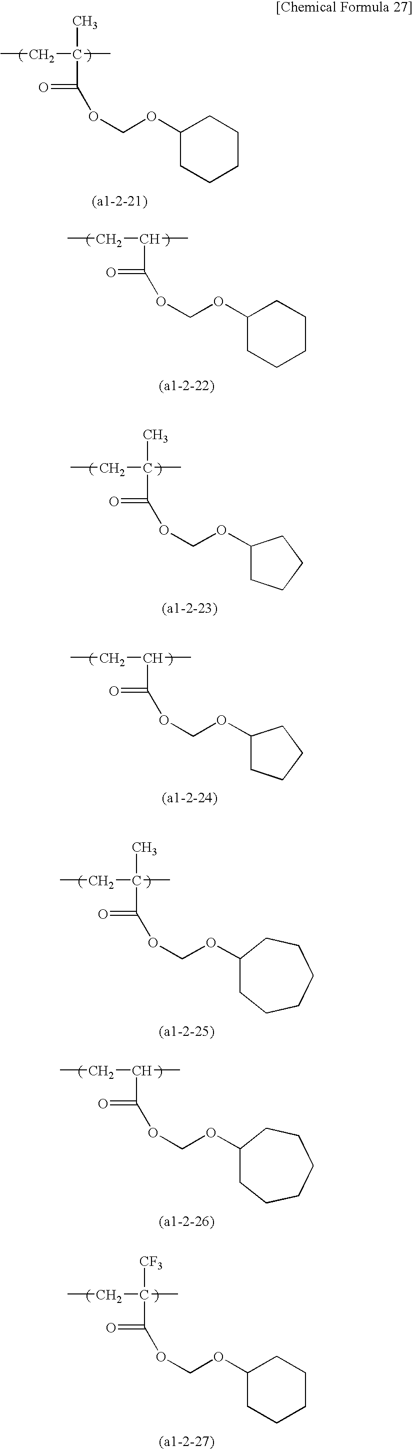

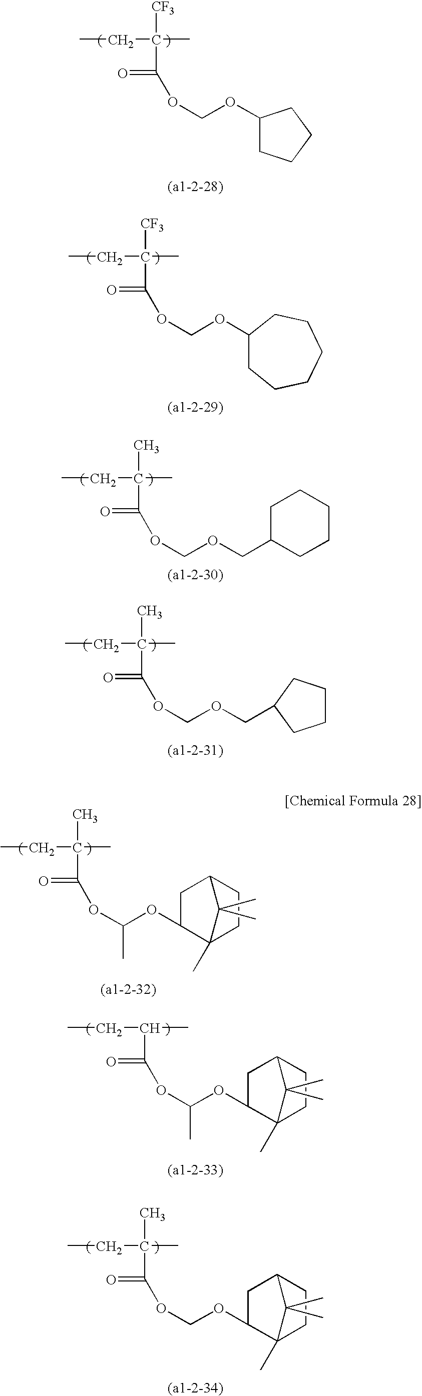

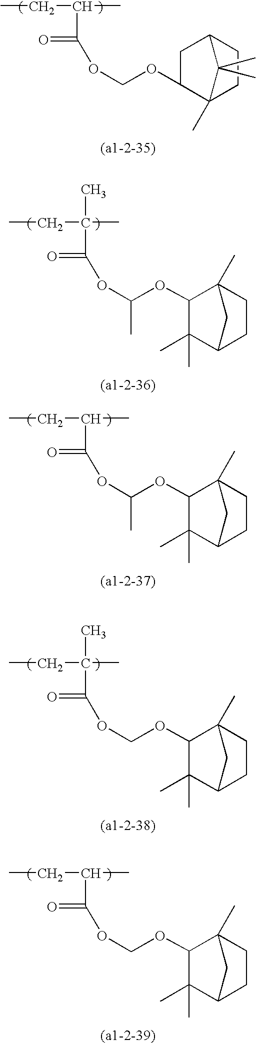

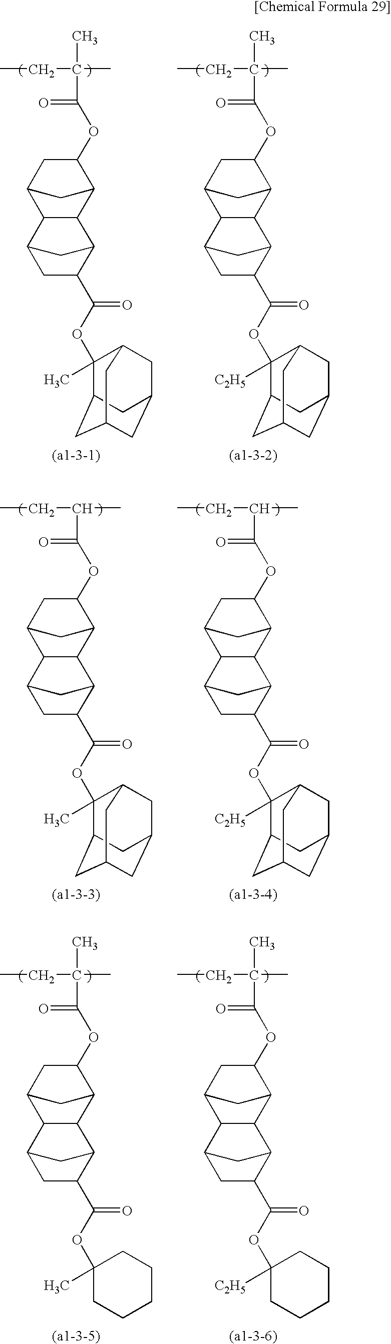

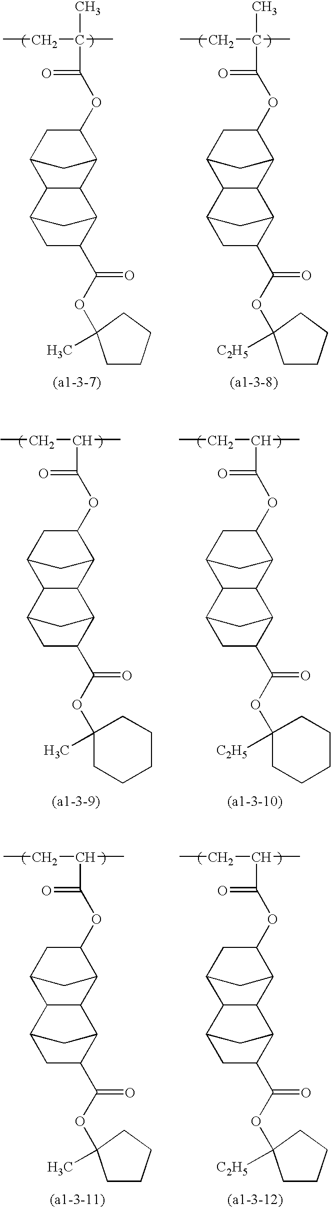

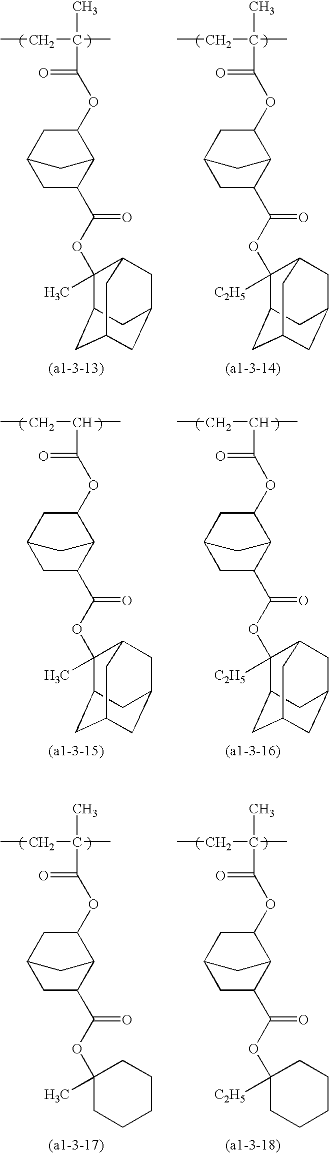

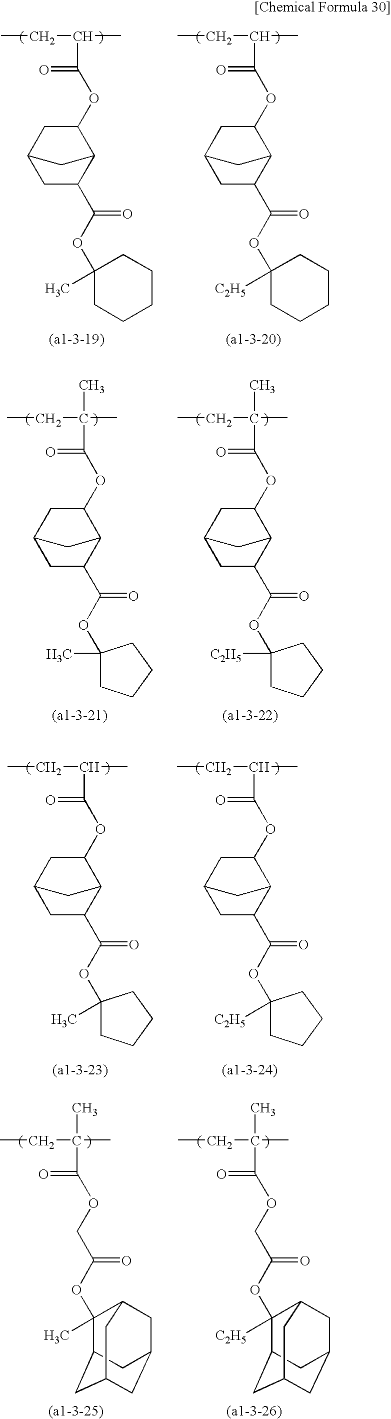

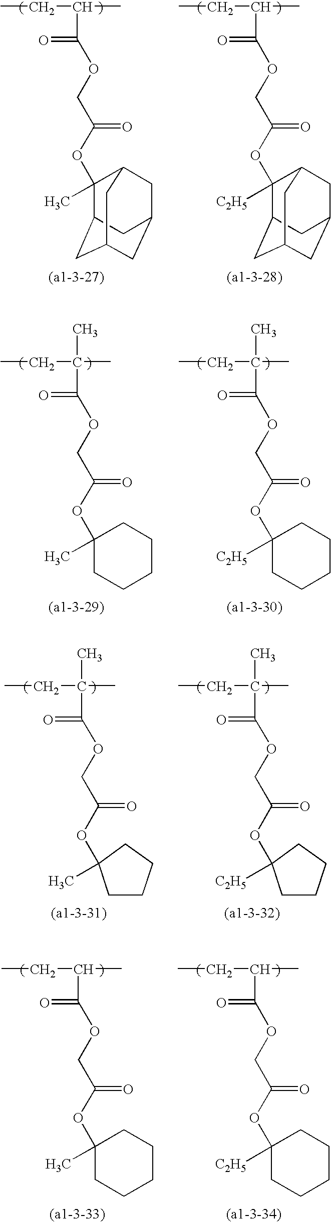

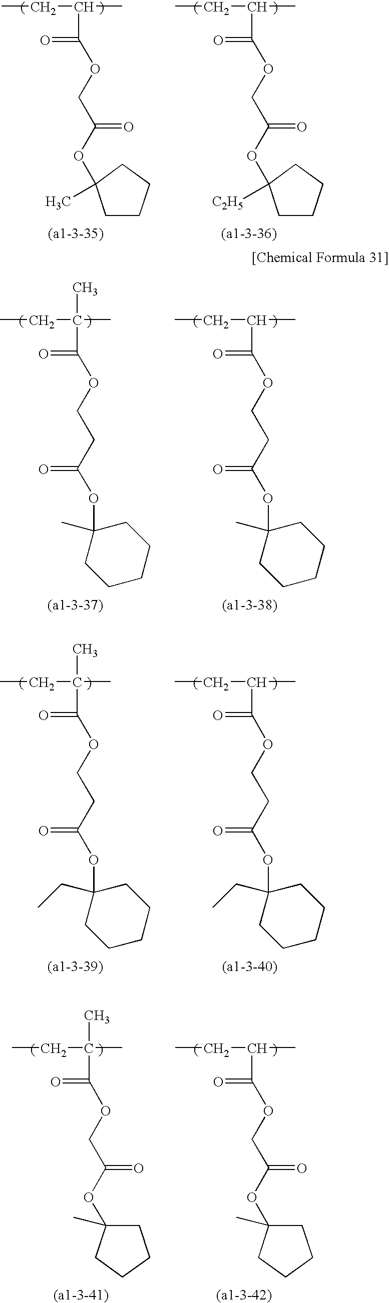

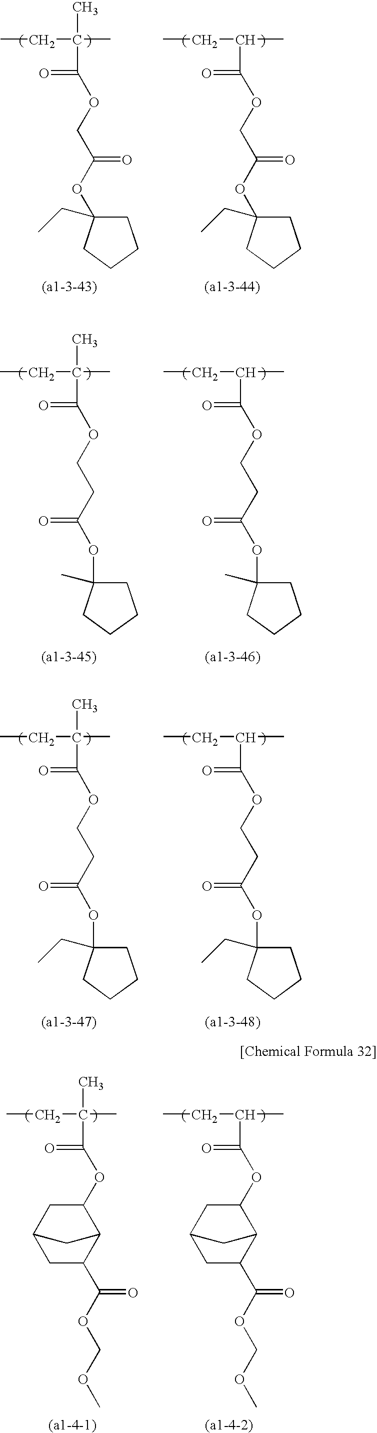

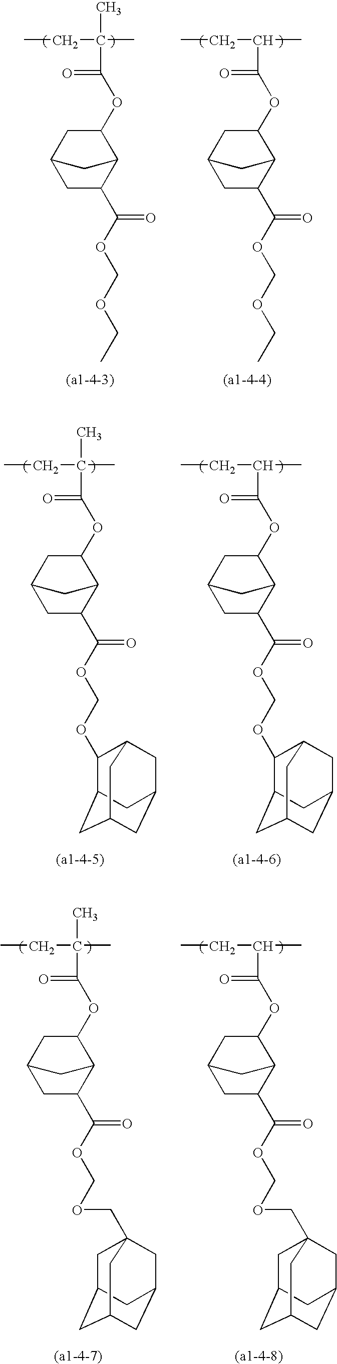

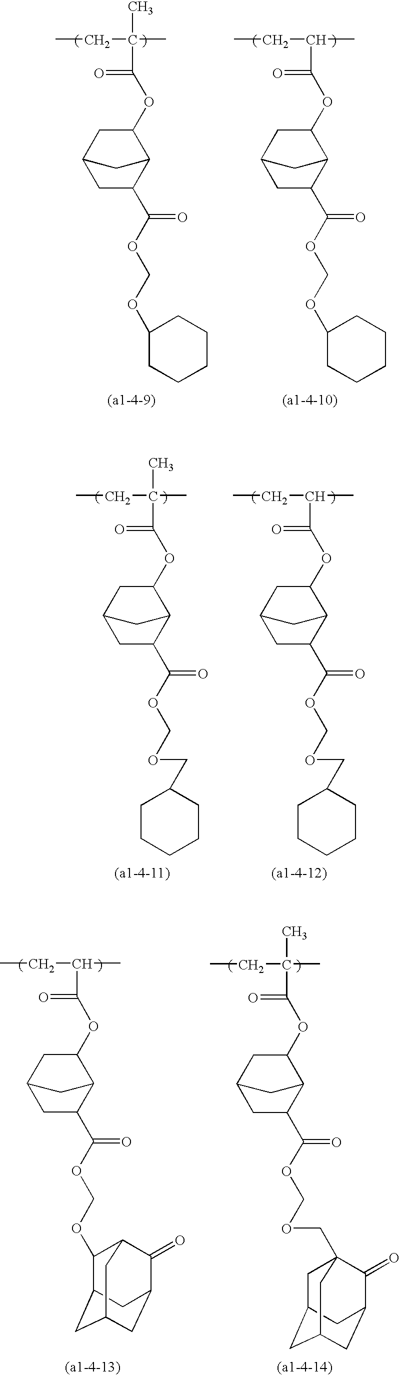

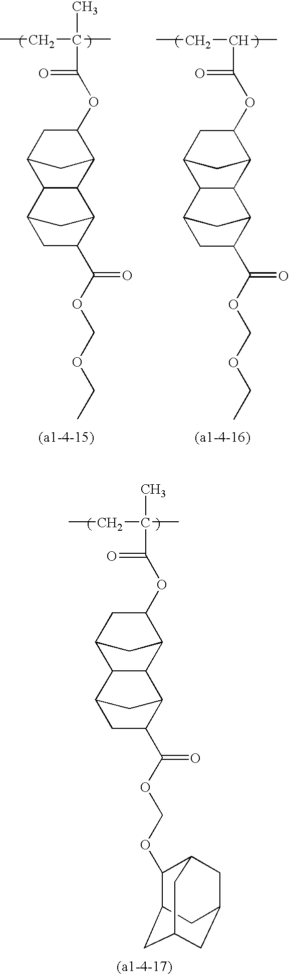

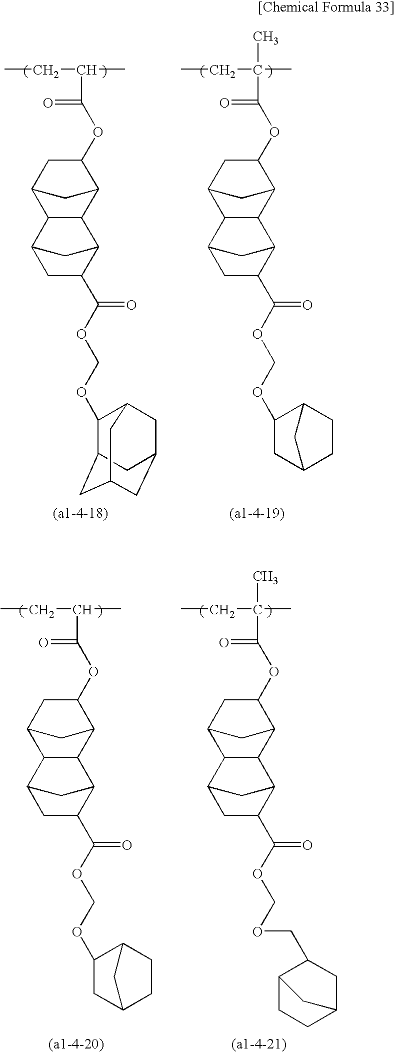

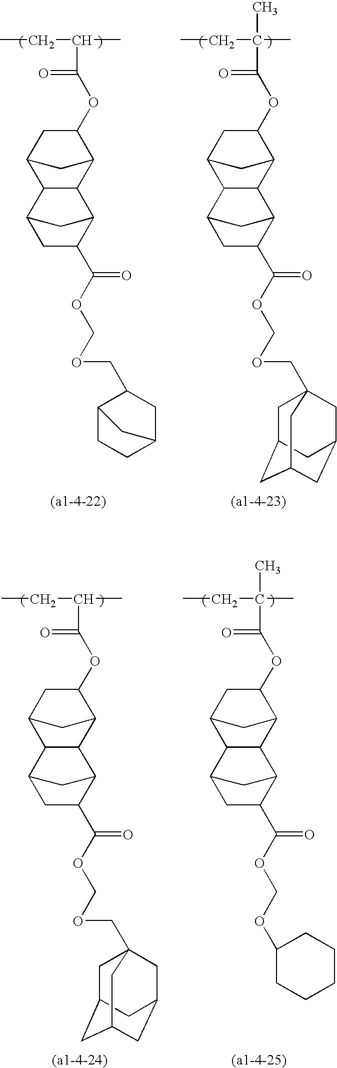

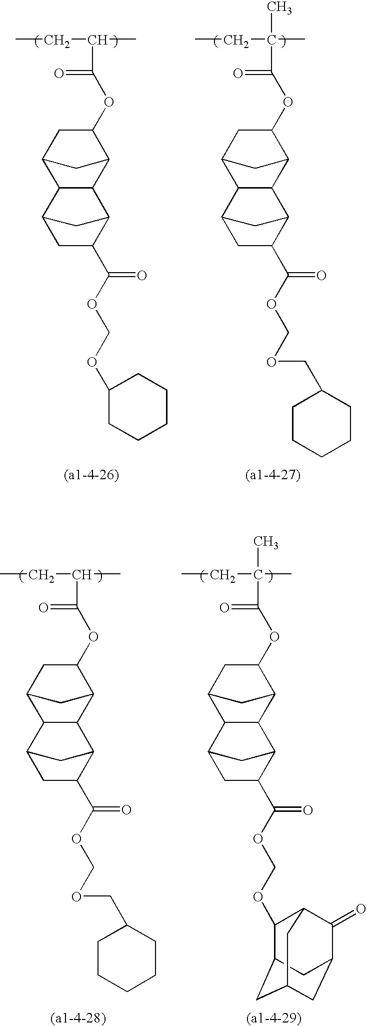

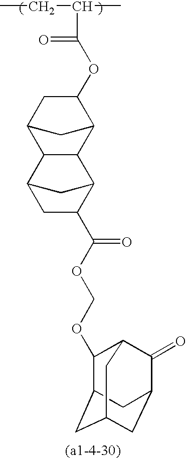

Among the above units, structural units represented by general formula (a1-1) are preferable. More specifically, at least one structural unit selected from the group consisting of structural units represented by formulas (a1-1-1) to (a1-1-6) and (a1-1-35) to (a1-1-41) is more preferable.

Further, as the structural unit (a1), structural units represented by general formula (a1-1-01) shown below which includes the structural units represented by formulas (a1-1-1) to (a1-1-4), and structural units represented by general formula (a1-1-02) shown below which includes the structural units represented by formulas (a1-1-35) to (a1-1-41) are also preferable.

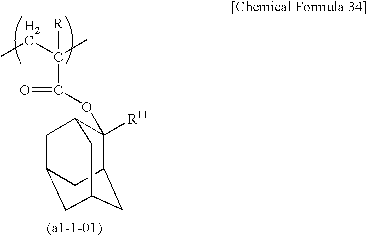

[wherein, R represents a hydrogen atom, a lower alkyl group or a halogenated lower alkyl group, and R¹¹ represents a lower alkyl group.]

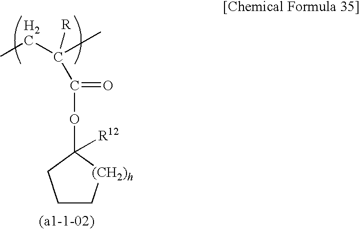

[wherein, R represents a hydrogen atom, a lower alkyl group or a halogenated lower alkyl group, R¹² represents a lower alkyl group, and h represents an integer of 1 to 3.]

In general formula (a1-1-01), R is as defined above.

The lower alkyl group for R¹¹ is as defined for the lower alkyl group for R, and is preferably a methyl group or an ethyl group.

In general formula (a1-1-02), R is as defined above.

The lower alkyl group for R¹² is as defined for the lower alkyl group for R, is preferably a methyl group or an ethyl group, and is most preferably an ethyl group. h is preferably 1 or 2, and most preferably 2.

As the structural unit (a1), a single type of structural unit may be used, or a combination of two or more types may be used.

In the component (A1), the proportion of the structural unit (a1), relative to the combined total of all the structural units that constitute the component (A1), is preferably from 10 to 80 mol %, more preferably from 20 to 70 mol %, and still more preferably from 25 to 50 mol %. By making the proportion of the structural unit (a1) at least as large as the lower limit of the above-mentioned range, a pattern can be easily formed using a resist composition prepared from the component (A1), whereas by ensuring that the proportion of the structural unit (a1) is no larger than the upper limit of the above range, a good balance can be achieved with the other structural units.

Structural Unit (a2)

The structural unit (a2) is derived from an acrylate ester containing a lactone-containing cyclic group.

The term “lactone-containing cyclic group” refers to a cyclic group that includes one ring containing a —O—C(O)— structure (a lactone ring). This lactone ring is counted as the first ring, and a lactone-containing cyclic group in which the only ring structure is the lactone ring is referred to as a monocyclic group, whereas groups containing other ring structures are described as polycyclic groups regardless of the structure of the other rings.

When the copolymer (A1) is used for forming a resist film, the lactone-containing cyclic group of the structural unit (a2) is effective in improving the adhesion between the resist film and the substrate, and increasing the compatibility with developing solutions that contain water.

As the structural unit (a2), any arbitrary structural unit may be used without any particular limitations.

Specific examples of lactone-containing monocyclic groups include groups in which one hydrogen atom has been removed from γ-butyrolactone. Further, specific examples of lactone-containing polycyclic groups include groups in which one hydrogen atom has been removed from a lactone ring-containing bicycloalkane, tricycloalkane or tetracycloalkane.

More specifically, examples of the structural unit (a2) include structural units represented by general formulas (a2-1) to (a2-5) shown below.

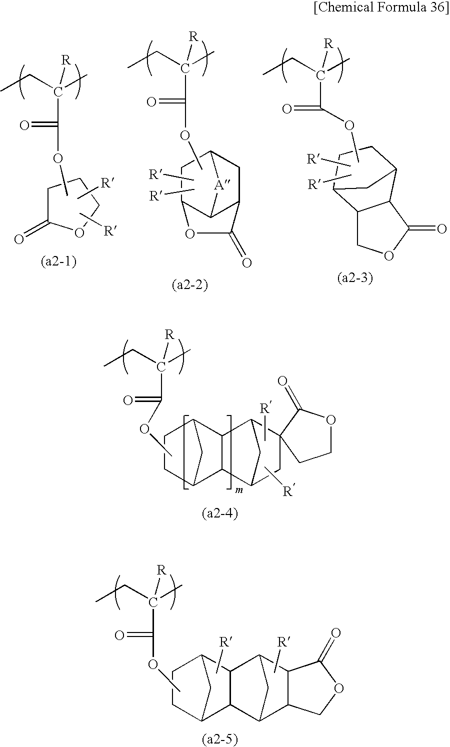

[wherein R represents a hydrogen atom, a lower alkyl group or a halogenated lower alkyl group, R′ represents a hydrogen atom, a lower alkyl group, an alkoxy group of 1 to 5 carbon atoms or a —COOR″ group, R″ represents a hydrogen atom, or a linear, branched or cyclic alkyl group of 1 to 15 carbon atoms, m represents an integer of 0 or 1, and A″ represents an alkylene group of 1 to 5 carbon atoms that may include an oxygen atom or sulfur atom, an oxygen atom, or a sulfur atom.]

In general formulas (a2-1) to (a2-5), R is as defined above for R in the structural unit (a1).

The lower alkyl group for R′ is as defined above for the lower alkyl group for R in the structural unit (a1).

When R″ represents a linear or branched alkyl group, the group preferably contains 1 to 10 carbon atoms, and more preferably 1 to 5 carbon atoms.

When R″ represents a cyclic alkyl group, the group preferably contains 3 to 15 carbon atoms, more preferably 4 to 12 carbon atoms, and most preferably 5 to 10 carbon atoms. Examples include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, or a polycycloalkane such as adamantane, norbornane, isobornane, tricyclodecane or tetracyclododecane.

In general formulas (a2-1) to (a2-5), in consideration of industrial availability, R′ is preferably a hydrogen atom.

Specific examples of the alkylene group of 1 to 5 carbon atoms that may include an oxygen atom or sulfur atom represented by A″ include a methylene group, ethylene group, n-propylene group, isopropylene group, —O—CH₂—, —CH₂—O—CH₂—, —S—CH₂—, and —CH₂—S—CH₂—.

Specific examples of structural units represented by general formulas (a2-1) to (a2-5) are shown below.

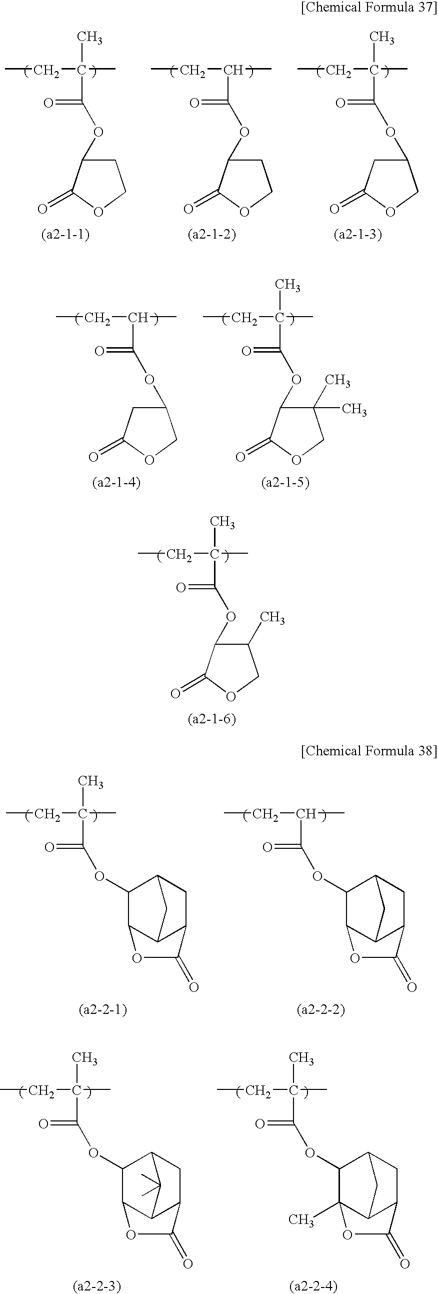

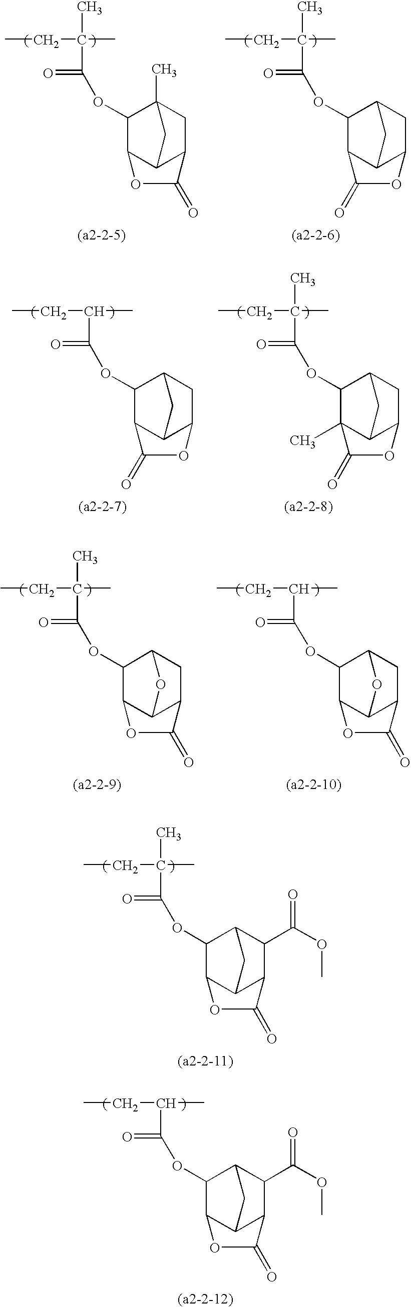

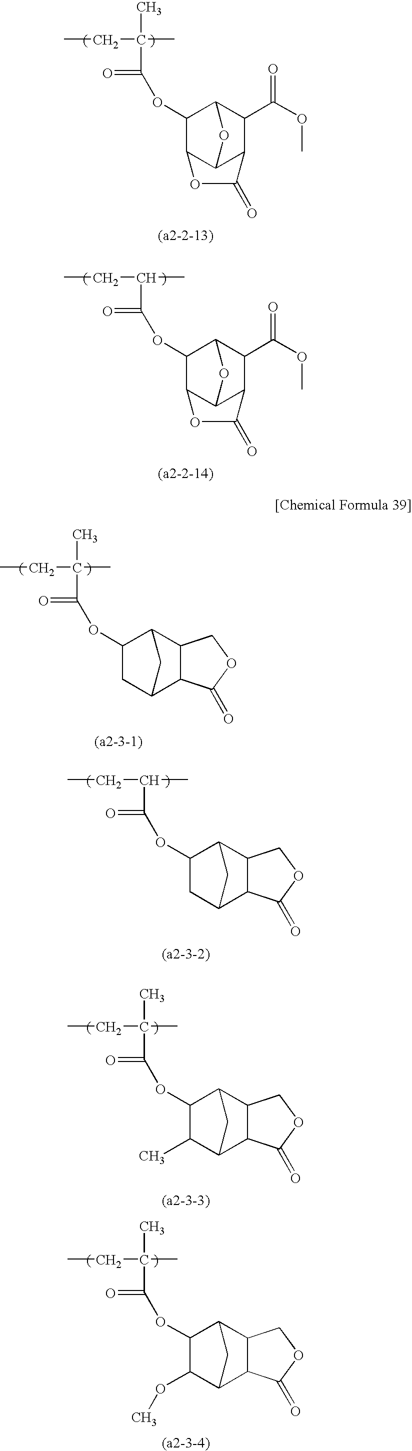

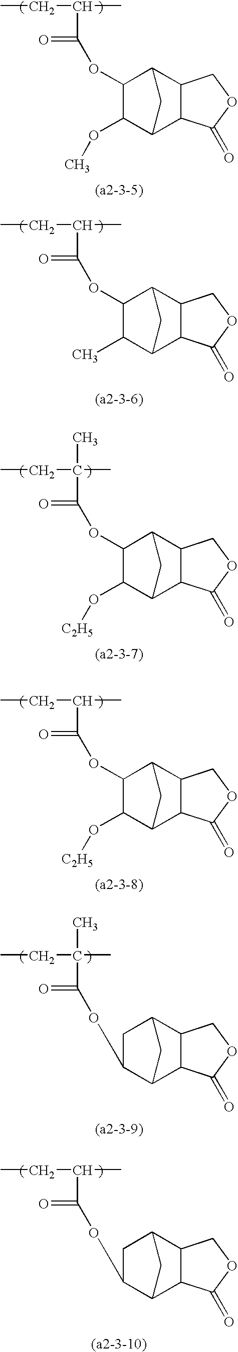

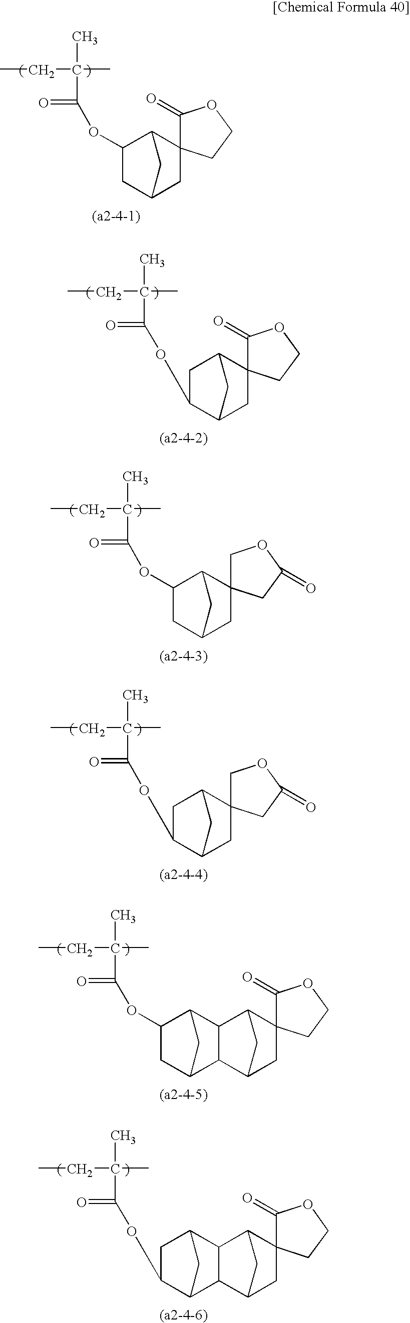

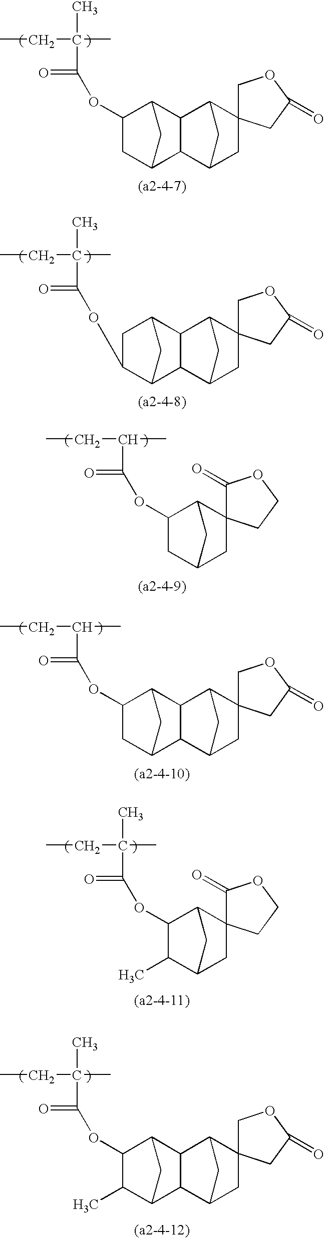

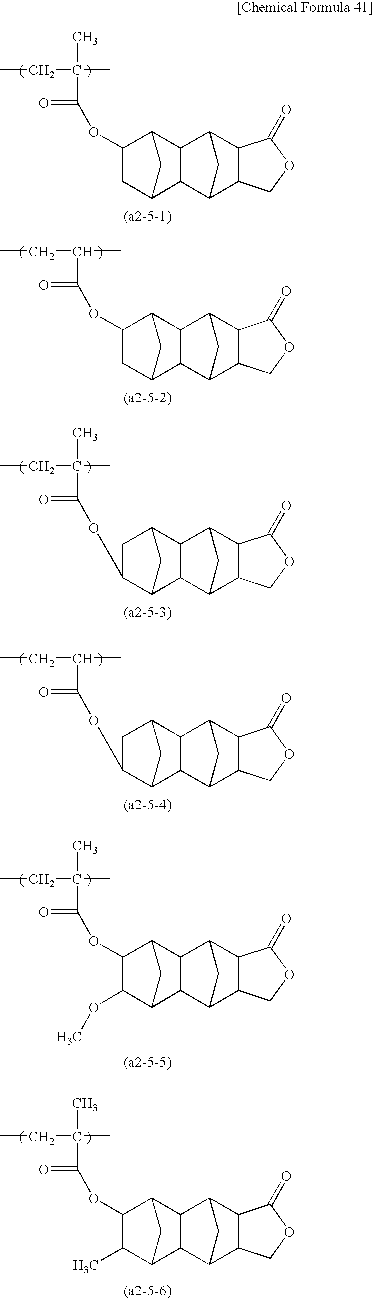

As the structural unit (a2), at least one structural unit selected from the group consisting of structural units represented by formulas (a2-1) to (a2-5) is preferred, and at least one structural unit selected from the group consisting of structural units represented by formulas (a2-1) to (a2-3) is more desirable. Specifically, it is preferable to use at least one structural unit selected from the group consisting of structural units represented by formulas (a2-1-1), (a2-1-2), (a2-2-1), (a2-2-2), (a2-2-9), (a2-2-10), (a2-3-1), (a2-3-2), (a2-3-9) and (a2-3-10).

As the structural unit (a2), one type of structural unit may be used, or two or more types may be used in combination.

In the component (A1), the proportion of the structural unit (a2), relative to the combined total of all the structural units that constitute the component (A1), is preferably from 5 to 60 mol %, more preferably from 10 to 50 mol %, and still more preferably from 20 to 50 mol %. By making the proportion of the structural unit (a2) at least as large as the lower limit of the above-mentioned range, the effect of using the structural unit (a2) can be satisfactorily achieved, whereas by ensuring that the proportion of the structural unit (a2) is no greater than the upper limit of the above range, a good balance can be achieved with the other structural units.

Structural Unit (a3)

The structural unit (a3) is derived from an acrylate ester having a polar group-containing aliphatic hydrocarbon group.

By including the structural unit (a3) within the component (A1), the hydrophilicity of the component (A1) is improved, and hence, the compatibility of the component (A1) with the developing solution is improved, and as a result, the alkali solubility of the exposed portions improves, which contributes to a favorable improvement in the resolution.

Examples of the polar group include a hydroxyl group, cyano group, carboxyl group, or hydroxyalkyl group in which some of the hydrogen atoms of the alkyl group have been substituted with fluorine atoms, although a hydroxyl group is particularly desirable.

Examples of the aliphatic hydrocarbon group include linear or branched hydrocarbon groups (and preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers and the like. The polycyclic group preferably contains 7 to 30 carbon atoms.

Of the various possibilities, structural units derived from an acrylate ester that includes an aliphatic polycyclic group containing a hydroxyl group, cyano group, carboxyl group, or a hydroxyalkyl group in which some of the hydrogen atoms of the alkyl group have been substituted with fluorine atoms are particularly desirable. Examples of the polycyclic group include groups in which two or more hydrogen atoms have been removed from a bicycloalkane, tricycloalkane or tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, groups in which two or more hydrogen atoms have been removed from norbornane, and groups in which two or more hydrogen atoms have been removed from tetracyclododecane are preferred industrially.

When the hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferred.

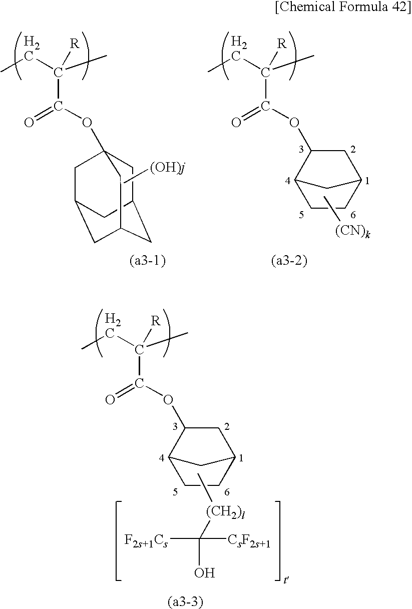

[wherein, R is as defined above, j is an integer of 1 to 3, k is an integer of 1 to 3, t′ is an integer of 1 to 3, 1 is an integer of 1 to 5, and s is an integer of 1 to 3.]

In formula (a3-1), j is preferably 1 or 2, and is most preferably 1. When j is 2, the hydroxyl groups are preferably bonded to the 3rd and 5th positions of the adamantyl group. When j is 1, the hydroxyl group is preferably bonded to the 3rd position of the adamantyl group.

j is preferably 1, and the hydroxyl group is preferably bonded to the 3rd position of the adamantyl group.

In formula (a3-2), k is preferably 1. The cyano group is preferably bonded to the 5th or 6th position of the norbornyl group.

In formula (a3-3), t′ is preferably 1, 1 is preferably 1, and s is preferably 1. Further, a 2-norbornyl group or 3-norbornyl group is preferably bonded to the terminal of the carboxyl group of the acrylic acid. The fluorinated alkyl alcohol is preferably bonded to the 5th or 6th position of the norbornyl group.

As the structural unit (a3), one type of structural unit may be used, or two or more types may be used in combination.

The proportion of the structural unit (a3) within the component (A1), relative to the combined total of all the structural units that constitute the component (A1), is preferably from 5 to 50 mol %, more preferably from 5 to 40 mol %, and still more preferably from 5 to 25 mol %. By making the proportion of the structural unit (a3) at least as large as the lower limit of the above-mentioned range, the effect of using the structural unit (a3) can be satisfactorily achieved, whereas by ensuring that the proportion of the structural unit (a3) is no larger than the upper limit of the above range, a good balance can be achieved with the other structural units.

Structural Unit (a4)

The component (A1) may also include a structural unit (a4) that is different from the aforementioned structural units (a1) to (a3), provided the effects of the present invention are not impaired.

As the structural unit (a4), any other structural unit that cannot be classified as one of the above structural units (a1) to (a3) can be used without any particular limitations, and any of the multitude of conventional structural units used within resist resins for ArF excimer lasers or KrF excimer lasers (and particularly for ArF excimer lasers) can be used.

As the structural unit (a4), a structural unit derived from an acrylate ester containing a non-acid-dissociable aliphatic polycyclic group is preferred. Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In terms of factors such as industrial availability, at least one polycyclic group selected from amongst a tricyclodecanyl group, adamantyl group, tetracyclododecanyl group, isobornyl group and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

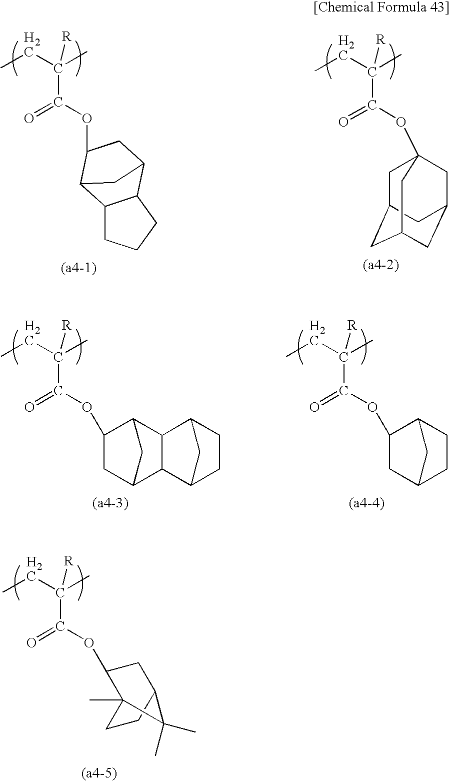

[wherein, R is as defined above.]

When the structural unit (a4) is included in the component (A1), the proportion of the structural unit (a4) within the component (A1), relative to the combined total of all the structural units that constitute the component (A1), is preferably within a range from 1 to 30 mol %, and more preferably from 10 to 20 mol %.

In the component (A), either a single copolymer (A1) may be used, or a combination of two or more copolymers may be used.

In the present invention, as the copolymer (A1), copolymers that include combinations of the types of structural units shown below are particularly desirable.

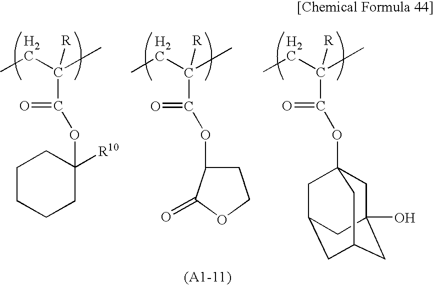

[wherein, R is as defined above, the plurality of R groups may be the same or different, and R¹⁰ represents a lower alkyl group.]

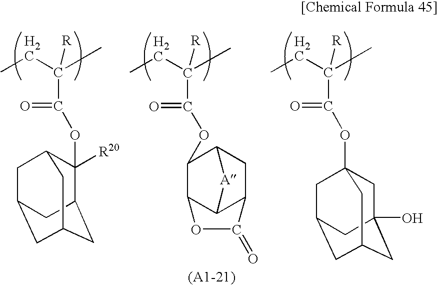

[wherein, R and A″ are as defined above, the plurality of R groups may be the same or different, and R²⁰ represents a lower alkyl group.]

In the formula (A1-11), the lower alkyl group for R¹⁰ is as defined above for the lower alkyl group for R, is preferably a methyl group or an ethyl group, and is most preferably a methyl group.

In the formula (A1-21), the lower alkyl group for R²⁰ is as defined above for the lower alkyl group for R, is preferably a methyl group or an ethyl group, and is most preferably a methyl group.

In the formula (A1-21), A″ is as defined above for A″ in general formula (a2-2), and is preferably an oxygen atom, a methylene group or an ethylene group.

In the present invention, the component (A1) preferably includes a copolymer containing the structural units (a1), (a2) and (a3). Examples of such a copolymer include a copolymer composed of the structural units (a1) and (a2) and (a3), and a copolymer composed of the structural units (a1), (a2), (a3) and (a4).

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH during the above polymerization, a —C(CF₃)₂—OH group can be introduced at the terminals of the component (A1). Such a copolymer having an introduced hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography) of the component (A1) is not particularly limited, but is preferably from 2,000 to 50,000, more preferably from 3,000 to 30,000, and most preferably from 5,000 to 20,000. By ensuring that the weight average molecular weight is no greater than the upper limit of the above-mentioned range, the component (A1) exhibits satisfactory solubility in a resist solvent when used as a resist, whereas by ensuring that the weight average molecular weight is at least as large as the lower limit of the above range, the dry etching resistance and cross-sectional shape of the resist pattern are more favorable.

Further, the degree of dispersion (Mw/Mn) is preferably from 1.0 to 5.0, more preferably from 1.0 to 3.0, and most preferably from 1.2 to 2.5. Here, Mn is the number average molecular weight.

### [Component (A2)]

As the component (A2), a low molecular weight compound that has a molecular weight of at least 500 but less than 2,000, contains a hydrophilic group, and also contains an acid dissociable, dissolution inhibiting group such as the groups exemplified above in the description of the component (A1) is preferred. Specific examples include compounds containing a plurality of phenol structures, in which some of the hydroxyl group hydrogen atoms have been substituted with the acid dissociable, dissolution inhibiting groups.

Preferred examples of the component (A2) include low molecular weight phenol compounds that are known, for example, as sensitizers or heat resistance improvers for use in non-chemically amplified g-line or i-line resists, wherein some of the hydroxyl group hydrogen atoms of these compounds have been substituted with the above acid dissociable, dissolution inhibiting groups, and any of these compounds may be used.

Specific examples of the low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers and tetramers of formalin condensation products of phenols such as phenol, m-cresol, p-cresol and xylenol. Of course, this is not a restrictive list.

There are no particular limitations on the acid dissociable, dissolution inhibiting group, and examples include the groups exemplified above.

As the component (A), one type of component may be used alone, or two or more types may be used in combination.

In the resist composition of the present invention, the amount of the component (A) may be adjusted appropriately in accordance with the thickness or the like of the resist film that is to be formed.

### <Component (B)>

As the component (B), there are no particular limitations, and any of the known acid generators used for conventional chemically amplified resists can be used. Examples of these acid generators are numerous, and include onium salt-based acid generators such as iodonium salts and sulfonium salts, oxime sulfonate-based acid generators, diazomethane-based acid generators such as bisalkyl or bisaryl sulfonyl diazomethanes and poly(bis-sulfonyl)diazomethanes, nitrobenzylsulfonate-based acid generators, iminosulfonate-based acid generators, and disulfone-based acid generators.

As the onium salt-based acid generator, a compound represented by general formula (b-1) or (b-2) shown below can be used.

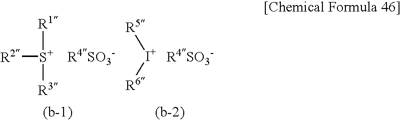

[wherein, R¹″ to R³″, and R⁵″ and R⁶″ each independently represents an aryl group or alkyl group, wherein two of R¹″ to R³″ in formula (b-1) may be bonded to each other to form a ring with the sulfur atom in the formula; and R⁴″ represents a linear, branched or cyclic alkyl group or fluorinated alkyl group; with the proviso that at least one of R¹″ to R³″ represents an aryl group, and at least one of R⁵″ and R⁶″ represents an aryl group.]

In formula (b-1), R¹″ to R³″ each independently represents an aryl group or an alkyl group. Two of R¹″ to R³″ in formula (b-1) may be bonded to each other to form a ring with the sulfur atom in the formula.

Further, among R¹″ to R³″, at least one group represents an aryl group. Among R¹″ to R³″, two or more groups are preferably aryl groups, and it is particularly desirable that all of R¹″ to R³″ are aryl groups.

The aryl group for R¹″ to R³″ is not particularly limited. For example, an aryl group having 6 to 20 carbon atoms may be used, in which some or all of the hydrogen atoms of the aryl group may or may not be substituted with alkyl groups, alkoxy groups, halogen atoms or hydroxyl groups. The aryl group is preferably an aryl group having 6 to 10 carbon atoms because it can be synthesized at a low cost. Specific examples thereof include a phenyl group and a naphthyl group.

The alkyl group with which hydrogen atoms of the aryl group may be substituted is preferably an alkyl group having 1 to 5 carbon atoms, and is most preferably a methyl group, ethyl group, propyl group, n-butyl group or tert-butyl group.

The alkoxy group with which hydrogen atoms of the aryl group may be substituted is preferably an alkoxy group having 1 to 5 carbon atoms, more preferably a methoxy group, ethoxy group, n-propoxy group, iso-propoxy group, n-butoxy group or tert-butoxy group, and is most preferably a methoxy group or an ethoxy group.

The halogen atom with which hydrogen atoms of the aryl group may be substituted is preferably a fluorine atom.

The alkyl group for R¹″ to R³″ is not particularly limited and examples thereof include linear, branched or cyclic alkyl groups having 1 to 10 carbon atoms. In terms of achieving excellent resolution, the alkyl group preferably contains 1 to 5 carbon atoms. Specific examples thereof include a methyl group, ethyl group, n-propyl group, isopropyl group, n-butyl group, isobutyl group, n-pentyl group, cyclopentyl group, hexyl group, cyclohexyl group, nonyl group or decanyl group. A methyl group is most preferable because it is excellent in resolution and can be synthesized at a low cost.

It is particularly desirable that each of R¹″ to R³″ is a phenyl group or a naphthyl group.

When two of R¹″ to R³″ in formula (b-1) are bonded to each other to form a ring with the sulfur atom shown in the formula, it is preferable that the two of R¹″ to R³″ form a 3- to 10-membered ring including the sulfur atom, and it is particularly desirable that the two of R¹″ to R³″ form a 5- to 7-membered ring including the sulfur atom.

When two of R¹″ to R³″ in formula (b-1) are bonded to each other to form a ring with the sulfur atom shown in the formula, the remaining one of R¹″ to R³″ is preferably an aryl group. As examples of the aryl group, the same as the above-mentioned aryl groups for R¹″ to R³″ can be exemplified.

R⁴″ represents a linear, branched or cyclic alkyl group or fluorinated alkyl group.

The linear or branched alkyl group preferably contains 1 to 10 carbon atoms, more preferably 1 to 8 carbon atoms, and most preferably 1 to 4 carbon atoms.

The cyclic alkyl group is preferably a cyclic group as described for R¹″, having 4 to 15 carbon atoms, more preferably 4 to 10 carbon atoms, and most preferably 6 to 10 carbon atoms.

The fluorinated alkyl group preferably contains 1 to 10 carbon atoms, more preferably 1 to 8 carbon atoms, and most preferably 1 to 4 carbon atoms. Further, the fluorination ratio of the fluorinated alkyl group (the percentage of fluorine atoms within the alkyl group) is preferably from 10 to 100%, more preferably from 50 to 100%, and it is particularly desirable that all hydrogen atoms are substituted with fluorine atoms (namely, the fluorinated alkyl group is a perfluoroalkyl group) because the acid strength increases.

R⁴″ is most preferably a linear or cyclic alkyl group or fluorinated alkyl group.

In formula (b-2), R⁵″ and R⁶″ each independently represents an aryl group or an alkyl group. At least one of R⁵″ and R⁶″ represents an aryl group. It is preferable that R⁵″ and R⁶″ both represent aryl groups.

As the aryl group for R⁵″ and R⁶″, the same aryl groups as those mentioned above for R¹″ to R³″ can be exemplified.

As the alkyl group for R⁵″ and R⁶″, the same alkyl groups as those mentioned above for R¹″ to R³″ can be exemplified.

It is particularly desirable that R⁵″ and R⁶″ both represent phenyl groups.

As R⁴″ in formula (b-2), the same groups as those mentioned above for R⁴″ in formula (b-1) can be exemplified.

Specific examples of suitable onium salt-based acid generators represented by formula (b-1) or (b-2) include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)disphenylsulfonium trifluoromethanesulfonate, heptafluoropropanesulfonate or nonafluorobutanesulfonate, (4-methoxyphenyl)diphenylsulfonium trifluoromethanesulfonate, heptafluoropropanesulfonate or nonafluorobutanesulfonate, tri(4-tert-butyl)phenylsulfonium trifluoromethanesulfonate, heptafluoropropanesulfonate or nonafluorobutanesulfonate, diphenyl(1-(4-methoxy)naphthyl)sulfonium trifluoromethanesulfonate, heptafluoropropanesulfonate or nonafluorobutanesulfonate, di(1-naphthyl)phenylsulfonium trifluoromethanesulfonate, heptafluoropropanesulfonate or nonafluorobutanesulfonate, 1-phenyltetrahydrothiophenium trifluoromethanesulfonate, heptafluoropropanesulfonate or nonafluorobutanesulfonate, 1-(4-methylphenyl)tetrahydrothiophenium trifluoromethanesulfonate, heptafluoropropanesulfonate or nonafluorobutanesulfonate, 1-(3,5-dimethyl-4-hydroxyphenyl)tetrahydrothiophenium trifluoromethanesulfonate, heptafluoropropanesulfonate or nonafluorobutanesulfonate, 1-(4-methoxynaphthalen-1-yl)tetrahydrothiophenium trifluoromethanesulfonate, heptafluoropropanesulfonate or nonafluorobutanesulfonate, 1-(4-ethoxynaphthalen-1-yl)tetrahydrothiophenium trifluoromethanesulfonate, heptafluoropropanesulfonate or nonafluorobutanesulfonate, 1-(4-n-butoxynaphthalen-1-yl)tetrahydrothiophenium trifluoromethanesulfonate, heptafluoropropanesulfonate or nonafluorobutanesulfonate, 1-phenyltetrahydrothiopyranium trifluoromethanesulfonate, heptafluoropropanesulfonate or nonafluorobutanesulfonate, 1-(4-hydroxyphenyl)tetrahydrothiopyranium trifluoromethanesulfonate, heptafluoropropanesulfonate or nonafluorobutanesulfonate, 1-(3,5-dimethyl-4-hydroxyphenyl)tetrahydrothiopyranium trifluoromethanesulfonate, heptafluoropropanesulfonate or nonafluorobutanesulfonate, and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts has been replaced by methanesulfonate, n-propanesulfonate, n-butanesulfonate, or n-octanesulfonate.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may also be used.

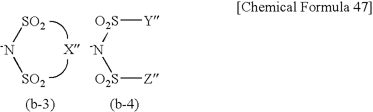

[wherein, X″ represents an alkylene group of 2 to 6 carbon atoms in which at least one hydrogen atom has been substituted with a fluorine atom, and Y″ and Z″ each independently represents an alkyl group of 1 to 10 carbon atoms in which at least one hydrogen atom has been substituted with a fluorine atom.]

X″ represents a linear or branched alkylene group in which at least one hydrogen atom has been substituted with a fluorine atom, wherein the alkylene group contains 2 to 6 carbon atoms, preferably 3 to 5 carbon atoms, and most preferably 3 carbon atoms.

Y″ and Z″ each independently represents a linear or branched alkyl group in which at least one hydrogen atom has been substituted with a fluorine atom, wherein the alkyl group contains 1 to 10 carbon atoms, preferably 1 to 7 carbon atoms, and more preferably 1 to 3 carbon atoms.

The smaller the number of carbon atoms within the alkylene group of X″ or within the alkyl group of Y″ and Z″ within the above ranges for the number of carbon atoms, the better the solubility in a resist solvent.

Further, in the alkylene group of X″ or the alkyl group of Y″ and Z″, it is preferable that the number of hydrogen atoms substituted with fluorine atoms is as large as possible, as the acid strength increases and the transparency to high energy radiation of 200 nm or less or electron beam is improved. The fluorination ratio of the alkylene group or alkyl group is preferably within a range from 70 to 100%, more preferably from 90 to 100%, and it is particularly desirable that the alkylene group or alkyl group be a perfluoroalkylene group or perfluoroalkyl group in which all the hydrogen atoms are substituted with fluorine atoms.

Furthermore, a sulfonium salt having a cation moiety represented by general formula (b-5) or (b-6) shown below may also be used as an onium salt-based acid generator.

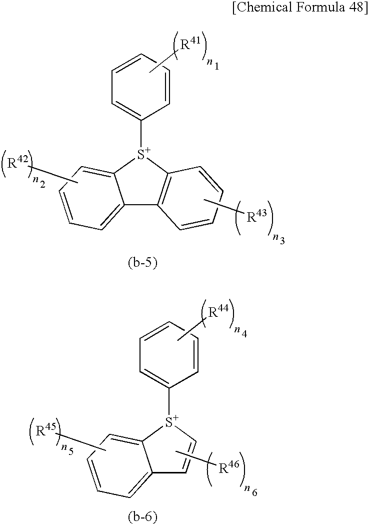

[wherein R⁴¹ to R⁴⁶ each independently represents an alkyl group, acetyl group, alkoxy group, carboxyl group, hydroxyl group or hydroxyalkyl group, n₁ to n₅ each independently represents an integer of 0 to 3, and n₆ represents an integer of 0 to 2.]

With respect to R⁴¹ to R⁴⁶, the alkyl group is preferably an alkyl group of 1 to 5 carbon atoms, more preferably a linear or branched alkyl group, and most preferably a methyl group, ethyl group, propyl group, isopropyl group, n-butyl group or tert butyl group.

The alkoxy group is preferably an alkoxy group of 1 to 5 carbon atoms, more preferably a linear or branched alkoxy group, and most preferably a methoxy group or ethoxy group.

The hydroxyalkyl group is preferably an aforementioned alkyl group in which one or more hydrogen atoms have been substituted with hydroxy groups, and examples thereof include a hydroxymethyl group, hydroxyethyl group and hydroxypropyl group.

When any of the subscripts n₁ to n₆ of R⁴¹ to R⁴⁶ represents an integer of 2 or more, the plurality of R⁴¹ to R⁴⁶ groups may be the same or different.

n₁ is preferably 0 to 2, more preferably 0 or 1, and still more preferably 0.

It is preferable that n₂ and n₃ each independently represents 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

The anion moiety of the sulfonium salt having a cation moiety represented by general formula (b-5) or (b-6) is not particularly limited, and the same anion moieties as those used within previously proposed onium salt-based acid generators may be used. Examples of such anion moieties include fluorinated alkylsulfonic acid ions such as anion moieties (R⁴″SO₃⁻) for onium salt-based acid generators represented by general formula (b-1) or (b-2) shown above, and anion moieties represented by general formula (b-3) or (b-4) shown above. Among these, fluorinated alkylsulfonic acid ions are preferred, fluorinated alkylsulfonic acid ions of 1 to 4 carbon atoms are more preferred, and linear perfluoroalkylsulfonic acid ions of 1 to 4 carbon atoms are particularly desirable. Specific examples include a trifluoromethylsulfonic acid ion, heptafluoro-n-propylsulfonic ion and nonafluoro-n-butylsulfonic acid ion.

In the present specification, an oxime sulfonate-based acid generator is a compound having at least one group represented by general formula (B-1) shown below, and has a feature of generating acid by irradiation. Such oxime sulfonate-based acid generators are widely used for chemically amplified resist compositions, and can be selected as appropriate.

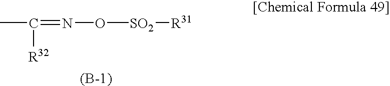

[wherein R³¹ and R³² each independently represents an organic group.]

The organic group for R³¹ and R³² refers to a group containing a carbon atom, and may include atoms other than carbon atoms (for example, a hydrogen atom, an oxygen atom, a nitrogen atom, a sulfur atom, a halogen atom (such as a fluorine atom or a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched or cyclic alkyl group having 1 to 6 carbon atoms. The expression “have a substituent” means that some or all of the hydrogen atoms of the alkyl group or the aryl group are substituted with substituents.

The alkyl group preferably contains 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which some of the hydrogen atoms are substituted with halogen atoms, and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably contains 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms, and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched or cyclic alkyl group or aryl group, or a cyano group is preferable. Examples of the alkyl group and the aryl group for R³² are the same as those of the alkyl group and the aryl group for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below.

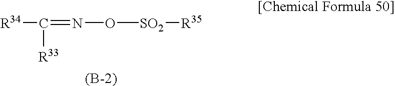

[wherein R³³ represents a cyano group, an alkyl group having no substituent or a halogenated alkyl group, R³⁴ represents an aryl group, and R³⁵ represents an alkyl group having no substituent or a halogenated alkyl group.]

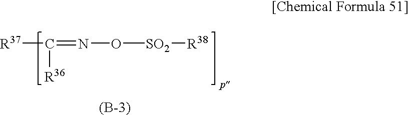

[wherein R³⁶ represents a cyano group, an alkyl group having no substituent or a halogenated alkyl group, R³⁷ represents a divalent or trivalent aromatic hydrocarbon group, R³⁸ represents an alkyl group having no substituent or a halogenated alkyl group, and p″ represents 2 or 3.]

In general formula (B-2), the alkyl group having no substituent or the halogenated alkyl group for R³³ preferably contains 1 to 10 carbon atoms, more preferably 1 to 8 carbon atoms, and most preferably 1 to 6 carbon atoms.

As R³³, a halogenated alkyl group is preferred, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably contains 1 to 8 carbon atoms, and more preferably 1 to 4 carbon atoms. The halogenated alkyl group is preferably a fluorinated alkyl group.

The alkyl group having no substituent or the halogenated alkyl group for R³⁵ preferably contains 1 to 10 carbon atoms, more preferably 1 to 8 carbon atoms, and most preferably 1 to 6 carbon atoms.

As R³⁵, a halogenated alkyl group is preferred, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms have been substituted with fluorine atoms is particularly desirable.

In general formula (B-3), the alkyl group having no substituent and the halogenated alkyl group for R³⁶ are the same as the alkyl group having no substituent and the halogenated alkyl group for R³³.

Examples of the divalent or trivalent aromatic hydrocarbon group for R³⁷ include groups in which one or two hydrogen atoms respectively have been removed from the aryl group for R³⁴.

As the alkyl group having no substituent or the halogenated alkyl group for R³⁸, the same groups as the alkyl group having no substituent or the halogenated alkyl group for R³⁵ can be used.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyinino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α- (ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described on pages 65 to 85) may be used favorably.

Furthermore, as preferable examples, the following can be exemplified.

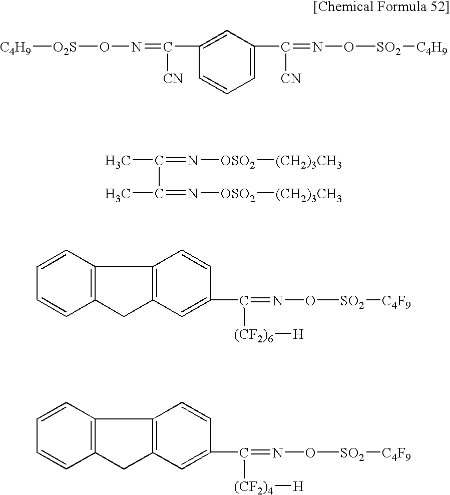

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be used favorably.

Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane may be exemplified.

As the component (B), one of the above types of acid generator may be used alone, or two or more types may be used in combination.

In the present invention, as the component (B), it is preferable to use an onium salt-based acid generator having a fluorinated alkylsulfonic acid ion that may have a substituent as the anion moiety.

The amount of the component (B) within the resist composition for immersion exposure according to the present invention is preferably within a range from 0.5 to 50 parts by weight, and more preferably from 1 to 30 parts by weight, relative to 100 parts by weight of the component (A). When the amount of the component (B) is within the above-mentioned range, formation of a resist pattern can be performed satisfactorily. Further, by virtue of the above-mentioned range, a uniform solution can be obtained and the storage stability becomes satisfactory.

### <Component (C)>

The component (C) is the fluorine-containing copolymer (C) of the present invention described above.

As the component (C), one type of fluorine-containing copolymer may be used, or two or more types may be used in combination.

The amount of the component (C) within the resist composition for immersion exposure according to the present invention is preferably within a range from 0.1 to 20 parts by weight, more preferably from 0.5 to 15 parts by weight, and still more preferably from 1 to 15 parts by weight, relative to 100 parts by weight of the component (A). By making the amount of the component (C) at least as large as the lower limit of the above-mentioned range, the hydrophobicity of the resist film formed using the resist composition for immersion exposure improves, yielding a level of hydrophobicity that is ideal for immersion exposure, whereas by ensuring that the amount of the component (C) is no greater than the upper limit of the above range, the lithography properties are improved.

### <Optional Components>

In the resist composition for immersion exposure according to the present invention, in order to improve the resist pattern shape and the post exposure stability of the latent image formed by the pattern-wise exposure of the resist layer, a nitrogen-containing organic compound (D) (hereafter referred to as “component (D)”) can be added as an optional component.

A multitude of these components (D) have already been proposed, and any of these known compounds may be used, although an aliphatic amine, and particularly a secondary aliphatic amine or tertiary aliphatic amine is preferable. An aliphatic amine is an amine having one or more aliphatic groups, and the aliphatic groups preferably contain 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (namely, alkylamines or alkyl alcohol amines), and cyclic amines.

Specific examples of alkylamines and alkyl alcohol amines include monoalkylamines such as n-hexylamine, n-heptylamine, n-octylamine, n-nonylamine and n-decylamine; dialkylamines such as diethylamine, di-n-propylamine, di-n-heptylamine, di-n-octylamine and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine and tri-n-dodecylamine; and alkyl alcohol amines such as diethanolamine, triethanolamine, diisopropanolamine, triisopropanolamine, di-n-octanolamine and tri-n-octanolamine. Among these, trialkylamines of 5 to 10 carbon atoms are preferred, and tri-n-pentylamine is particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably contains 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

These compounds may be used either alone, or in combinations of two or more different compounds.

The component (D) is typically used in an amount within a range from 0.01 to 5.0 parts by weight, relative to 100 parts by weight of the component (A).

Furthermore, in the resist composition for immersion exposure according to the present invention, in order to prevent any deterioration in sensitivity and improve the resist pattern shape and the post exposure stability of the latent image formed by the pattern-wise exposure of the resist layer, at least one compound (E) (hereafter referred to as “component (E)”) selected from the group consisting of organic carboxylic acids, and phosphorus oxo acids and derivatives thereof can be added.

Examples of suitable organic carboxylic acids include acetic acid, malonic acid, citric acid, malic acid, succinic acid, benzoic acid and salicylic acid.

Examples of phosphorus oxo acids or derivatives thereof include phosphoric acid, phosphonic acid and phosphinic acid. Among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include alkyl groups of 1 to 5 carbon atoms and aryl groups of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid ester.

As the component (E), one type of compound may be used alone, or two or more types may be used in combination.

The component (E) is typically used in an amount within a range from 0.01 to 5.0 parts by weight, relative to 100 parts by weight of the component (A).

If desired, other miscible additives can also be added to the resist composition for immersion exposure according to the present invention. Examples of such miscible additives include additive resins for improving the performance of the resist film, surfactants for improving the applicability, dissolution inhibitors, plasticizers, stabilizers, colorants, halation prevention agents and dyes.

### <Organic Solvent (S)>

The resist composition for immersion exposure according to the present invention can be prepared by dissolving the materials for the resist composition in an organic solvent (S) (hereafter, frequently referred to as “component (S)”).

The component (S) may be any organic solvent which can dissolve the respective components to give a uniform solution, and any one or more types of organic solvent can be appropriately selected from those that have been conventionally known as solvents for chemically amplified resists.

Examples thereof include lactones such as y-butyrolactone; ketones such as acetone, methyl ethyl ketone, cyclohexanone, methyl-n-pentyl ketone, methyl isopentyl ketone and 2-heptanone; polyhydric alcohols such as ethylene glycol, diethylene glycol, propylene glycol and dipropylene glycol; polyhydric alcohol derivatives including compounds having an ester bond such as ethylene glycol monoacetate, diethylene glycol monoacetate, propylene glycol monoacetate and dipropylene glycol monoacetate, and compounds having an ether bond such as a monoalkyl ether (such as a monomethyl ether, monoethyl ether, monopropyl ether or monobutyl ether) or a monophenyl ether of any of the above polyhydric alcohols or compounds having an ester bond [among these derivatives, propylene glycol monomethyl ether acetate (PGMEA) and propylene glycol monomethyl ether (PGME) are preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene and mesitylene.

These organic solvents may be used individually, or as mixed solvents containing two or more solvents.

Among these, propylene glycol monomethyl ether acetate (PGMEA), propylene glycol monomethyl ether (PGME), and ethyl lactate (EL) are preferred.

Further, among the mixed solvents, a mixed solvent obtained by mixing PGMEA with a polar solvent is preferred. The mixing ratio (weight ratio) of the mixed solvent can be determined appropriately with due consideration of the compatibility of the PGMEA with the polar solvent, but is preferably in the range of 1:9 to 9:1, and more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferred. The mixing ratio (former:latter) of such a mixed solvent is preferably from 70:30 to 95:5.

The amount of the component (S) is not particularly limited, and may be adjusted appropriately to a concentration that enables coating of a coating solution to a substrate in accordance with the thickness of the coating film. In general, the organic solvent is used in an amount that yields a solid content for the resist composition that is within a range from 2 to 20% by weight, and preferably from 5 to 15% by weight.

Dissolving of the materials in the component (S) can be conducted by simply mixing and stirring each of the above components together using conventional methods, and where required, the composition may also be mixed and dispersed using a dispersion device such as a dissolver, a homogenizer, or a triple roll mill. Furthermore, following mixing, the composition may also be filtered using a mesh or a membrane filter or the like.

The resist composition for immersion exposure according to the present invention has the properties required of a resist composition used in immersion lithography, namely, favorable lithography properties and favorable properties (particularly hydrophobicity) for use within an immersion exposure process, and can therefore be used very favorably for immersion exposure.

In other words, a resist film formed using the resist composition for immersion exposure according to the present invention contains the component (C) described above, namely, the fluorine-containing copolymer (C) of the present invention containing the structural unit (c1).

As described above, the structural unit (c1) includes a fluorine atom, and a base dissociable group bonded to a hydrophilic group as represented by -Q²-R². As a result, the component (C) has a high hydrophobicity by virtue of containing a fluorine atom, and also exhibits a property wherein the hydrophilicity increases under basic conditions by virtue of containing the -Q²-R² group. This increase in hydrophilicity is because under the action of a base (an alkali developing solution), the —R² group dissociates, forming a hydrophilic (-Q²H) group.

Accordingly, a resist film formed using a resist composition for immersion exposure of the present invention that includes the component (C) together with the component (A) and the component (B) exhibits a high level of hydrophobicity prior to contact with an alkali developing solution (for example, during the immersion exposure), but then develops increased hydrophilicity upon contact with the alkali developing solution.

In this manner, because the hydrophobicity is high during the immersion exposure, a resist film formed using the resist composition for immersion exposure according to the present invention exhibits an extremely favorable water tracking ability, which is required when the immersion exposure is performed using a scanning-type immersion exposure apparatus such as that disclosed in Non-Patent Document 1.

Further, because the hydrophilicity is increased during alkali developing, the resist composition for immersion exposure according to the present invention can effectively reduce defects during the immersion exposure. In other words, when immersion exposure of a resist film is conducted during immersion lithography, the solubility of the exposed portions within the alkali developing solution changes. For example, in the case of a positive resist composition, the solubility of the exposed portions in the alkali developing solution increases, whereas in the case of a negative resist composition, the solubility of the exposed portions in the alkali developing solution decreases. Then, when alkali developing is conducted, the exposed portions are removed in the case of the positive composition, and the unexposed portions are removed in the case of the negative composition, in either case leading to the formation of a resist pattern.

During the alkali developing, the surface of those portions of the resist film that have not been not irradiated during the immersion exposure (for example, the unexposed portions of a positive resist) are often prone to post-developing defects caused by the immersion medium such as water (such as water mark defects). However, because a resist film formed using the resist composition for immersion exposure according to the present invention exhibits increased hydrophilicity during developing, it is able to reduce the occurrence of these defects.

A resist composition for immersion exposure according to the present invention that includes, as the component (C), a fluorine-containing copolymer that contains a structural unit (c2) containing an acid dissociable group in addition to the structural unit (c1), is able to form a more favorable resist pattern than a resist composition for immersion exposure that does not include such a component (C). The reason that this effect is obtained is not entirely clear, but is thought to be due to the fact that the acid dissociable group undergoes no change in structure within the unexposed portions, but dissociates due to the acid generated from the component (B) in the exposed portions, and as a result, including a fluorine-containing copolymer that contains the structural unit (c2) enables a magnification of the change in solubility in the alkali developing solution that is observed for the resist composition for immersion exposure under the action of acid. For example, in the case where the resist composition for the present invention is a positive resist composition, the immersion exposure causes the acid dissociable group of the structural unit (c2) to dissociate within the exposed portions, thereby yielding a larger increase in the solubility of the exposed portions in the alkali developing solution. In other words, it is thought that a solubility acceleration effect manifests within the exposed portions of the component (C), and that this effect enables the formation of a more favorable resist pattern.

Further, by using the resist composition for immersion exposure according to the present invention, substance elution from the resist film during immersion exposure can be suppressed.

As described above, immersion exposure is a technique that includes a step of conducting exposure (immersion exposure) in a state where the region between the lens and the resist film formed on the wafer, which has conventionally been filled with air or an inert gas such as nitrogen, is filled with a solvent (a liquid immersion medium) having a larger refractive index than the refractive index of air. In immersion exposure, when the resist film and the immersion solvent make contact, elution of substances within the resist film (such as the component (B) and the component (D)) into the immersion solvent (namely, substance elution) tends to occur. This substance elution causes phenomena such as degeneration of the resist layer and variation in the refractive index of the immersion solvent, causing a deterioration in the lithography properties.

The amount of this substance elution is affected by the properties of the resist film surface (such as the hydrophilicity or hydrophobicity). Accordingly, it is thought that by increasing the hydrophobicity of the resist film surface, the degree of substance elution can be reduced.

A resist film formed using the resist composition for immersion exposure according to the present invention includes the fluorine atom-containing component (C), and therefore has a higher level of hydrophobicity prior to exposure and developing than a resist film that does not include the component (C). Accordingly, the resist composition for immersion exposure according to the present invention can inhibit substance elution during immersion exposure.

Because it enables suppression of substance elution, using the resist composition for immersion exposure of the present invention also enables suppression of degeneration of the resist film and variation in the refractive index of the immersion solvent during immersion exposure. By suppressing fluctuation in the refractive index of the immersion solvent, the shape and the like of the resulting resist pattern can be improved. Further, staining of the lens of the exposure apparatus can also be reduced. As a result, protective measures for preventing such staining need not be performed, which contributes to a simplification of both the process and the exposure apparatus.

Further, a resist film formed using the resist composition for immersion exposure according to the present invention is resistant to swelling in water, meaning a very fine resist pattern can be formed with superior precision.

Furthermore, the resist composition for immersion exposure according to the present invention also exhibits favorable lithography properties such as sensitivity, resolution and etching resistance, and when used as a resist in an actual immersion exposure, is capable of forming a favorable resist pattern without any practical difficulties. For example, by using the resist composition for immersion exposure according to the present invention, a very fine resist pattern with dimensions of not more than 120 nm can be formed.

The hydrophobicity of a resist film can be evaluated by measuring the contact angles relative to water, such as the static contact angle (the contact angle between the surface of a water droplet on the resist film in a horizontal state and the resist film surface), and the dynamic contact angles (including the contact angle at which a water droplet starts to slide when the resist film is inclined (the sliding angle), the contact angle at the front-end point of the water droplet in the sliding direction (the advancing angle), and the contact angle at the rear-end point of the water droplet in the sliding direction (the receding angle)). For example, the higher the hydrophobicity of the resist film, the larger the static contact angle, the advancing angle and the receding angle, but the smaller the sliding angle.

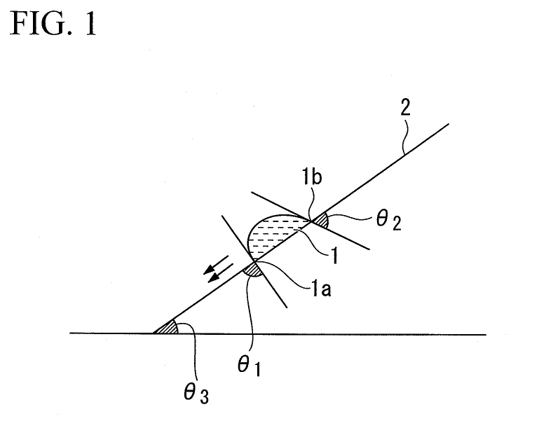

As shown in FIG. 1, when a flat surface 2 with a liquid droplet 1 placed thereon is gradually inclined, the advancing angle describes the angle θ₁ between the surface of the liquid droplet at the bottom edge 1a of the liquid droplet 1 and the flat surface 2 when the liquid droplet 1 starts to move (slide) down the flat surface 2. Further, at this point (the point when the liquid droplet 1 starts to move (slide) down the flat surface 2), the angle θ₂ between the surface of the liquid droplet at the top edge 1b of the liquid droplet 1 and the flat surface 2 is the receding angle, and the inclination angle θ₃ of the flat surface 2 is the sliding angle.

In the present description, the advancing angle, the receding angle, and the sliding angle are measured in the following manner.

First, a resist composition solution is spin-coated onto a silicon substrate, and is then heated at a temperature of 110° C. for 60 seconds to form a resist film.

Subsequently, the contact angles for the resist film can be measured using a commercially available measurement apparatus such as a DROP MASTER-700 (a product name, manufactured by Kyowa Interface Science Co. Ltd.), an AUTO SLIDING ANGLE: SA-30DM (a product name, manufactured by Kyowa Interface Science Co. Ltd.), or an AUTO DISPENSER: AD-31 (a product name, manufactured by Kyowa Interface Science Co. Ltd.).

For a resist film obtained using the resist composition for immersion exposure according to the present invention, the receding angle measured prior to immersion exposure and developing is preferably 50 degrees or more, more preferably from 50 to 150 degrees, still more preferably from 50 to 130 degrees, and most preferably from 53 to 100 degrees. When the receding angle is at least as large as the lower limit of the above-mentioned range, the suppression effect on substance elution during the immersion exposure is enhanced. The reason for this observation is not entirely clear, but it is presumed that one of the main reasons is related to the hydrophobicity of the resist film. More specifically, it is presumed that because an aqueous substance such as water is used as the immersion medium, higher hydrophobicity has an influence on the swift removal of the immersion medium from the surface of the resist film after the immersion exposure. On the other hand, ensuring that the receding angle is no higher than the upper limit of the above range yields more favorable lithography properties.

For similar reasons, for a resist film obtained using the resist composition for immersion exposure according to the present invention, the static contact angle measured prior to immersion exposure and developing is preferably 60 degrees or greater, more preferably from 63 to 95 degrees, and most preferably from 65 to 95 degrees.

Furthermore, for a resist film obtained using the resist composition for immersion exposure according to the present invention, the sliding angle measured prior to immersion exposure and developing is preferably no more than 36 degrees, more preferably from 10 to 36 degrees, still more preferably from 7 to 30 degrees, and most preferably from 14 to 27 degrees. When the sliding angle is no higher than the upper limit of the above-mentioned range, the suppression effect on substance elution during the immersion exposure is enhanced. In contrast, ensuring that the sliding angle is at least as large as the lower limit of the above range yields more favorable lithography properties.

The magnitude of the various angles described above (the dynamic contact angles (advancing angle, receding angle, and sliding angle) and the static contact angle) can be adjusted by altering the formulation for the resist composition for immersion exposure, for example by varying the type or amount of the component (C) and varying the type of the component (A). For example, the larger the amount of the component (C), the higher the hydrophobicity of the obtained resist composition, and hence, the larger the advancing angle, the receding angle and the static contact angle, and the smaller the sliding angle.

In this manner, the resist composition for immersion exposure according to the present invention satisfactorily exhibits all the properties required of a resist material for immersion exposure, and can therefore be used very favorably as an immersion exposure composition.

### <<Method of Forming a Resist Pattern>>

The method of forming a resist pattern according to the present invention includes: forming a resist film on a substrate using the resist composition for immersion exposure according to the present invention described above, conducting immersion exposure of the resist film; and alkali-developing the resist film to form a resist pattern.

A preferred example of the method of forming a resist pattern according to the present invention is described below.

Firstly, a resist composition for immersion exposure according to the present invention is applied onto a substrate using a spinner or the like, and a prebake (post applied bake (PAB) treatment) is conducted to form a resist film.

The substrate is not specifically limited and a conventionally known substrate can be used. For example, substrates for electronic components, and such substrates having wiring patterns formed thereon can be exemplified. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-exemplified substrates provided with an inorganic and/or organic film on the surface thereof may also be used. As the inorganic film, an inorganic antireflection film (inorganic BARC) can be exemplified. As the organic film, an organic antireflection film (organic BARC) and an organic film such as a lower-layer organic film used in a multilayer resist method can be exemplified.

Here, a “multilayer resist method” is a method in which at least one layer of an organic film (a lower-layer organic film) and at least one layer of a resist film (an upper resist film) are provided on a substrate, and a resist pattern formed on the upper resist film is used as a mask to conduct patterning of the lower-layer organic film. This method is capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method can be broadly classified into a method in which a double-layer structure consisting of an upper-layer resist film and a lower-layer organic film is formed (a double-layer resist method), and a method in which a multilayer structure having at least three layers consisting of an upper-layer resist film, a lower-layer organic film and at least one intermediate layer (a thin metal film or the like) provided between the upper-layer resist film and the lower-layer organic film is formed (a three-layer resist method).

After formation of a resist film, an organic antireflection film may be provided on the resist film, thereby forming a three-layer laminate consisting of the substrate, the resist film and the antireflection film. The antireflection film provided on top of the resist film is preferably soluble in an alkali developing solution.

The steps up until this point can be conducted by using conventional techniques. The operating conditions and the like are preferably selected appropriately in accordance with the formulation and the characteristics of the resist composition for immersion exposure being used.

Subsequently, the obtained resist film is subjected to selective immersion exposure (Liquid Immersion Lithography) through a desired mask pattern. At this time, the region between the resist film and the lens at the lowermost point of the exposure apparatus is pre-filled with a solvent (immersion medium) that has a larger refractive index than the refractive index of air, and the exposure (immersion exposure) is conducted in this state.

There are no particular limitations on the wavelength used for the exposure, and an ArF excimer laser, KrF excimer laser or F₂ laser or the like can be used. The resist composition according to the present invention is effective for KrF and ArF excimer lasers, and is particularly effective for an ArF excimer laser.

The immersion medium preferably exhibits a refractive index larger than the refractive index of air but smaller than the refractive index of the resist film formed from the resist composition for immersion exposure according to the present invention. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

A resist composition for immersion exposure according to the present invention is particularly resistant to any adverse effects caused by water, and because the resulting lithography properties such as the sensitivity and shape of the resist pattern profile are excellent, water is preferably used as the immersion medium. Furthermore, water is also preferred in terms of cost, safety, environmental friendliness, and versatility.

Subsequently, following completion of the immersion exposure step, post exposure baking (PEB) is conducted, and a developing treatment is then performed using an alkali developing solution composed of an aqueous alkali solution. Thereafter, a water rinse is preferably conducted with pure water. This water rinse can be conducted by dripping or spraying water onto the surface of the substrate while rotating the substrate, and washes away the developing solution and those portions of the resist composition for immersion exposure that have been dissolved by the developing solution. By subsequently drying the resist, a resist pattern is obtained in which the resist film (the coating of the resist composition for immersion exposure) has been patterned into a shape faithful to the mask pattern.

### EXAMPLES

As follows is a more detailed description of the present invention based on a series of examples, although the scope of the present invention is in no way limited by these examples.

[Fluorine-containing copolymers 1 to 12] described below were synthesized using [compounds 1 to 6] and [polymer compounds 19 to 21 ] shown below, using the methods described below within the examples.

In the examples below, the weight average molecular weight (hereafter frequently abbreviated as “molecular weight”) refers to the weight average molecular weight determined by GPC measurement and referenced against standard polystyrenes, whereas the polymer composition describes the proportion (molar ratio) of each of the structural units within the polymer structure.

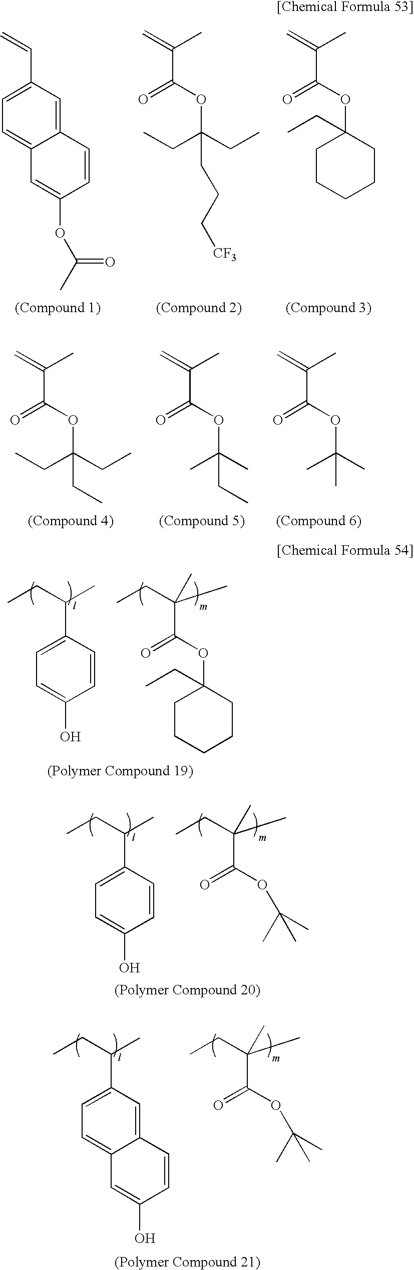

### Example 1

### (Step 1)

10.00 g (47.17 mmol) of the [compound 1] and 3.14 g (11.79 mmol) of the [compound 2] were dissolved in 74.46 g of tetrahydrofuran (THF). To this solution was added and dissolved 3.54 mmol of a polymerization initiator V-601 (manufactured by Wako Pure Chemical Industries, Ltd.). The resulting solution was then subjected to a polymerization reaction under a nitrogen atmosphere for 6 hours at 80° C. Following completion of the reaction, the reaction solution was cooled to room temperature. Subsequently, an operation in which the reaction solution was added dropwise to a large volume of methanol to precipitate the polymer was repeated three times. The thus obtained polymer was then dried under reduced pressure at room temperature, yielding 5.2 g of a white powder. This product was termed [polymer compound 1]. The molecular weight of this [polymer compound 1] was 11,300 and the degree of dispersion was 1.32.

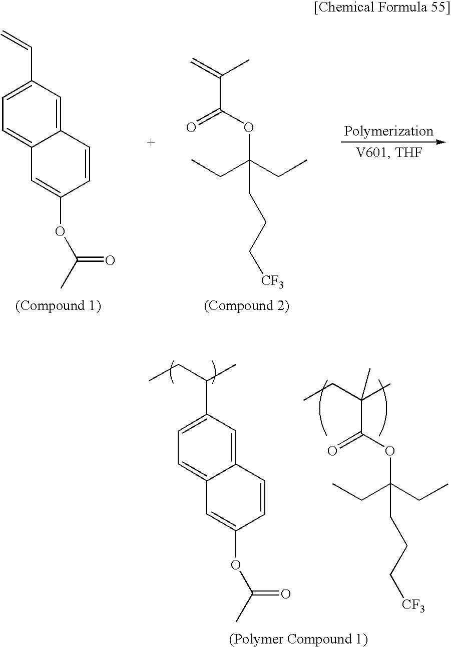

### (Step 2)

Subsequently, under a nitrogen atmosphere at 0° C., 17 g of a THF solution containing 5.2 g of the above [polymer compound 1] was prepared, and to this THF solution were added 1.46 g (11.95 mmol) of dimethylaminopyridine (DMAP) and 15.60 g of methanol. The reaction solution was returned to room temperature, and then stirred for 12 hours under heating at 70° C. Following cooling to room temperature, the solvent was removed from the reaction solution by concentration under reduced pressure, and following extraction into ethyl acetate, the resulting organic layer was washed twice with a 1N aqueous solution of hydrochloric acid and twice with water. The solvent was then removed from the organic layer by evaporation under reduced pressure, yielding 3 g of a [polymer compound 2]. Analysis of this [polymer compound 2] using ¹³C-NMR (600 MHz) to confirm the rate of deprotection of the acetyl groups revealed a deprotection rate of 100%. Further, the polymer composition of the [polymer compound 2] was l/m=86.9/13.1.

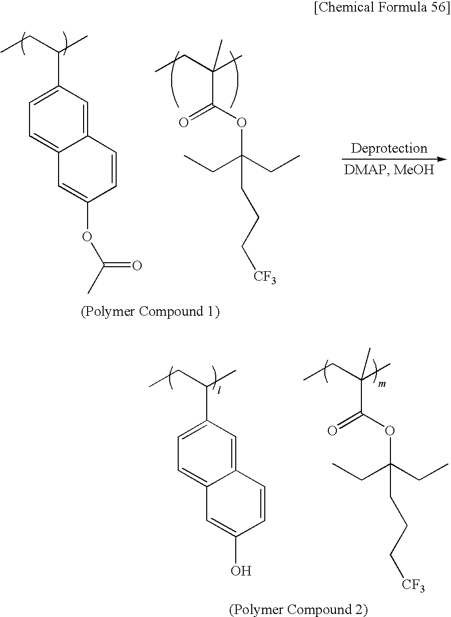

### (Step 3)

Subsequently, under a nitrogen atmosphere at 0° C., 3 g (equivalent to 14.3 mmol) of the [polymer compound 2] was added to 60 ml of a THF solution containing 2.7 g (21.5 mmol) of 3,3,3-trifluoropropionic acid, 4.1 g (21.5 mmol) of ethyldiisopropylaminocarbodiimide (EDCI) hydrochloride, and 0.08 g (0.7 mmol) of DMAP, and the resulting solution was then returned to room temperature and stirred for 3 hours. The reaction solution was then cooled to 0° C., and water was added to halt the reaction. The resulting organic layer was washed with water three times, and the solvent was then removed by evaporation under reduced pressure. A re-precipitation operation was conducted by adding a THF solution of the thus obtained crude product dropwise to heptane, thus yielding 4.3 g of the target [fluorine-containing copolymer 1] as a colorless solid (yield: 94%).

Analysis of this [fluorine-containing copolymer 1] using ¹³C-NMR to confirm the introduction of —CO—CH₂—CF₃ groups revealed an introduction rate of 74.1%. Furthermore, the molecular weight of the [fluorine-containing copolymer 1] was 13,300 and the degree of dispersion was 1.27.

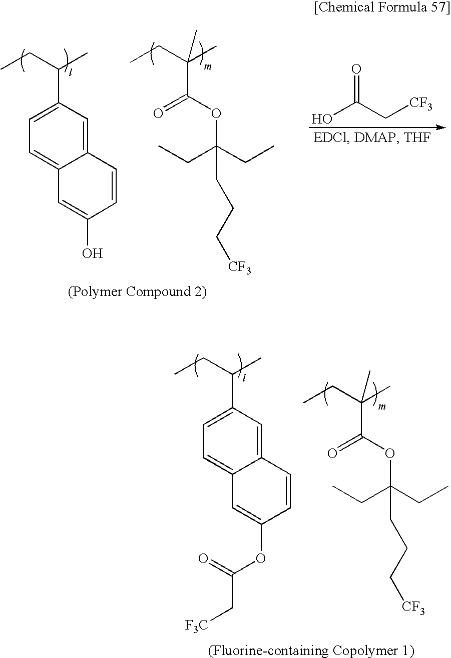

### Example 2

7.00 g (33.02 mmol) of the [compound 1] and 5.86 g (22.01 mmol) of the [compound 2] were dissolved in 72.87 g of THF. To this solution was added and dissolved 3.03 mmol of the polymerization initiator V-601, and the same procedure as that described for step 1 of Example 1 was then used to obtain 3.8 g of a white powder. This product was termed [polymer compound 3]. The molecular weight of this [polymer compound 3] was 11,000 and the degree of dispersion was 1.23.

Subsequently, under a nitrogen atmosphere at 0° C., 13 g of a THF solution containing 3.8 g of the above [polymer compound 3] was prepared, and to this THF solution were added 1.04 g (8.54 mmol) of DMAP and 11.46 g of methanol. The same procedure as that described for step 2 of Example 1 was then used to obtain 3.2 g of a [polymer compound 4] from the [polymer compound 3]. Analysis of this [polymer compound 4] using ¹³C-NMR to confirm the rate of deprotection of the acetyl groups revealed a deprotection rate of 100%. Further, the polymer composition of the [polymer compound 4] was l/m=74.8/25.2, the weight average molecular weight was 11,000, and the degree of dispersion was 1.02.

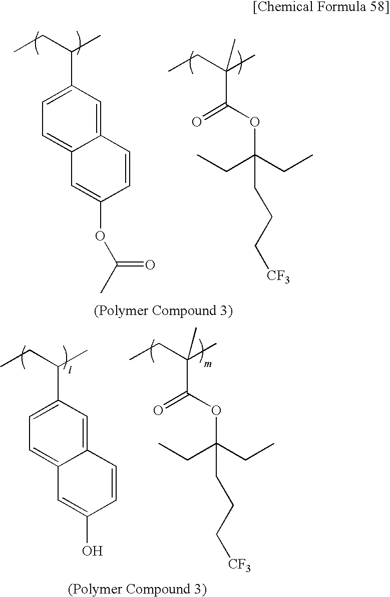

Subsequently, under a nitrogen atmosphere at 0° C., 3.2 g (equivalent to 12.4 mmol) of the [polymer compound 4] was added to 50 ml of a THF solution containing 2.4 g (18.6 mmol) of 3,3,3-trifluoropropionic acid, 3.7 g (18.6 mmol) of EDCI hydrochloride, and 0.07 g (0.6 mmol) of DMAP, and the same procedure as that described for step 3 of Example 1 was then used to obtain 4.1 g of a colorless solid of a [fluorine-containing copolymer 2] (yield: 84%) from the [polymer compound 4]. Analysis of this [fluorine-containing copolymer 2] using ¹³C-NMR to confirm the introduction of —CO—CH₂—CF₃ groups revealed an introduction rate of >99%. Furthermore, the molecular weight of the [fluorine-containing copolymer 2] was 12,800 and the degree of dispersion was 1.21.

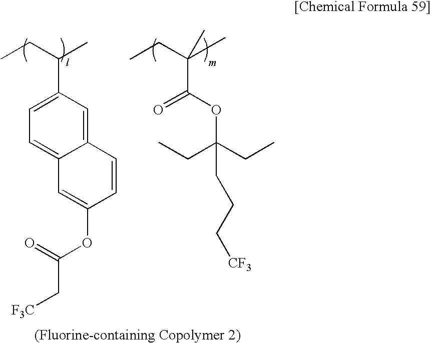

### Example 3

10.00 g (47.17 mmol) of the [compound 1] and 6.16 g (31.45 mmol) of the [compound 3] were dissolved in 91.57 g of THF. To this solution was added and dissolved 4.72 mmol of the polymerization initiator V-601, and the same procedure as that described for step 1 of Example 1 was then used to obtain 7.6 g of a white powder. This product was termed [polymer compound 5]. The molecular weight of this [polymer compound 5] was 8,800 and the degree of dispersion was 1.28.

Subsequently, under a nitrogen atmosphere at 0° C., 25 g of a THF solution containing 7.6 g of the above [polymer compound 5] was prepared, and to this THF solution were added 2.27 g (18.58 mmol) of DMAP and 22.89 g of methanol. The same procedure as that described for step 2 of Example 1 was then used to obtain 3.9 g of a [polymer compound 6] from the [polymer compound 5]. Analysis of this [polymer compound 6] using ¹³C-NMR to confirm the rate of deprotection of the acetyl groups revealed a deprotection rate of 100%. Further, the polymer composition of the [polymer compound 6] was l/m=76.3/23.7, the weight average molecular weight was 6,800, and the degree of dispersion was 1.30.

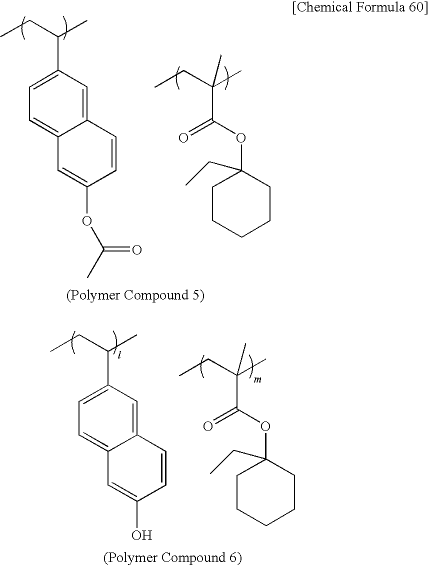

Subsequently, under a nitrogen atmosphere at 0° C., 3.9 g (equivalent to 22.9 mmol) of the [polymer compound 6] was added to 50 ml of a THF solution containing 4.4 g (34.4 mmol) of 3,3,3-trifluoropropionic acid, 6.6 g (34.4 mmol) of EDCI hydrochloride, and 0.14 g (1.15 mmol) of DMAP, and the same procedure as that described for step 3 of Example 1 was then used to obtain 6.3 g of a colorless solid of a [fluorine-containing copolymer 3] (yield: 78%) from the [polymer compound 6]. Analysis of this [fluorine-containing copolymer 3] using ¹³C-NMR to confirm the introduction of —CO—CH₂—CF₃ groups revealed an introduction rate of >99%. Furthermore, the molecular weight of the [fluorine-containing copolymer 3] was 11,000 and the degree of dispersion was 1.24.

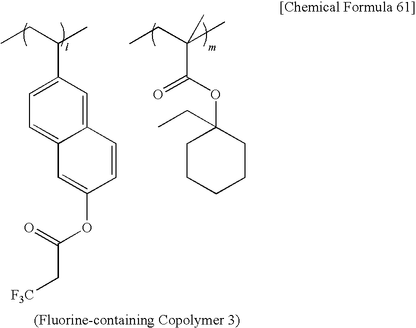

### Example 4

10.00 g (47.17 mmol) of the [compound 1] and 13.87 g (70.76 mmol) of the [compound 3] were dissolved in 135.26 g of THF. To this solution was added and dissolved 4.72 mmol of the polymerization initiator V-601, and the same procedure as that described for step 1 of Example 1 was then used to obtain 6.3 g of a white powder. This product was termed [polymer compound 7]. The molecular weight of this [polymer compound 7] was 9,300 and the degree of dispersion was 1.25.

Subsequently, under a nitrogen atmosphere at 0° C., 21 g of a THF solution containing 6.3 g of the above [polymer compound 7] was prepared, and to this THF solution were added 1.90 g (15.55 mmol) of DMAP and 18.90 g of methanol. The same procedure as that described for step 2 of Example 1 was then used to obtain 6.3 g of a [polymer compound 8] from the [polymer compound 7]. Analysis of this [polymer compound 8] using ¹³C-NMR to confirm the rate of deprotection of the acetyl groups revealed a deprotection rate of 100%. Further, the polymer composition of the [polymer compound 8] was l/m=59.5/40.5, the weight average molecular weight was 7,600, and the degree of dispersion was 1.27.

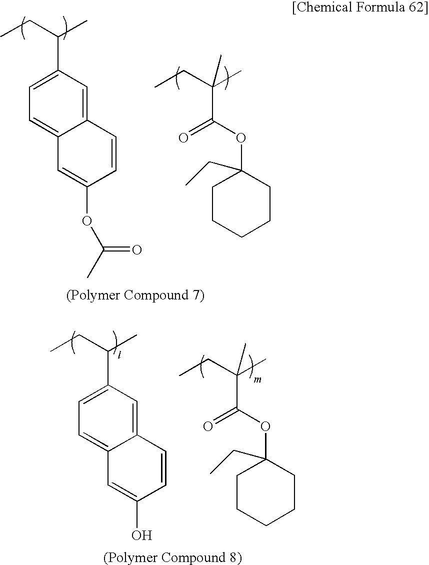

Subsequently, under a nitrogen atmosphere at 0° C., 6.3 g (equivalent to 20.9 mmol) of the [polymer compound 8] was added to 50 ml of a THF solution containing 4.0 g (31.4 mmol) of 3,3,3-trifluoropropionic acid, 6.0 g (31.4 mmol) of EDCI hydrochloride, and 0.12 g (1.0 mmol) of DMAP, and the same procedure as that described for step 3 of Example 1 was then used to obtain 7.5 g of a colorless solid of a [fluorine-containing copolymer 4] (yield: 87%) from the [polymer compound 8]. Analysis of this [fluorine-containing copolymer 4] using ¹³C-NMR to confirm the introduction of —CO—CH₂—CF₃ groups revealed an introduction rate of >99%. Furthermore, the molecular weight of the [fluorine-containing copolymer 4] was 11,500 and the degree of dispersion was 1.21.

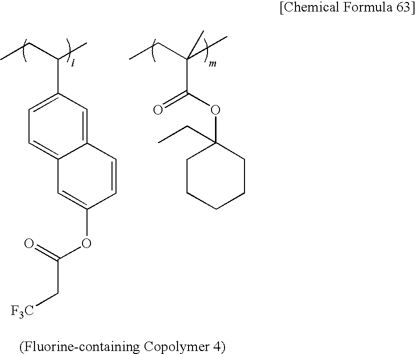

### Example 5

10.00 g (47.17 mmol) of the [compound 1] and 9.25 g (47.17 mmol) of the [compound 3] were dissolved in 109.08 g of THF. To this solution was added and dissolved 3.77 mmol of the polymerization initiator V-601, and the same procedure as that described for step 1 of Example 1 was then used to obtain 6.3 g of a white powder. This product was termed [polymer compound 9]. The molecular weight of this [polymer compound 9] was 9,900 and the degree of dispersion was 1.27.

Subsequently, under a nitrogen atmosphere at 0° C., 21 g of a THF solution containing 6.3 g of the above [polymer compound 9] was prepared, and to this THF solution were added 1.90 g (15.55 mmol) of DMAP and 18.90 g of methanol. The same procedure as that described for step 2 of Example 1 was then used to obtain 5.8 g of a [polymer compound 10] from the [polymer compound 9]. Analysis of this [polymer compound 10] using ¹³C-NMR to confirm the rate of deprotection of the acetyl groups revealed a deprotection rate of 100%. Further, the polymer composition of the [polymer compound 10] was l/m=69.1/30.9, the weight average molecular weight was 7,800, and the degree of dispersion was 1.29.

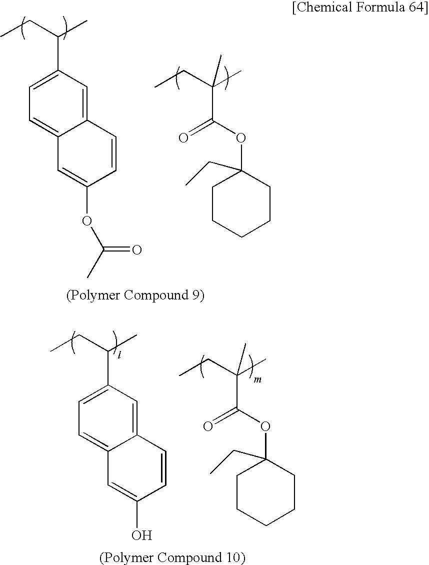

Subsequently, under a nitrogen atmosphere at 0° C., 5.8 g (equivalent to 22.8 mmol) of the [polymer compound 10] was added to 50 ml of a THF solution containing 4.4 g (34.2 mmol) of 3,3,3-trifluoropropionic acid, 6.6 g (34.2 mmol) of EDCI hydrochloride, and 0.13 g (1.1 mmol) of DMAP, and the same procedure as that described for step 3 of Example 1 was then used to obtain 6.4 g of a colorless solid of a [fluorine-containing copolymer 5] (yield: 77%) from the [polymer compound 10]. Analysis of this [fluorine-containing copolymer 5] using ¹³C-NMR to confirm the introduction of —CO—CH₂—CF₃ groups revealed an introduction rate of >99%. Furthermore, the molecular weight of the [fluorine-containing copolymer 5] was 12,400 and the degree of dispersion was 1.22.

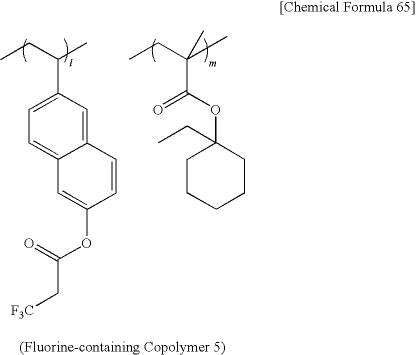

### Example 6

10.00 g (47.17 mmol) of the [compound 1] and 8.68 (47.17 mmol) of the [compound 4] were dissolved in 105.85 g of THF. To this solution was added and dissolved 3.77 mmol of the polymerization initiator V-601, and the same procedure as that described for step 1 of Example 1 was then used to obtain 4.3 g of a white powder. This product was termed [polymer compound 11]. The molecular weight of this [polymer compound 11] was 10,400 and the degree of dispersion was 1.23.

Subsequently, under a nitrogen atmosphere at 0° C., 14 g of a THF solution containing 4.3 g of the above [polymer compound 11] was prepared, and to this THF solution were added 1.33 g (10.89 mmol) of DMAP and 12.90 g of methanol. The same procedure as that described for step 2 of Example 1 was then used to obtain 4.3 g of a [polymer compound 12] from the [polymer compound 11]. Analysis of this [polymer compound 12] using ¹³C-NMR to confirm the rate of deprotection of the acetyl groups revealed a deprotection rate of 100%. Further, the polymer composition of the [polymer compound 12] was l/m=69.3/30.7, the weight average molecular weight was 8,300, and the degree of dispersion was 1.25.

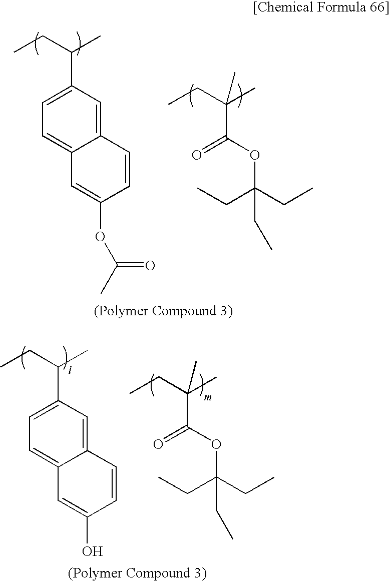

Subsequently, under a nitrogen atmosphere at 0° C., 4.3 g (equivalent to 17.0 mmol) of the [polymer compound 12] was added to 50 ml of a THF solution containing 3.3 g (25.5 mmol) of 3,3,3-trifluoropropionic acid, 4.9 g (25.5 mmol) of EDCI hydrochloride, and 0.12 g (1.0 mmol) of DMAP, and the same procedure as that described for step 3 of Example 1 was then used to obtain 5.3 g of a colorless solid of a [fluorine-containing copolymer 6] (yield: 85%) from the [polymer compound 12]. Analysis of this [fluorine-containing copolymer 6] using ¹³C-NMR to confirm the introduction of —CO—CH₂—CF₃ groups revealed an introduction rate of >99%. Furthermore, the molecular weight of the [fluorine-containing copolymer 6] was 13,000 and the degree of dispersion was 1.19.

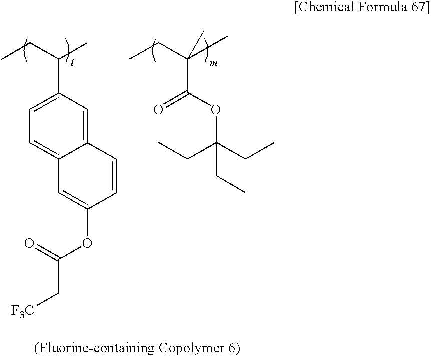

### Example 7

20.00 g (94.34 mmol) of the [compound 1] and 26.04 (141.51 mmol) of the [compound 4] were dissolved in 260.89 g of THF. To this solution was added and dissolved 9.43 mmol of the polymerization initiator V-601, and the same procedure as that described for step 1 of Example 1 was then used to obtain 10.20 g of a white powder. This product was termed [polymer compound 13]. The molecular weight of this [polymer compound 13] was 10,100 and the degree of dispersion was 1.20.

Subsequently, under a nitrogen atmosphere at 0° C., 34 g of a THF solution containing 10.20 g of the above [polymer compound 13] was prepared, and to this THF solution were added 3.19 g (26.11 mmol) of DMAP and 30.60 g of methanol. The same procedure as that described for step 2 of Example 1 was then used to obtain 4.3 g of a [polymer compound 14] from the [polymer compound 13]. Analysis of this [polymer compound 14] using ¹³C-NMR to confirm the rate of deprotection of the acetyl groups revealed a deprotection rate of 100%. Further, the polymer composition of the [polymer compound 14] was l/m=62.0/38.0, the weight average molecular weight was 8,300, and the degree of dispersion was 1.21.

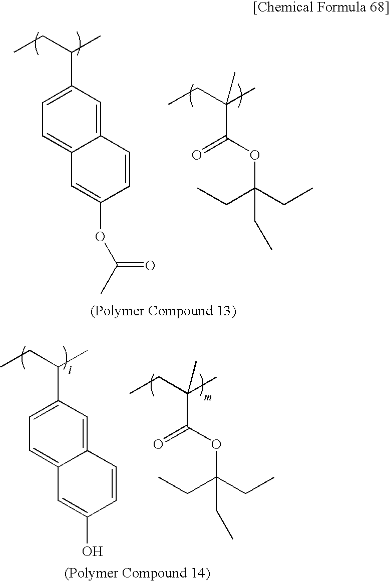

Subsequently, under a nitrogen atmosphere at 0° C., 4.3 g (equivalent to 15.2 mmol) of the [polymer compound 14] was added to 50 ml of a THF solution containing 2.9 g (22.8 mmol) of 3,3,3-trifluoropropionic acid, 4.4 g (22.8 mmol) of EDCI hydrochloride, and 0.1 g (0.8 mmol) of DMAP, and the same procedure as that described for step 3 of Example 1 was then used to obtain 5.3 g of a colorless solid of a [fluorine-containing copolymer 7] (yield: 89%) from the [polymer compound 14]. Analysis of this [fluorine-containing copolymer 7] using ¹³C-NMR to confirm the introduction of —CO—CH₂—CF₃ groups revealed an introduction rate of >99%. Furthermore, the molecular weight of the [fluorine-containing copolymer 7] was 12,300 and the degree of dispersion was 1.17.

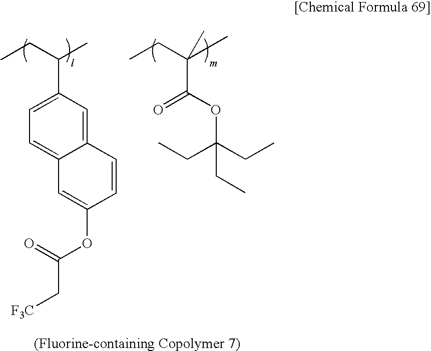

### Example 8

20.00 g (94.34 mmol) of the [compound 1] and 22.08 (141.51 mmol) of the [compound 5] were dissolved in 238.45 g of THF. To this solution was added and dissolved 9.43 mmol of the polymerization initiator V-601, and the same procedure as that described for step 1 of Example 1 was then used to obtain 9.61 g of a white powder. This product was termed [polymer compound 15]. The molecular weight of this [polymer compound 15] was 10,800 and the degree of dispersion was 1.22.

Subsequently, under a nitrogen atmosphere at 0° C., 32 g of a THF solution containing 9.61 g of the above [polymer compound 15] was prepared, and to this THF solution were added 3.29 g (26.93 mmol) of DMAP and 28.83 g of methanol. The same procedure as that described for step 2 of Example 1 was then used to obtain 8.7 g of a [polymer compound 16] from the [polymer compound 15]. Analysis of this [polymer compound 16] using ¹³C-NMR to confirm the rate of deprotection of the acetyl groups revealed a deprotection rate of 100%. Further, the polymer composition of the [polymer compound 16] was l/m=62.1/37.9, the weight average molecular weight was 8,900, and the degree of dispersion was 1.22.

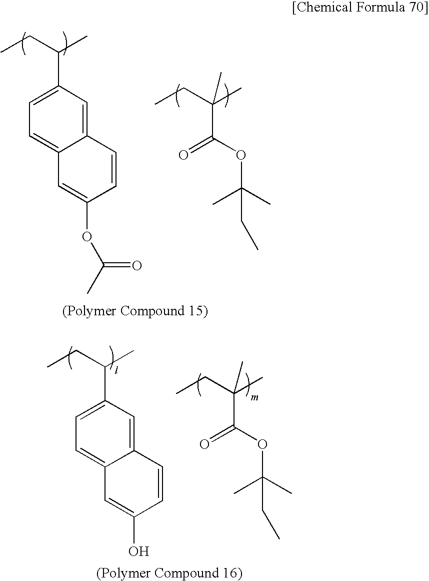

Subsequently, under a nitrogen atmosphere at 0° C., 8.7 g (equivalent to 31.7 mmol) of the [polymer compound 16] was added to 50 ml of a THF solution containing 6.1 g (47.6 mmol) of 3,3,3-trifluoropropionic acid, 9.1 g (47.6 mmol) of EDCI hydrochloride, and 0.2 g (1.5 mmol) of DMAP, and the same procedure as that described for step 3 of Example 1 was then used to obtain 9.8 g of a colorless solid of a [fluorine-containing copolymer 8] (yield: 80%) from the [polymer compound 16]. Analysis of this [fluorine-containing copolymer 8] using ¹³C-NMR to confirm the introduction of —CO—CH₂—CF₃ groups revealed an introduction rate of >99%. Furthermore, the molecular weight of the [fluorine-containing copolymer 8] was 13,100 and the degree of dispersion was 1.17.

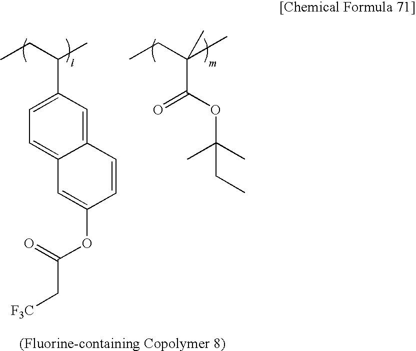

### Example 9

20.00 g (94.34 mmol) of the [compound 1] and 20.09 (141.51 mmol) of the [compound 6] were dissolved in 227.18 g of THF. To this solution was added and dissolved 9.43 mmol of the polymerization initiator V-601, and the same procedure as that described for step 1 of Example 1 was then used to obtain 10.50 g of a white powder. This product was termed [polymer compound 17]. The molecular weight of this [polymer compound 17] was 10,700 and the degree of dispersion was 1.24.

Subsequently, under a nitrogen atmosphere at 0° C., 35 g of a THF solution containing 10.50 g of the above [polymer compound 17] was prepared, and to this THF solution were added 3.77 g (30.88 mmol) of DMAP and 31.50 g of methanol. The same procedure as that described for step 2 of Example 1 was then used to obtain 9.0 g of a [polymer compound 18] from the [polymer compound 17]. Analysis of this [polymer compound 18] using ¹³C-NMR to confirm the rate of deprotection of the acetyl groups revealed a deprotection rate of 100%. Further, the polymer composition of the [polymer compound 18] was l/m=61.8/38.2, the weight average molecular weight was 8,800, and the degree of dispersion was 1.24.

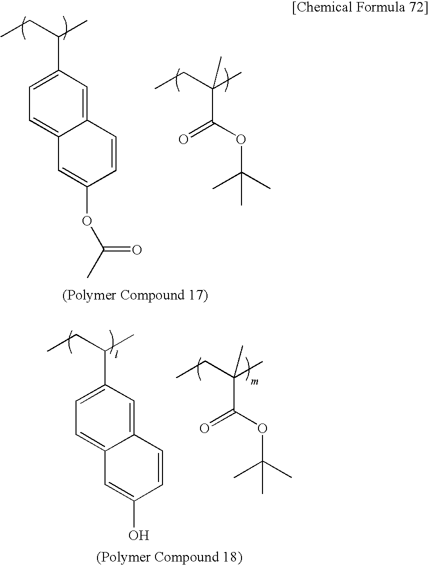

Subsequently, under a nitrogen atmosphere at 0° C., 9.0 g (equivalent to 35.0 mmol) of the [polymer compound 18] was added to 50 ml of a THF solution containing 6.7 g (52.5 mmol) of 3,3,3-trifluoropropionic acid, 10.0 g (52.5 mmol) of EDCI hydrochloride, and 0.2 g (1.8 mmol) of DMAP, and the same procedure as that described for step 3 of Example 1 was then used to obtain 9.5 g of a colorless solid of a [fluorine-containing copolymer 9] (yield: 74%) from the [polymer compound 18]. Analysis of this [fluorine-containing copolymer 9] using ¹³C-NMR to confirm the introduction of —CO—CH₂—CF₃ groups revealed an introduction rate of >99%. Furthermore, the molecular weight of the [fluorine-containing copolymer 9] was 11,400 and the degree of dispersion was 1.28.

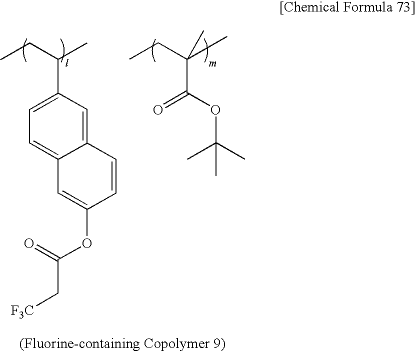

### Example 10

Under a nitrogen atmosphere at 0° C., 9.0 g (equivalent to 53.9 mmol) of the [polymer compound 19] was added to 200 ml of a THF solution containing 10.4 g (80.9 mmol) of 3,3,3-trifluoropropionic acid, 15.5 g (80.9 mmol) of EDCI hydrochloride, and 0.3 g (2.7 mmol) of DMAP, and the same procedure as that described for step 3 of Example 1 was then used to obtain 12.5 g of a colorless solid of a [fluorine-containing copolymer 10] (yield: 87%) from the [polymer compound 19] (l/m=75/25). Analysis of this [fluorine-containing copolymer 10] using ¹³C-NMR to confirm the introduction of —CO—CH₂—CF₃ groups revealed an introduction rate of >99%. Furthermore, the molecular weight of the [fluorine-containing copolymer 10] was 17,600 and the degree of dispersion was 1.54.

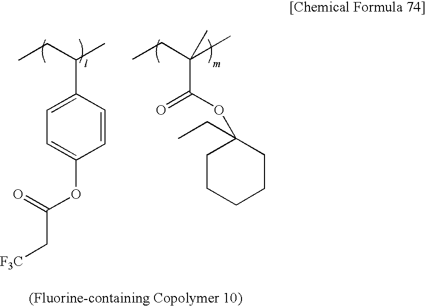

### Example 11

Under a nitrogen atmosphere at 0° C., 9.0 g (equivalent to 42.0 mmol) of the [polymer compound 20] was added to 200 ml of a THF solution containing 9.1 g (46.2 mmol) of 3,3,3-trifluoropropionic acid, 9.7 g (50.4 mmol) of EDCI hydrochloride, and 0.3 g (2.1 mmol) of DMAP, and the same procedure as that described for step 3 of Example 1 was then used to obtain 11.2 g of a colorless solid of a [fluorine-containing copolymer 11] (yield: 85%) from the [polymer compound 20] (l/m=60/40). Analysis of this [fluorine-containing copolymer 11] using ¹³C-NMR to confirm the introduction of —CO—CH₂—CF₃ groups revealed an introduction rate of >99%. Furthermore, the molecular weight of the [fluorine-containing copolymer 11] was 14,600 and the degree of dispersion was 1.46.

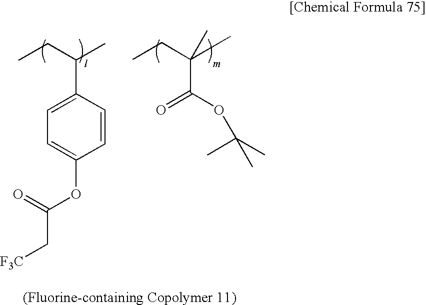

### Example 12

Under a nitrogen atmosphere at 0° C., 3.0 g (equivalent to 11.6 mmol) of the [polymer compound 21] was added to 30 ml of a THF solution containing 2.2 g (17.4 mmol) of 3,3,3-trifluoropropionic acid, 3.3 g (17.4 mmol) of EDCI hydrochloride, and 0.07 g (0.6 mmol) of DMAP, and the same procedure as that described for step 3 of Example 1 was then used to obtain 3.5 g of a colorless solid of a [fluorine-containing copolymer 12] (yield: 78%) from the [polymer compound 21] (l/m=73.6/26.4). Analysis of this [fluorine-containing copolymer 12] using ¹³C-NMR to confirm the introduction of —CO—CH₂—CF₃ groups revealed an introduction rate of >99%. Furthermore, the molecular weight of the [fluorine-containing copolymer 12] was 12,900 and the degree of dispersion was 1.32.

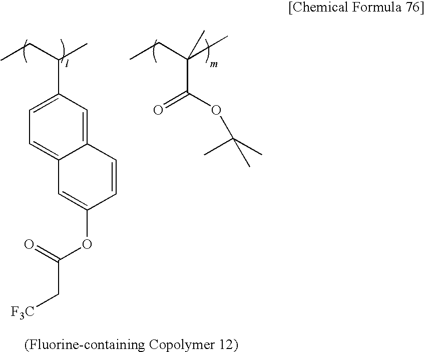

### Examples 13 to 32

The components shown below in Table 1 were mixed together and dissolved to prepare a series of resist compositions.

TABLE 1

| | Component | Component | Component | Component | Component |
|---|---|---|---|---|---|
| | (A) | (B) | (C) | (D) | (S) |
| Example 13 | (A)-1 | (B)-1 | (C)-1 | (D)-1 | (S)-1 |
| | [100] | [8.0] | [1.0] | [1.0] | [1500] |
| Example 14 | (A)-1 | (B)-1 | (C)-2 | (D)-1 | (S)-1 |
| | [100] | [8.0] | [1.0] | [1.0] | [1500] |
| Example 15 | (A)-1 | (B)-1 | (C)-3 | (D)-1 | (S)-1 |
| | [100] | [8.0] | [1.0] | [1.0] | [1500] |
| Example 16 | (A)-1 | (B)-1 | (C)-4 | (D)-1 | (S)-1 |
| | [100] | [8.0] | [1.0] | [1.0] | [1500] |
| Example 17 | (A)-1 | (B)-1 | (C)-4 | (D)-1 | (S)-1 |
| | [100] | [8.0] | [5.0] | [1.0] | [1500] |
| Example 18 | (A)-1 | (B)-1 | (C)-5 | (D)-1 | (S)-1 |
| | [100] | [8.0] | [1.0] | [1.0] | [1500] |
| Example 19 | (A)-1 | (B)-1 | (C)-6 | (D)-1 | (S)-1 |
| | [100] | [8.0] | [1.0] | [1.0] | [1500] |
| Example 20 | (A)-1 | (B)-1 | (C)-6 | (D)-1 | (S)-1 |
| | [100] | [8.0] | [3.0] | [1.0] | [1500] |
| Example 21 | (A)-1 | (B)-1 | (C)-6 | (D)-1 | (S)-1 |
| | [100] | [8.0] | [5.0] | [1.0] | [1500] |
| Example 22 | (A)-1 | (B)-1 | (C)-7 | (D)-1 | (S)-1 |
| | [100] | [8.0] | [1.0] | [1.0] | [1500] |
| Example 23 | (A)-1 | (B)-1 | (C)-8 | (D)-1 | (S)-1 |
| | [100] | [8.0] | [1.0] | [1.0] | [1500] |
| Example 24 | (A)-1 | (B)-1 | (C)-8 | (D)-1 | (S)-1 |
| | [100] | [8.0] | [3.0] | [1.0] | [1500] |
| Example 25 | (A)-1 | (B)-1 | (C)-8 | (D)-1 | (S)-1 |
| | [100] | [8.0] | [15.0] | [1.0] | [1500] |
| Example 26 | (A)-1 | (B)-1 | (C)-9 | (D)-1 | (S)-1 |
| | [100] | [8.0] | [1.0] | [1.0] | [1500] |
| Example 27 | (A)-1 | (B)-1 | (C)-9 | (D)-1 | (S)-1 |
| | [100] | [8.0] | [3.0] | [1.0] | [1500] |
| Example 28 | (A)-1 | (B)-1 | (C)-10 | (D)-1 | (S)-1 |
| | [100] | [8.0] | [1.0] | [1.0] | [1500] |
| Example 29 | (A)-1 | (B)-1 | (C)-11 | (D)-1 | (S)-1 |
| | [100] | [8.0] | [1.0] | [1.0] | [1500] |
| Example 30 | (A)-1 | (B)-1 | (C)-11 | (D)-1 | (S)-1 |
| | [100] | [8.0] | [3.0] | [1.0] | [1500] |
| Example 31 | (A)-1 | (B)-1 | (C)-11 | (D)-1 | (S)-1 |
| | [100] | [8.0] | [5.0] | [1.0] | [1500] |
| Example 32 | (A)-1 | (B)-1 | (C)-12 | (D)-1 | (S)-1 |
| | [100] | [8.0] | [1.0] | [1.0] | [1500] |

The meanings of the abbreviations used in Table 1 are as shown below. (A)-1: a copolymer represented by chemical formula (A)-1 shown below (molecular weight: 7,000, degree of dispersion: 1.8). In the formula, the subscript numerals shown to the bottom right of the parentheses ( ) indicate the percentage (mol %) of the respective structural units within the copolymer.
(B)-1: (4-methylphenyl)diphenylsulfonium nonafluoro-n-butane sulfonate.
(C)-1: the [fluorine-containing copolymer 1] synthesized in Example 1.
(C)-2: the [fluorine-containing copolymer 2] synthesized in Example 2.
(C)-3: the [fluorine-containing copolymer 3] synthesized in Example 3.
(C)-4: the [fluorine-containing copolymer 4] synthesized in Example 4.
(C)-5: the [fluorine-containing copolymer 5] synthesized in Example 5.
(C)-6: the [fluorine-containing copolymer 6] synthesized in Example 6.
(C)-7: the [fluorine-containing copolymer 7] synthesized in Example 7.
(C)-8: the [fluorine-containing copolymer 8] synthesized in Example 8.
(C)-9: the [fluorine-containing copolymer 9] synthesized in Example 9.
(C)-10: the [fluorine-containing copolymer 10] synthesized in Example 10.
(C)-11: the [fluorine-containing copolymer 11] synthesized in Example 11.
(C)-12: the [fluorine-containing copolymer 12] synthesized in Example 12.
(D)-1: tri-n-pentylamine
(S)-1: a mixed solvent of PGMEA/PGME=6/4 (weight ratio).

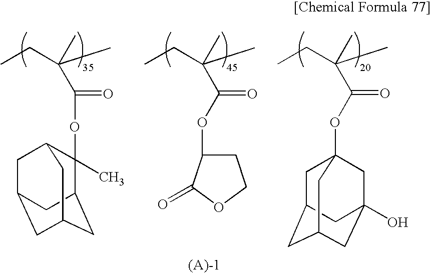

Subsequently, the resist compositions of Examples 13 to 32 were each coated onto an 8-inch silicon wafer using a spinner, subsequently subjected to a prebake treatment on a hotplate for 60 seconds at 110° C., and then dried, yielding a resist film with a film thickness of 120 nm in each case.

A water droplet was dripped onto the surface of each resist film (the resist film prior to exposure), and a DROP MASTER-700 apparatus (a product name, manufactured by Kyowa Interface Science Co. Ltd.) was used to measure the contact angle (the static contact angle) (contact angle measurement: water 2 μl). The result of this measurement was recorded as the “post-coating contact angle (°)”.

Following measurement of the contact angle, the wafer was subjected to a developing treatment for either 30 seconds or 60 seconds at 23° C. in a 2.38% by weight aqueous solution of tetramethylammonium hydroxide (TMAH), and subsequently rinsed with pure water for 15 seconds. The contact angle was then measured in the same manner as that described above. The measured values were recorded as “contact angle (°) after 30 s developing” and “contact angle (°) after 60 s developing” respectively. The results are shown in Table 2.

TABLE 2

| | | Contact | Contact |
|---|---|---|---|
| | Post-coating contact | angle (°) after | angle (°) after |
| | angle (°) | 30 s developing | 60 s developing |
| Example 13 | 80.4 | 59.8 | 58.3 |
| Example 14 | 82.4 | 64.7 | 62.3 |
| Example 15 | 80.3 | 63.1 | 63.0 |
| Example 16 | 68.2 | 59.8 | 59.9 |
| Example 17 | 85.2 | 61.7 | 61.5 |
| Example 18 | 79.5 | 62.5 | 62.2 |
| Example 19 | 79.9 | 62.1 | 62.4 |
| Example 20 | 83.9 | 62.8 | 62.6 |
| Example 21 | 84.5 | 61.1 | 63.9 |
| Example 22 | 69.0 | 59.9 | 59.5 |
| Example 23 | 78.1 | 62.8 | 62.2 |
| Example 24 | 84.2 | 63.4 | 62.0 |
| Example 25 | 88.7 | 61.6 | 63.7 |
| Example 26 | 80.2 | 59.2 | 58.0 |
| Example 27 | 83.8 | 61.2 | 59.4 |
| Example 28 | 83.2 | 60.6 | 59.5 |
| Example 29 | 80.8 | 62.9 | 63.0 |
| Example 30 | 85.2 | 62.7 | 63.5 |
| Example 31 | 86.5 | 65.9 | 66.4 |
| Example 32 | 80.0 | 60.4 | 57.5 |

As is evident from the above results, the resist films formed using the resist compositions of Examples 13 to 32 which included the [fluorine-containing copolymers 1 to 12] exhibited a lower contact angle following developing than the contact angle prior to developing. In other words, these resist films had a higher degree of hydrophilicity following developing than that observed prior to developing.

These results show that the resist compositions of Examples 13 to 32 exhibited hydrophobic properties during immersion exposure, but then developed hydrophilic properties during developing. It is surmised that these results indicate that the action of the alkali developing solution caused the —CO—CH₂—CF₃ groups within the [fluorine-containing copolymers 1 to 12] to dissociate, thereby generating —OH groups and increasing the solubility of the copolymer in the alkali developing solution.

### [Method of Forming Resist Pattern]

An organic antireflection film composition (product name: ARC29A, manufactured by Brewer Science Ltd.) was applied onto an 8-inch silicon wafer using a spinner, and the composition was then baked on a hotplate at 205° C. for 60 seconds, thereby forming an organic antireflection film having a film thickness of 89 nm. Then, each of the resist compositions obtained above was applied onto the antireflection film using a spinner, and was then prebaked (PAB) and dried on a hotplate at 110° C. for 60 seconds, thereby forming a resist film having a film thickness of 100 nm.

Thereafter, using an ArF exposure apparatus for immersion lithography (product name: NSR-S609B, manufactured by Nikon Corporation, NA (numerical aperture)=1.07, σ0.97), the resist film was selectively irradiated with an ArF excimer laser (193 nm) through a mask pattern. A PEB treatment was then conducted at 110° C. for 60 seconds, followed by development for 30 seconds at 23° C. in a 2.38% by weight aqueous solution of tetramethylammonium hydroxide (TMAH). The resist film was then rinsed for 30 seconds with pure water, and shaken dry.

As a result, in each of the examples, a line and space pattern having a line width of 55 nm and a pitch of 110 nm was formed on the resist film.

The above results confirmed that the resist composition for immersion exposure according to the present invention is useful as a resist composition.

What is claimed is:

1. A resist composition for immersion exposure, comprising a base component (A) that exhibits changed solubility in an alkali developing solution under action of acid, an acid generator component (B) that generates acid upon exposure, and a fluorine-containing copolymer (C) comprising a structural unit (c1) represented by general formula (c1-1) shown below: 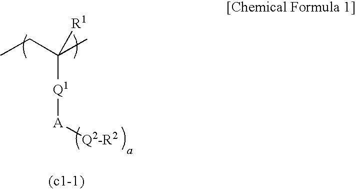
[wherein, R¹ represents a hydrogen atom, a lower alkyl group or a halogenated lower alkyl group, Q¹ represents a single bond or a divalent linking group, A represents an aromatic cyclic group that may have a substituent, Q² represents a group in which one hydrogen atom has been removed from a monovalent hydrophilic group, R² represents a base dissociable group, and a represents 1 or 2, provided that at least one among A and said a R² groups contains a fluorine atom].

2. A resist composition for immersion exposure according to claim 1, wherein said fluorine-containing copolymer (C) further comprises a structural unit (c2) containing an acid dissociable group.

3. A resist composition for immersion exposure according to claim 2, wherein said structural unit (c2) is represented by general formula (c2-1) shown below: 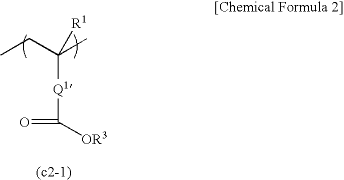
[wherein, R¹ represents a hydrogen atom, a lower alkyl group or a halogenated lower alkyl group, Q¹′ represents a single bond or a divalent linking group, and R³ represents an acid dissociable group].

4. A resist composition for immersion exposure according to claim 1, wherein said R² is at least one group selected from among groups represented by general formulas (II-1) to (II-3) shown below: 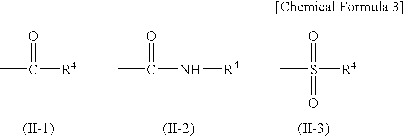
[wherein, each R⁴ independently represents a hydrocarbon group that may contain a fluorine atom].

5. The resist composition for immersion exposure according to claim 1, wherein said base component (A) is a base component that exhibits increased solubility in an alkali developing solution under action of acid.

6. The resist composition for immersion exposure according to claim 5, wherein said base component (A) comprises a resin component (A1) that exhibits increased solubility in an alkali developing solution under action of acid, and said resin component (A1) comprises a structural unit (a1) derived from an acrylate ester containing an acid dissociable, dissolution inhibiting group.

7. The resist composition for immersion exposure according to claim 6, wherein said resin component (A1) further comprises a structural unit (a2) derived from an acrylate ester containing a lactone-containing cyclic group.

8. The resist composition for immersion exposure according to claim 7, wherein said resin component (A1) further comprises a structural unit (a3) derived from an acrylate ester containing a polar group-containing aliphatic hydrocarbon group.

9. The resist composition for immersion exposure according to claim 1, which further comprises a nitrogen-containing organic compound (D).

10. A method of forming a resist pattern, comprising: forming a resist film on a substrate using a positive resist composition for immersion exposure according to claim 1, conducting immersion exposure of said resist film, and alkali-developing said resist film to form a resist pattern.

11. A fluorine-containing copolymer comprising a structural unit (c1) represented by general formula (c1-1) shown below: 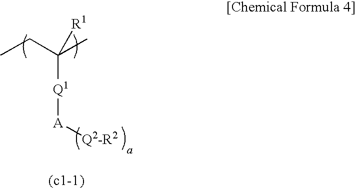
[wherein, R¹ represents a hydrogen atom, a lower alkyl group or a halogenated lower alkyl group, Q¹ represents a single bond or a divalent linking group, A represents an aromatic cyclic group that may have a substituent, Q² represents a group in which one hydrogen atom has been removed from a monovalent hydrophilic group, R² represents a base dissociable group, and a represents 1 or 2, provided that at least one among A and said a R² groups contains a fluorine atom].

12. A fluorine-containing copolymer according to claim 11, further comprising a structural unit (c2) containing an acid dissociable group.

13. A fluorine-containing copolymer according to claim 12, wherein said structural unit (c2) is represented by general formula (c2-1) shown below: 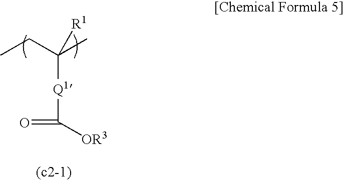
[wherein, R¹ represents a hydrogen atom, a lower alkyl group or a halogenated lower alkyl group, Q¹′ represents a single bond or a divalent linking group, and R³ represents an acid dissociable group].

14. A fluorine-containing copolymer according to claim 11, wherein said R² is at least one group selected from among groups represented by general formulas (II-1) to (II-3) shown below: 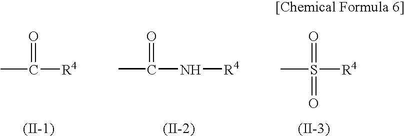
[wherein, each R⁴ independently represents a hydrocarbon group that may contain a fluorine atom].
